(19) United States
(12) Patent Application Publication
(10) Pub. No.: US 2024/0407098 A1
(43) Pub. Date: Dec. 5, 2024

(54) MODULE AND APPARATUS

(71) Applicant: CANON KABUSHIKI KAISHA, Tokyo (JP)

(72) Inventors: MITSUTOSHI HASEGAWA, Kanagawa (JP); NORITAKE TSUBOI, Kanagawa (JP); SATORU HIGUCHI, Tokyo (JP)

(21) Appl. No.: 18/771,186

(22) Filed: Jul. 12, 2024

Related U.S. Application Data
(63) Continuation of application No. PCT/JP2022/001025, filed on Jan. 14, 2022.

(51) Int. Cl. H05K 1/14; H01L 27/146

(52) U.S. Cl. CPC H05K 1/145; H01L 27/14618; H01L 27/14636; H05K 1/144; H05K 1/147; H05K 2201/042; H05K 2201/10121

(57) ABSTRACT

A first wiring board, a first component mounted on the first wiring board, a second wiring board overlapping the first wiring board, a second component mounted on the second wiring board, and a connecting member disposed between the first wiring board and the second wiring board, the connecting member being soldered to the first wiring board and the second wiring board, the connecting member electrically connecting the first wiring board to the second wiring board, are provided.

### CROSS-REFERENCE TO RELATED APPLICATIONS

This application is a Continuation of International Patent Application No. PCT/JP2022/001025, filed Jan. 14, 2022, which is hereby incorporated by reference herein in its entirety.

### TECHNICAL FIELD

The present invention relates to a module including an image sensor or a display.

### BACKGROUND ART

With enhanced performance of an electrooptical device, such as an image sensor and a display, higher integration of a circuit associated is desired.

PTL 1 describes an electronic module in which components are attached to a substrate on which an electronic device is mounted.

### CITATION LIST

### Patent Literature

PTL 1 Japanese Patent Laid-Open No. 2021-002627

With the technology of PTL 1, there is a limit on a highly-integrated module.

### SUMMARY OF INVENTION

The present invention provides a beneficial technology for higher integration of a module.

An aspect of a module that can solve the above problem includes a first wiring board, a first component that is an electrooptical component mounted on the first wiring board, a second wiring board overlapping the first wiring board, a second component that is an integrated circuit component mounted on the second wiring board, and a connecting member disposed between the first wiring board and the second wiring board, the connecting member being soldered to the first wiring board and the second wiring board, the connecting member electrically connecting the first wiring board to the second wiring board.

Further features of the present invention will become apparent from the following description of exemplary embodiments with reference to the attached drawings.

### BRIEF DESCRIPTION OF DRAWINGS

FIG. 1A is a schematic diagram illustrating a module.

FIG. 1B is a schematic diagram illustrating a module.

FIG. 1C is a schematic diagram illustrating a module.

FIG. 1D is a schematic diagram illustrating a module.

FIG. 1E is a schematic diagram illustrating a module.

FIG. 1F is a schematic diagram illustrating a module.

FIG. 1G is a schematic diagram illustrating a module.

FIG. 1H is a schematic diagram illustrating a module.

FIG. 2A is a schematic diagram illustrating a module.

FIG. 2B is a schematic diagram illustrating a module.

FIG. 2C is a schematic diagram illustrating a module.

FIG. 3A is a schematic diagram illustrating a module.

FIG. 3B is a schematic diagram illustrating a module.

FIG. 3C is a schematic diagram illustrating a module.

FIG. 4A is a schematic diagram illustrating a module.

FIG. 4B is a schematic diagram illustrating a module.

FIG. 4C is a schematic diagram illustrating a module.

FIG. 5A is a schematic diagram illustrating a module.

FIG. 5B is a schematic diagram illustrating a module.

FIG. 5C is a schematic diagram illustrating a module.

FIG. 6A is a schematic diagram illustrating a module.

FIG. 6B is a schematic diagram illustrating a module.

FIG. 7A is a schematic diagram illustrating a module.

FIG. 7B is a schematic diagram illustrating a module.

FIG. 8A is a schematic diagram illustrating a module.

FIG. 8B is a schematic diagram illustrating a module.

FIG. 9A is a schematic diagram illustrating a module.

FIG. 9B is a schematic diagram illustrating a module.

FIG. 10A is a schematic diagram illustrating an apparatus.

FIG. 10B is a schematic diagram illustrating an apparatus.

FIG. 11 is a diagram of a digital camera serving as an example of an electronic apparatus according to Embodiment 2I.

FIG. 12A is a diagram of an electronic module according to Embodiment 2I.

FIG. 12B is a diagram of the electronic module according to Embodiment 2I.

FIG. 13A is a diagram of an intermediate connecting member according to Embodiment 2I.

FIG. 13B is a diagram of the intermediate connecting member according to Embodiment 2I.

FIG. 14A is a diagram of a manufacturing method for the intermediate connecting member according to Embodiment 2I.

FIG. 14B is a diagram of the manufacturing method for the intermediate connecting member according to Embodiment 2I.

FIG. 15A is a diagram of the manufacturing method for the intermediate connecting member according to Embodiment 2I.

FIG. 15B is a diagram of the manufacturing method for the intermediate connecting member according to Embodiment 2I.

FIG. 15C is a diagram of the manufacturing method for the intermediate connecting member according to Embodiment 2I.

FIG. 16A is a diagram of the manufacturing method for the intermediate connecting member according to Embodiment 2I.

FIG. 16B is a diagram of the manufacturing method for the intermediate connecting member according to Embodiment 2I.

FIG. 16C is a diagram of the manufacturing method for the intermediate connecting member according to Embodiment 2I.

FIG. 17A is a diagram of the manufacturing method for the intermediate connecting member according to Embodiment 2I.

FIG. 17B is a diagram of the manufacturing method for the intermediate connecting member according to Embodiment 2I.

FIG. 17C is a diagram of the manufacturing method for the intermediate connecting member according to Embodiment 2I.

FIG. 18A is a diagram of the manufacturing method for the intermediate connecting member according to Embodiment 2I.

FIG. 18B is a diagram of the manufacturing method for the intermediate connecting member according to Embodiment 2I.

FIG. 19A is a diagram of a manufacturing method for an image pickup module according to Embodiment 2I.

FIG. 19B is a diagram of the manufacturing method for the image pickup module according to Embodiment 2I.

FIG. 19C is a diagram of the manufacturing method for the image pickup module according to Embodiment 2I.

FIG. 20A is a diagram of the manufacturing method for the image pickup module according to Embodiment 2I.

FIG. 20B is a diagram of the manufacturing method for the image pickup module according to Embodiment 2I.

FIG. 20C is a diagram of the manufacturing method for the image pickup module according to Embodiment 2I.

FIG. 21A is a diagram of an intermediate connecting member according to Embodiment 2II.

FIG. 21B is a diagram of the intermediate connecting member according to Embodiment 2II.

FIG. 22A is a diagram of a manufacturing method for the intermediate connecting member according to Embodiment 2II.

FIG. 22B is a diagram of the manufacturing method for the intermediate connecting member according to Embodiment 2II.

FIG. 22C is a diagram of the manufacturing method for the intermediate connecting member according to Embodiment 2II.

FIG. 22D is a diagram of the manufacturing method for the intermediate connecting member according to Embodiment 2II.

FIG. 23 is a perspective view of an intermediate connecting member according to Embodiment 2III.

FIG. 24 is a perspective view of an intermediate connecting member according to Embodiment 2IV.

FIG. 25A is a diagram of an intermediate connecting member according to Embodiment 2V.

FIG. 25B is a diagram of the intermediate connecting member according to Embodiment 2V.

FIG. 26A is a diagram of an intermediate connecting member according to Embodiment 2VI.

FIG. 26B is a diagram of the intermediate connecting member according to Embodiment 2VI.

FIG. 27A is a diagram of an intermediate connecting member according to a modification.

FIG. 27B is a diagram of an intermediate connecting member according to a modification.

FIG. 28A is a diagram of an intermediate connecting member according to Embodiment 2VII.

FIG. 28B is a diagram of the intermediate connecting member according to Embodiment 2VII.

FIG. 29 is a perspective view of an intermediate connecting member according to Embodiment 2VIII.

FIG. 30A is a diagram of an intermediate connecting member according to a modification.

FIG. 30B is a diagram of an intermediate connecting member according to a modification.

FIG. 31A is a schematic diagram illustrating a wiring component.

FIG. 31B is a schematic diagram illustrating the wiring component.

FIG. 31C is a schematic diagram illustrating the wiring component.

FIG. 32A is a schematic diagram illustrating a wiring component.

FIG. 32B is a schematic diagram illustrating the wiring component.

FIG. 32C is a schematic diagram illustrating the wiring component.

FIG. 33A is a schematic diagram illustrating a wiring component.

FIG. 33B is a schematic diagram illustrating the wiring component.

FIG. 34A is a schematic diagram illustrating a manufacturing method for a module.

FIG. 34B is a schematic diagram illustrating the manufacturing method for the module.

FIG. 34C is a schematic diagram illustrating the manufacturing method for the module.

FIG. 34D is a schematic diagram illustrating the manufacturing method for the module.

FIG. 34E is a schematic diagram illustrating the manufacturing method for the module.

FIG. 35A is a schematic diagram illustrating a module.

FIG. 35B is a schematic diagram illustrating the module.

FIG. 36A is a schematic diagram illustrating a wiring component.

FIG. 36B is a schematic diagram illustrating the wiring component.

FIG. 36C is a schematic diagram illustrating the wiring component.

FIG. 37A-1 is a schematic diagram illustrating a wiring component.

FIG. 37A-2 is a schematic diagram illustrating the wiring component.

FIG. 37B-1 is a schematic diagram illustrating a wiring component.

FIG. 37B-2 is a schematic diagram illustrating the wiring component.

FIG. 37C-1 is a schematic diagram illustrating a wiring component.

FIG. 37C-2 is a schematic diagram illustrating the wiring component.

FIG. 37D-1 is a schematic diagram illustrating a wiring component.

FIG. 37D-2 is a schematic diagram illustrating the wiring component.

FIG. 37E-1 is a schematic diagram illustrating a wiring component.

FIG. 37E-2 is a schematic diagram illustrating the wiring component.

FIG. 38A-1 is a schematic diagram illustrating a wiring component.

FIG. 38A-2 is a schematic diagram illustrating the wiring component.

FIG. 38B-1 is a schematic diagram illustrating the wiring component.

FIG. 38B-2 is a schematic diagram illustrating the wiring component.

FIG. 38C-1 is a schematic diagram illustrating the wiring component.

FIG. 38C-2 is a schematic diagram illustrating the wiring component.

FIG. 38D-1 is a schematic diagram illustrating the wiring component.

FIG. 38D-2 is a schematic diagram illustrating the wiring component.

FIG. 39A is a schematic diagram illustrating a wiring component.

FIG. 39B is a schematic diagram illustrating a wiring component.

FIG. 39C-1 is a schematic diagram illustrating a wiring component.

FIG. 39C-2 is a schematic diagram illustrating the wiring component.

FIG. 40A is a schematic diagram illustrating a manufacturing method for a module.

FIG. 40B is a schematic diagram illustrating the manufacturing method for the module.

FIG. 40C is a schematic diagram illustrating the manufacturing method for the module.

FIG. 40D is a schematic diagram illustrating the manufacturing method for the module.

FIG. 40E is a schematic diagram illustrating the manufacturing method for the module.

FIG. 40F is a schematic diagram illustrating the manufacturing method for the module.

FIG. 41 is a diagram of an electronic apparatus according to Embodiment 4I.

FIG. 42A is a diagram of an electronic module according to Embodiment 4I.

FIG. 42B is a diagram of the electronic module according to Embodiment 4I.

FIG. 43 is a diagram of an image pickup module according to Embodiment 4I.

FIG. 44A is a diagram of an intermediate connecting member according to Embodiment 4I.

FIG. 44B is a diagram of the intermediate connecting member according to Embodiment 4I.

FIG. 44C is a diagram of the intermediate connecting member according to Embodiment 4I.

FIG. 45A is a diagram of a manufacturing method for an intermediate connecting unit according to Embodiment 4I.

FIG. 45B is a diagram of the manufacturing method for the intermediate connecting unit according to Embodiment 4I.

FIG. 45C is a diagram of the manufacturing method for the intermediate connecting unit according to Embodiment 4I.

FIG. 45D is a diagram of the manufacturing method for the intermediate connecting unit according to Embodiment 4I.

FIG. 45E is a diagram of the manufacturing method for the intermediate connecting unit according to Embodiment 4I.

FIG. 45F is a diagram of the manufacturing method for the intermediate connecting unit according to Embodiment 4I.

FIG. 45G is a diagram of the manufacturing method for the intermediate connecting unit according to Embodiment 4I.

FIG. 46A is a diagram of a manufacturing method for an image pickup module according to Embodiment 4I.

FIG. 46B is a diagram of the manufacturing method for the image pickup module according to Embodiment 4I.

FIG. 46C is a diagram of the manufacturing method for the image pickup module according to Embodiment 4I.

FIG. 46D is a diagram of the manufacturing method for the image pickup module according to Embodiment 4I.

FIG. 47A is a diagram of the manufacturing method for the image pickup module according to Embodiment 4I.

FIG. 47B is a diagram of the manufacturing method for the image pickup module according to Embodiment 4I.

FIG. 47C is a diagram of the manufacturing method for the image pickup module according to Embodiment 4I.

FIG. 48A is a diagram of an intermediate connecting unit according to Embodiment 4II.

FIG. 48B is a diagram of the intermediate connecting unit according to Embodiment 4II.

FIG. 48C is a diagram of the intermediate connecting unit according to Embodiment 4II.

FIG. 49 is a schematic diagram illustrating an apparatus.

FIG. 50A is a schematic diagram illustrating a module.

FIG. 50B is a schematic diagram illustrating a module.

FIG. 50C is a schematic diagram illustrating a module.

FIG. 50D is a schematic diagram illustrating a module.

### DESCRIPTION OF EMBODIMENTS

Hereinafter, embodiments of the present invention will be described with reference to the attached drawings. In the following description and the drawings, like reference signs are assigned to common components over a plurality of the drawings. Therefore, common components will be described with reference to a plurality of drawings, and the description of components with common reference signs will not be repeated as needed.

Each drawing shows coordinate axes as needed. An X direction, a Y direction, and a Z direction are directions orthogonal to one another. A direction along a certain direction is a direction of which an angle formed with the certain direction is larger than or equal to zero degrees and smaller than or equal to 30 degrees. An angle formed by two directions is defined only within the range larger than or equal to zero degrees and smaller than or equal to 90 degrees. A state where the angle formed by two directions is 180 degrees is regarded as the same as a state where the angle formed by two directions is zero degrees. A state where the angle formed by two directions is 135 degrees is regarded as the same as a state where the angle formed by two directions is 45 degrees.

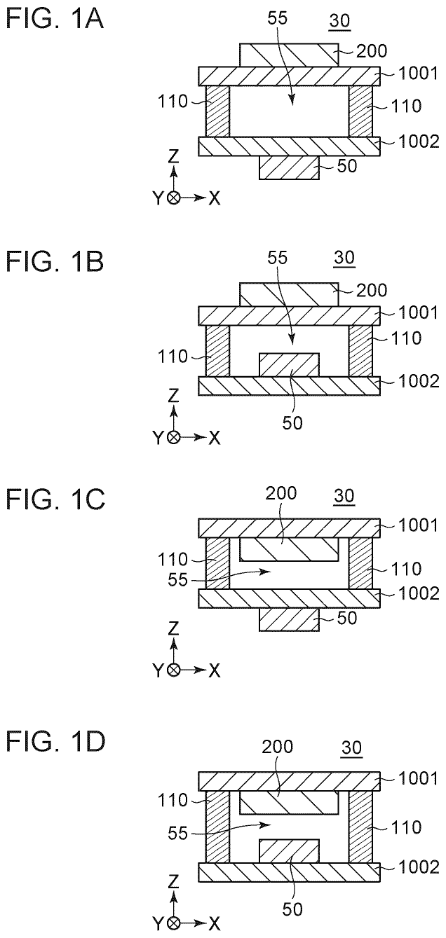

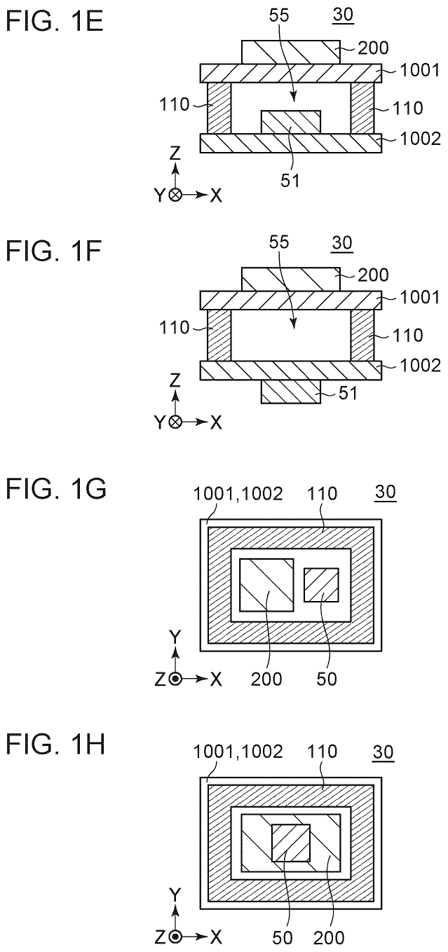

FIGS. 1A to 1F are X-Z sectional views of modules 30 according to some examples of a mode for carrying out the invention. FIGS. 1G and 1H are see-through X-Y plan views of modules 30 according to some examples of the mode for carrying out the invention.

As shown in FIGS. 1A to 1D, each of the modules 30 can include a wiring board 1001, an electrooptical component 200, a wiring board 1002, an integrated circuit component 50, and connecting members 110.

The electrooptical component 200 is mounted on the wiring board 1001. The wiring board 1002 overlaps the wiring board 1001. A direction in which the wiring board 1001 and the wiring board 1002 overlap each other is defined as Z direction, a direction orthogonal to the Z direction is defined as X direction, and a direction orthogonal to the X direction and the Z direction is defined as Y direction. The Z direction is a direction perpendicular to each of a principal surface of the wiring board 1001, a principal surface of the wiring board 1002, and a principal surface of the electrooptical component 200. The principal surface of the electrooptical component 200 is an image pickup surface (light-receiving surface) when the electrooptical component 200 is, for example, an image pickup device (image sensor). The principal surface of the electrooptical component 200 is a display surface (light-emitting surface) when the electrooptical component 200 is, for example, a display device (display). The integrated circuit component 50 is mounted on the wiring board 1002. The connecting members 110 are disposed between the wiring board 1001 and the wiring board 1002. The connecting members 110 electrically connect the wiring board 1001 to the wiring board 1002. The connecting members 110 are soldered to the wiring board 1001 and the wiring board 1002. The integrated circuit component 50 overlaps the wiring board 1001. The integrated circuit component 50 supplies electric power to the electrooptical component 200 via the connecting members 110. Since the integrated circuit component 50 overlaps the wiring board 1001, a reduction in the size of the module 30 is possible.

Since the electrooptical component 200 and the integrated circuit component 50 are respectively mounted on the separate wiring boards 1001, 1002, the influence of heat generated from the electrooptical component 200 on the integrated circuit component 50 is reduced. For this reason, noise that can occur in the integrated circuit component 50 depending on the temperature of the integrated circuit component 50 is reduced. Then, at the time of supplying electric power from the integrated circuit component 50 to the electrooptical component 200, noise that can be superimposed on a power line is reduced. As a result, the operation of the electrooptical component 200 is stable. Such an advantage is suitable in the module 30 in which the temperature of the electrooptical component 200 becomes higher than the temperature of the integrated circuit component 50 when electric power is supplied. The temperature of the electrooptical component 200 may be higher than or equal to, for example, 60° C. The influence of heat generated from the integrated circuit component 50 on the electrooptical component 200 is reduced. For this reason, noise that can occur in the electrooptical component 200 depending on the temperature of the electrooptical component 200 is reduced. As a result, the operation of the electrooptical component 200 is stable. An integrated circuit component is a semiconductor component including at least one semiconductor substrate in which a plurality of semiconductor elements is provided. The semiconductor elements provided in the semiconductor substrate can be transistors and diodes.

As shown in FIGS. 1A to 1D, an air gap 55 is preferably provided between the electrooptical component 200 and the integrated circuit component 50. Heat conduction between the electrooptical component 200 and the integrated circuit component 50 is suppressed by the air gap 55.

The wiring board 1001 and the wiring board 1002 are typically printed wiring boards. The wiring board 1001 and the wiring board 1002 may be wiring boards on or in which a wiring pattern is formed with a method other than a printing method, such as an interposer formed by photolithography. The wiring board 1001 and the wiring board 1002 are typically rigid wiring boards. The wiring board 1001 and the wiring board 1002 may be flexible wiring boards.

The present embodiment is suitable in a case where the electrooptical component 200 includes an analog circuit. This is because, although an analog circuit is more easily affected by noise than a digital circuit, noise is reduced according to the present embodiment. The electrooptical component 200 can be an integrated circuit component. The electrooptical component 200 may be an image pickup device (image sensor) or a display device (display). This is because, although an image quality (image pickup quality or display quality) of an image pickup device or a display device can be affected by noise, noise is reduced according to the present embodiment. The image pickup device can be a CCD image sensor, a CMOS image sensor, a TOF sensor, a SPAD sensor, or the like. The display device can be an EL display, a liquid crystal display, or a digital mirror display.

The integrated circuit component 50 is a power supply device that supplies electric power as described above and is a device including, for example, a linear regulator or a DC/DC converter. The integrated circuit component 50 may be a single-function power IC, may be a multi-function power IC, or may be a power management IC (PMIC).

In the examples of FIGS. 1A and 1C, the wiring board 1002 is provided between the integrated circuit component 50 and the wiring board 1001. In the examples of FIGS. 1A and 1C, the wiring board 1002 is provided between the integrated circuit component 50 and the electrooptical component 200. In the examples of FIGS. 1B and 1D, the integrated circuit component 50 is provided between the wiring board 1001 and the wiring board 1002. In the examples of FIGS. 1A and 1B, the wiring board 1001 is provided between the electrooptical component 200 and the wiring board 1002. In the examples of FIGS. 1A and 1B, the wiring board 1001 is provided between the electrooptical component 200 and the integrated circuit component 50. In the examples of FIGS. 1C and 1D, the electrooptical component 200 is provided between the wiring board 1001 and the wiring board 1002. With a light transmission window provided in the wiring board 1001, the electrooptical component 200 can be used through the light transmission window. In the examples of FIGS. 1C and 1D, the electrooptical component 200 is provided between the wiring board 1001 and the integrated circuit component 50.

As shown in FIGS. 1E and 1F, each of the modules 30 can include an integrated circuit component 51 mounted on the wiring board 1002. In the example of FIG. 1E, the integrated circuit component 51 is provided between the wiring board 1001 and the wiring board 1002. In the example of FIG. 1F, the wiring board 1002 is provided between the integrated circuit component 51 and the wiring board 1001. The integrated circuit component 50 may be configured to supply electric power to the integrated circuit component 51. A combination of any one of the examples shown in FIGS. 1A to 1D and any one of the examples shown in FIGS. 1E and 1F is possible.

The integrated circuit component 51 can be a storage device (memory). The storage device may be a nonvolatile memory, such as a flash memory, or may be a volatile memory, such as a DRAM and an SRAM. The integrated circuit component 51 can be a processing device (processor). The integrated circuit component 51 serving as a processing device may be a device that processes a signal to be input to the electrooptical component 200 or may be a device that processes a signal output from the electrooptical component 200. The integrated circuit component 51 can be a control device (controller). The integrated circuit component 51 serving as a control device can be a device that controls the electrooptical component 200 or another component. The integrated circuit component 51 can be a communication device. The communication device performs wired communication or wireless communication. The communication device may perform communication in a frequency band of 3.5 GHz to 5.0 GHz or may perform communication in a frequency band of 24 GHz to 53 GHz. The communication device may perform communication by terahertz waves, not limited to microwaves or millimeter waves. The integrated circuit component 51 may include a semiconductor device manufactured in accordance with 65 nm to 5 nm process rule or may include a semiconductor device manufactured in accordance with a 1 nm to 4 nm process rule. In manufacturing these, an EUV exposure apparatus, an electron beam exposure apparatus, a nanoimprint lithography apparatus, or the like can be used. The plurality of integrated circuit components 51 may be mounted on the wiring board 1002, and each of the plurality of integrated circuit components 51 may have a function different from each other. For example, at least two devices of a storage device, a processing device, and a control device can be mounted on the wiring board 1002. The integrated circuit component 50 is also capable of supplying electric power to the plurality of integrated circuit components 51 mounted on the wiring board 1002.

In the example shown in FIG. 1H, the integrated circuit component 50 overlaps the electrooptical component 200 in the Z direction perpendicular to the principal surfaces of the wiring boards 1001, 1002 and the principal surface of the electrooptical component 200. Because the integrated circuit component 50 overlaps the electrooptical component 200, a reduction in the size of the module 30 is possible. The integrated circuit component 51 may also overlap the electrooptical component 200 in the Z direction perpendicular to the principal surfaces of the wiring boards 1001, 1002 and the principal surface of the electrooptical component 200. In the example shown in FIG. 1G, the integrated circuit component 50 does not overlap the electrooptical component 200 in the Z direction perpendicular to the principal surfaces of the wiring boards 1001, 1002 and the principal surface of the electrooptical component 200. Since the integrated circuit component 50 does not overlap the electrooptical component 200, the influence of heat of the electrooptical component 200 on the integrated circuit component 50 is reduced. A combination of any one of the examples shown in FIGS. 1A to 1D and any one of the examples shown in FIGS. 1G and 1H is possible.

### Embodiments 1I to 1III

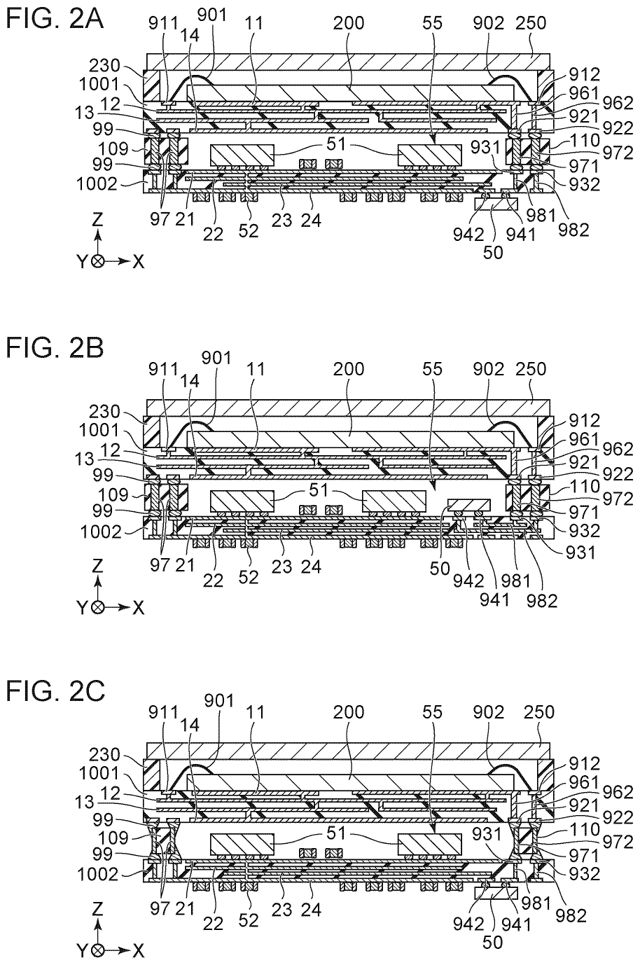

FIG. 2A is a sectional view of a module 30 according to Embodiment 1I. FIG. 2B is a sectional view of a module 30 according to Embodiment 1II. FIG. 2C is a sectional view of a module 30 according to Embodiment 1III.

Each of the modules 30 includes an electrooptical component 200, a wiring board 1001, a lid 250, a frame 230, a connecting member 110, a wiring board 1002, and an integrated circuit component 50. The electrooptical component 200 has an analog circuit. Electric power needed for operation is supplied from the integrated circuit component 50 via a wiring line.

The connecting member 110 has a power supply wiring line 971 that supplies a power supply potential from the integrated circuit component 50 to the electrooptical component 200, and a grounding wiring line 972 that supplies a grounding potential from the integrated circuit component 50 to the electrooptical component 200.

The lid 250 that protects the electrooptical component 200 is fixed to the wiring board 1001 via the frame 230. The frame 230 serves as a spacer for not bringing the electrooptical component 200 and the lid 250 into contact with each other. The material of the frame 230 is resin or ceramic. The lid 250 and the frame 230 are fixed to each other by an adhesive.

The wiring board 1001 has a conductor part and an insulator part. The conductor part is made of a metal having electrical conductivity, such as copper and gold. The insulator part is made of a material having an electrical insulation property, such as glass epoxy resin and ceramic. In this example, the conductor part is made of copper, and the insulator part is made of glass epoxy resin. The outer shape of the wiring board 1001 is a substantially quadrilateral. The dimensions (long side, short side, and diagonal lengths) of the wiring board 1001, for example, range from 10 mm to 100 mm.

The thickness of the wiring board 1001, for example, ranges from 200 μm to 2 mm. From the viewpoint of a low-profile configuration of the module 30, the thickness of the wiring board 1001 is preferably less than 800 μm.

In the wiring board 1001, a plurality of conductor layers is disposed with a space from each other in the Z direction that is a thickness direction of the wiring board 1001. At least two or more conductor layers are provided. An insulator layer is disposed between the two conductor layers. In this example, four conductor layers are provided. A conductor layer 11, a conductor layer 12, a conductor layer 13, and a conductor layer 14 are disposed so as to be laminated in this order from the electrooptical component 200 side. The conductor layer 11 and the conductor layer 14 are surface layers. A solder resist (not shown) may be provided on the surface of the conductor layer 11 and the surface of the conductor layer 14. The conductor part of the wiring board 1001 includes the conductor layers 11, 12, 13, 14 and vias connecting these conductor layers and is used as wiring lines and electrodes of the wiring board 1001.

A power supply electrode 911 and a grounding electrode 912 spaced apart from each other are provided in the conductor layer 11. A power supply electrode 921 and a grounding electrode 922 spaced apart from each other are provided in the conductor layer 14. The power supply electrode 911 and the power supply electrode 921 are electrically connected by a power supply wiring line 961 provided in the wiring board 1001. The grounding electrode 912 and the grounding electrode 922 are electrically connected by a grounding wiring line 962 provided in the wiring board 1001. The power supply wiring line 961 and the grounding wiring line 962 are formed from the conductor part (conductor layers and/or vias) of the wiring board 1001.

The electrooptical component 200 is disposed on the conductor layer 11 and is connected by a conductive member 901 and a conductive member 902 respectively to the power supply electrode 911 and the grounding electrode 912 provided in the wiring board 1001. The conductive member 901 is connected to the power supply electrode 911, and the conductive member 902 is connected to the grounding electrode 912. The conductive members 901, 902 are electrically connected by using a metal material, such as gold and aluminum. In this example, the electrooptical component 200 is mounted on the wiring board 1001 by wire bonding, and the conductive members 901, 902 are bonding wires, such as gold wires and copper wires. However, the configuration is not limited thereto. The electrooptical component 200 may be mounted on the wiring board 1001 by flip chip bonding. The conductive members 901, 902 may be metal bumps of solder, gold, or the like.

The wiring board 1002 has a conductor part and an insulator part. The conductor part is made of a metal having electrical conductivity, such as copper. The insulator part is made of a material having an electrical insulation property, such as glass epoxy resin and ceramic. In this example, the conductor part is made of copper, and the insulator part is made of glass epoxy resin. The outer shape of the wiring board 1002 is a substantially quadrilateral. The dimensions (long side, short side, and diagonal lengths) of the wiring board 1002, for example, range from 10 mm to 100 mm. The dimensions of the wiring board 1002 may be greater or less than the dimensions of the wiring board 1001. From the viewpoint of a reduction in the size of the module 30, the dimensions of the wiring board 1002 are preferably 0.9 times to 1.1 times the dimensions of the wiring board 1001. Here, comparison in dimensions between the wiring board 1001 and the wiring board 1002 can be performed in one sectional view when both are stacked. The thickness of the wiring board 1002, for example, ranges from 200 μm to 2 mm. From the viewpoint of a low-profile configuration of the module 30, the thickness of the wiring board 1002 is preferably less than 800 μm.

In the wiring board 1002, a plurality of conductor layers is disposed with a space from each other in the Z direction that is the thickness direction of the wiring board. At least two or more conductor layers are provided. An insulator layer is disposed between the two conductor layers. In this example, four conductor layers are provided. A conductor layer 21, a conductor layer 22, a conductor layer 23, and a conductor layer 24 are disposed so as to be laminated in this order from the electrooptical component 200 side. The conductor layer 21 and the conductor layer 24 are surface layers. A solder resist (not shown) may be provided on the surface of the conductor layer 21 and the surface of the conductor layer 24. The conductor part of the wiring board 1002 includes the conductor layers 21, 22, 23, 24 and vias connecting these conductor layers and is used as wiring lines and electrodes of the wiring board 1002.

A power supply electrode 931 and a grounding electrode 932 spaced apart from each other are provided in the conductor layer 21. A power supply electrode 941 and a grounding electrode 942 spaced apart from each other are provided in the conductor layer 24. The power supply electrode 931 and the power supply electrode 941 are electrically connected by a power supply wiring line 981 provided in the wiring board 1002. The grounding electrode 932 and the grounding electrode 942 are electrically connected by a grounding wiring line 982 provided in the wiring board 1002. The power supply wiring line 981 and the grounding wiring line 982 are formed from the conductor part (conductor layers and/or vias) of the wiring board 1002.

In addition to the integrated circuit component 50 and the integrated circuit components 51, passive components 52, such as resistors and capacitors, may be mounted on the wiring board 1002. The passive components 52 may include a battery, such as a lithium ion battery, an all-solid battery, and a fuel cell. The passive component 52 serving as a battery may supply electric power to the integrated circuit component 50. The integrated circuit component 50 is a power supply circuit for supplying electric power to an analog circuit or a digital circuit included in the electrooptical component 200 and supplies electric power for actuating the electrooptical component 200.

In Embodiments 1I and 1III, as shown in FIGS. 2A and 2C, the integrated circuit component 50 is connected by electrically conductive members 99 to the power supply electrode 941 and the grounding electrode 942 provided in the conductor layer 24. The conductive members 99 are made of solder or conductive resin. In Embodiment 1II, as shown in FIG. 2B, the integrated circuit component 50 is connected by electrically conductive members 99 to the power supply electrode 941 and the grounding electrode 942 provided in the conductor layer 21. In any one of Embodiments 1I to 1III, the integrated circuit component 50 overlaps the electrooptical component 200. In Embodiments 1I and 1III, the integrated circuit component 50 may overlap the connecting member 110.

The connecting member 110 has conductor parts 97 and an insulator part 109. The conductor parts 97 of the connecting member 110 are made of a metal having electrical conductivity, such as copper. The conductor parts 97 of the connecting member 110 are used as wiring lines that connect the wiring board 1001 to the wiring board 1002.

In FIGS. 2A to 2C, the power supply wiring line 971 and the grounding wiring line 972 are described as the conductor parts 97 of the connecting member 110. The power supply wiring line 971 and the grounding wiring line 972 are supported by the insulator part 109. The insulator part 109 is made of a material having an electrical insulation property, such as resin and ceramic. The resin used for the insulator part 109 is thermoplastic resin or thermosetting resin. To ensure heat resistance during manufacturing or during use, a thermosetting resin is preferably used. The connecting member 110 of this example has the insulator part 109 made of glass epoxy resin. The connecting member 110 of this example can be a member obtained by thermally curing a prepreg containing thermosetting resin, patterning a conductor, and machining the prepared printed wiring board. In the connecting member 110 of another embodiment, the insulator part 109 can be manufactured by performing injection molding of thermoplastic resin. The connecting member 110 can be manufactured by performing insert molding of the insulator part 109 made of thermoplastic resin and the conductor parts 97, such as metal pins.

When the power supply wiring line 971 and the grounding wiring line 972 of the connecting member 110 are located between the wiring board 1001 and the wiring board 1002, a wiring line path between the wiring board 1001 and the wiring board 1002 is reduced as much as possible. For this reason, the power supply wiring line 971 and the grounding wiring line 972 desirably do not extend to outside an outer edge of the wiring board 1001 and the wiring board 1002. On the other hand, the insulator part 109 of the connecting member 110 may have an extended portion extending from between the wiring board 1001 and the wiring board 1002 to outside the outer edge of the wiring board 1001 and the wiring board 1002. A through hole or the like for fixing or aligning a module may be provided at the extended portion.

Conductive portions are provided at corresponding locations in the Z direction respectively on the upper and lower surfaces of the connecting member 110. The conductive portions on the upper and lower surfaces are electrically connected by the conductor parts 97. The conductive portions on the upper surface of the connecting member 110 are connected to the wiring board 1001 via the conductive members 99. The conductive portions on the lower surface of the connecting member 110 is connected to the wiring board 1002 via the conductive members 99.

The conductor parts 97 formed in the connecting member 110 and the electrodes of the wiring boards 1001, 1002 implement electrical connection by using the conductive members 99. Of the plurality of conductor parts 97 provided in the connecting member 110, the power supply wiring line 971 connects the power supply electrode 921 of the wiring board 1001 to the power supply electrode 931 of the wiring board 1002. In other words, the integrated circuit component 50 supplies a power supply potential to the electrooptical component 200 via the power supply wiring line 971. Of the plurality of conductor parts 97 provided in the connecting member 110, the grounding wiring line 972 connects the grounding electrode 922 of the wiring board 1001 to the grounding electrode 932 of the wiring board 1002. In other words, the integrated circuit component 50 supplies a grounding potential to the electrooptical component 200 via the grounding wiring line 972.

The plurality of conductor parts 97 in the connecting member 110 can be arranged at substantially the equal pitch (center-to-center distance), and the pitch of the adjacent two conductor parts 97 in this case is defined as an array pitch P. A distance between the adjacent conductor parts 97 can be approximated to substantially half (P/2) of the array pitch P. In a case where N (N≥0) conductor parts 97 are located between the two conductor parts 97, the pitch (center-to-center distance) of the two conductor parts 97 is (N+1)×P, and a distance between the two conductor parts 97 can be approximated by (N+0.5)×P. The array pitch P is, for example, greater than or equal to 10 μm, may be greater than or equal to 50 μm, may be greater than or equal to 100 μm, and may be greater than or equal to 300 μm. The array pitch P is, for example, less than or equal to 5 mm, may be less than or equal to 3 mm, and may be less than or equal to 1 mm. Electric power that actuates the electrooptical component 200 is supplied from the integrated circuit component 50 mounted on the wiring board 1002. The path runs from the power supply electrode 941 and the grounding electrode 942, to which the integrated circuit component 50 is connected, to the power supply electrode 931 and the grounding electrode 932 through the wiring lines of the wiring board 1002 in the wiring board 1002. Subsequently, the path runs through the power supply wiring line 971 and the grounding wiring line 972 extending in the Z direction in the connecting member 110 and reaches the power supply electrode 921 and the grounding electrode 922. Subsequently, the path runs through the power supply wiring line 961 and the grounding wiring line 962 of the wiring board 1001 and reaches the power supply electrode 911 and the grounding electrode 912 in the wiring board 1001. Then, the path runs from the power supply electrode 911 and the grounding electrode 912 to the electrooptical component 200 through the conductive members 901, 902.

Manufacturing of each of the modules 30 respectively shown in FIGS. 2A to 2C can be performed by using a general SMT process. Initially, solder pastes are supplied by screen printing or with a dispenser onto electrodes provided on one surface layer of the wiring board 1002. In the next step, conductive portions of the electronic components (the integrated circuit components 50, 51 and the passive components 52) are aligned and mounted so as to contact with the supplied solder pastes. Subsequently, the conductive members 99 are heated to higher than or equal to the melting point of the conductive members 99 to melt and then cooled to solidify, thus joining the conductive portions of the electronic components to connecting lands of the wiring board. Heating of the solder pastes can be performed in a reflow furnace. Mechanically and/or electrically joining two components with solder is referred to as soldering. Solder is an alloy of tin. Typical solder can be an alloy of tin and lead; however, the content of lead is not indispensable. In terms of global environments, using lead-free solder is desirable.

Subsequently, the electronic components and the connecting members 110 can be joined by performing the above-described three steps of supplying solder pastes, mounting the components, and heating, to a yet-to-be mounted surface of the wiring board 1002. Joining of the connecting members 110 can be performed in a similar step to the step of the electronic components, so the connecting members 110 can be joined together with the other electronic components at the same time.

A method of joining the wiring board 1002 having the connecting member, manufactured through the above-described steps, with the wiring board 1001 on which the electrooptical component 200 and the lid 250 are mounted will be described below. Initially, solder pastes are supplied by screen printing or with a dispenser to the electrodes for the connecting member, provided on the surface layer of the wiring board 1001. Subsequently, the electrodes of the connecting members 110 integrated with the wiring board 1002 are aligned with the locations of the solder pastes supplied, and mounted. After that, the conductive members 99 are heated to higher than or equal to the melting point to melt, and cooled to solidify the conductive members 99, thus making it possible to perform joining.

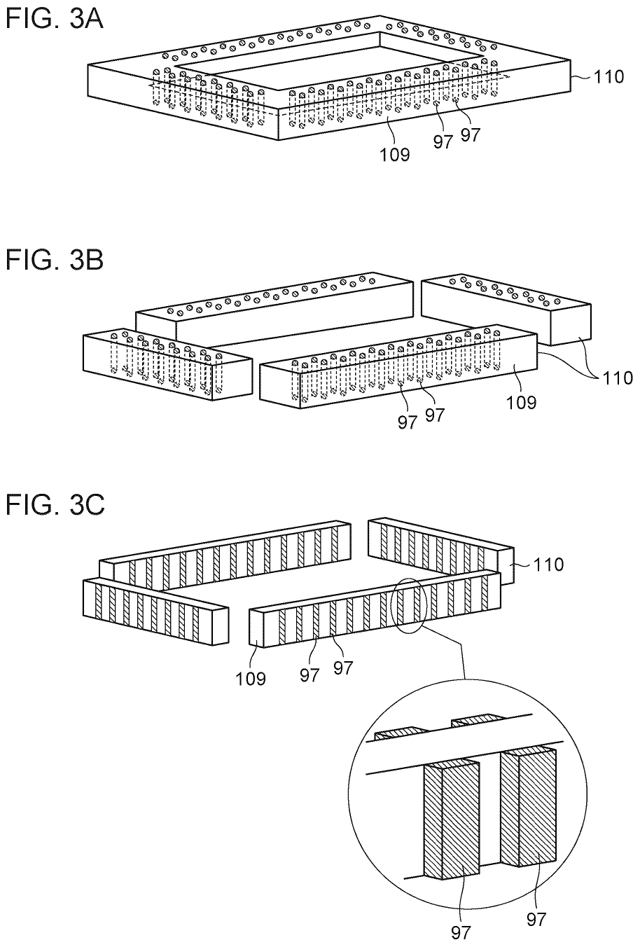

FIGS. 3A, 3B, and 3C are perspective views that illustrate modes of the connecting members 110.

The connecting member 110 shown in FIG. 3A has a frame structure. To connect the connecting member 110 to the wiring board 1001 and the wiring board 1002, a plurality of conductive portions is provided on the upper surface and the lower surface of the connecting member 110. The conductive portions on the opposite upper and lower sides are continuous by the conductor parts 97 of the connecting member 110. For example, continuity between the upper and lower sides may be obtained by forming through holes and applying copper plating, or copper rods may be embedded instead of plating.

The connecting members 110 shown in FIG. 3B each have a rectangular parallelepiped shape and may include the plurality of connecting members 110 as needed. The conductive portions connected to the wiring board are formed on the upper and lower surfaces as in the case of FIG. 3A, and the conductive portions on the opposite upper and lower sides are continuous by the conductor parts 97 of the connecting member 110. For example, continuity between the upper and lower sides may be obtained by forming through holes and applying copper plating, or copper rods may be embedded instead of plating.

The connecting members 110 shown in FIG. 3C each have a rectangular parallelepiped shape as in the case of FIG. 3B. The conductive portions each have a rectangular shape, and connection of the upper and lower conductive portions is achieved by electrical connection using the conductor parts 97 formed on the side surfaces of the connecting members 110. The conductor parts 97 of the connecting members 110 may be formed by, for example, etching copper foil stuck to the surface of the insulator part 109 or plating.

The electrooptical component 200 is mounted on the wiring board 1001. The integrated circuit component 50 is mounted on the wiring board 1002. The wiring board 1001 and the wiring board 1002 are connected to each other via the connecting members 110. In other words, most of the part between the wiring board 1001 and the wiring board 1002 is the air gap 55, and a main heat conduction path between the wiring board 1001 and the wiring board 1002 is the connecting members 110.

For this reason, since the air gap 55 having high thermal resistance is interposed, the influence of heat on the integrated circuit component 50 is reduced even when the electrooptical component 200 generates heat. By reducing a temperature change in the integrated circuit component 50, Johnson noise is reduced, which contributes to stable operation of the electrooptical component 200.

Next, inductive noise will be described in detail. Electric power that actuates the electrooptical component 200 is supplied from the integrated circuit component 50 joined on the wiring board. The path runs from the power supply electrode, to which the integrated circuit component 50 is connected, to the power supply electrode 931 through the wiring line of the wiring board in the wiring board 1002. Subsequently, the path runs through the conductor parts 97 connecting the upper and lower electrodes of the connecting member 110 and reaches the power supply electrode 921. Subsequently, the path runs from the power supply electrode 921 to the power supply electrode 911 through the wiring line and a first via conductor 961 of the wiring board and reaches the electrooptical component 200 through a wire in the wiring board 1001. At this time, a closed loop is formed by the wiring line from the integrated circuit component 50 to the electrooptical component 200. Where the area of the closed loop is S, a magnetic flux density is B, and a magnetic flux that links with the closed loop is Φ, the expression Φ=B×S holds. In other words, the magnetic flux Φ is proportional to the area S of the closed loop. When the magnetic flux Φ links with the closed loop, an induced electromotive force V according to a temporal change in magnetic flux Φ occurs in the closed loop of the wiring line. This conforms with Faraday's and Lenz's law. The relationship between an induced electromotive force V and a change ΔΦ in magnetic flux Φ in a minute time Δt is expressed by V=−ΔΦ/Δt. Since ΔΦ is proportional to the area S of the closed loop, an induced electromotive force V that occurs in the closed loop is also proportional to the area S of the closed loop. According to Ohm's law, the relationship among an induced electromotive force V that occurs in the closed loop, the impedance R of the closed loop, and an induced current I flowing through the closed loop is expressed by I=V/R. Since an induced current I is inversely proportional to an impedance R, an induced current I more easily flows as the impedance R reduces. In a case where the magnetic flux Φ is directed in a 180-degrees opposite direction, the direction of the induced electromotive force V and the direction of the current I are opposite directions. Even in a case where the magnetic flux Φ reaches in a diagonal direction to a closed loop plane, an induced electromotive force V is generated by a component in a perpendicular direction to the loop plane.

The electrooptical component 200 can include an analog circuit having a low resistance against a magnetic flux. For this reason, as the magnetic flux increases, inductive noise occurs in the analog circuit of the electrooptical component 200, which leads to a decrease in stable operation. Alternatively, noise can be superimposed on a signal handled in the analog circuit. When the electrooptical component 200 is an image pickup device or a display device, this may lead to a decrease in image quality. To reduce the influence due to the inductive noise, the area of the closed loop should be reduced. When the integrated circuit component 50 overlaps the wiring board 1001, the spread of the closed loop is suppressed, with the result that inductive noise is reduced. When the integrated circuit component 50 is disposed at a location that overlaps the wiring board 1001, a power supply path from the integrated circuit component 50 to the electrooptical component 200 is shortened, with the result that further stable power supply is achieved. When the integrated circuit component 50 overlaps the connecting member 110, the area of the closed loop is further reduced.

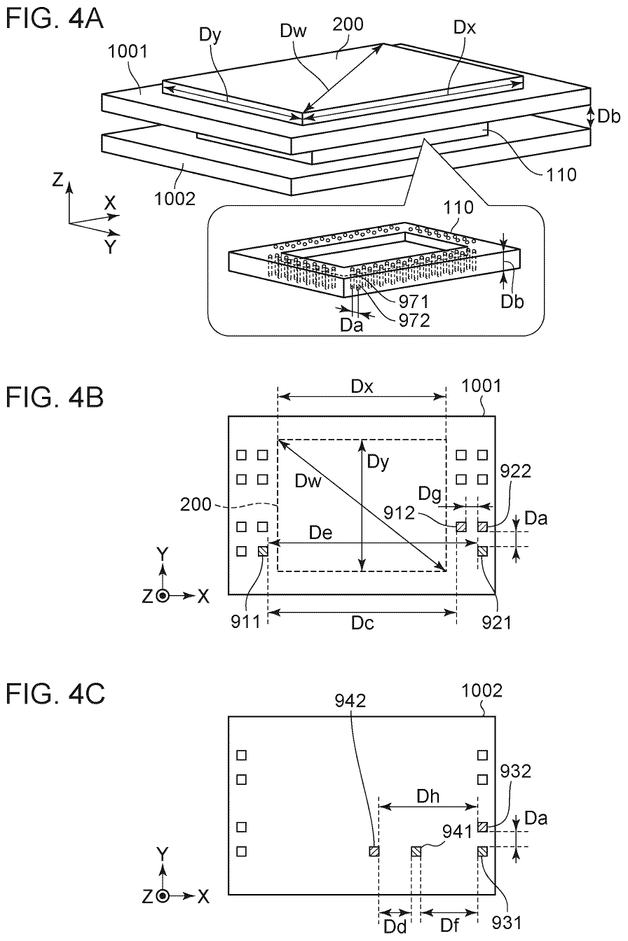

FIG. 4A is a perspective view of the module 30. The outer shape of the electrooptical component 200 can be a quadrilateral. The diagonal dimension of the electrooptical component 200 is denoted by Dw. When the electrooptical component 200 is viewed in a plan view, the dimension of a first side is denoted by Dx, and the dimension of a second side that intersects with the first side is denoted by Dy. FIG. 4B is a plan view of the wiring board 1001. FIG. 4C is a plan view of the wiring board 1002. The examples shown in FIGS. 4B and 4C are suitable arrangements of electrodes and wiring lines in reducing thermal noise and inductive noise in the module 30.

To reduce the influence of inductive noise, the distance Da between the power supply wiring line 971 and the grounding wiring line 972 is preferably less than the dimension Dw of the electrooptical component 200 (Da<Dw). The distance Da between the power supply wiring line 971 and the grounding wiring line 972 is preferably less than the dimension Dx of the electrooptical component 200 (Da<Dx). The distance Da between the power supply wiring line 971 and the grounding wiring line 972 is preferably less than the dimension Dy of the electrooptical component 200 (Da<Dy).

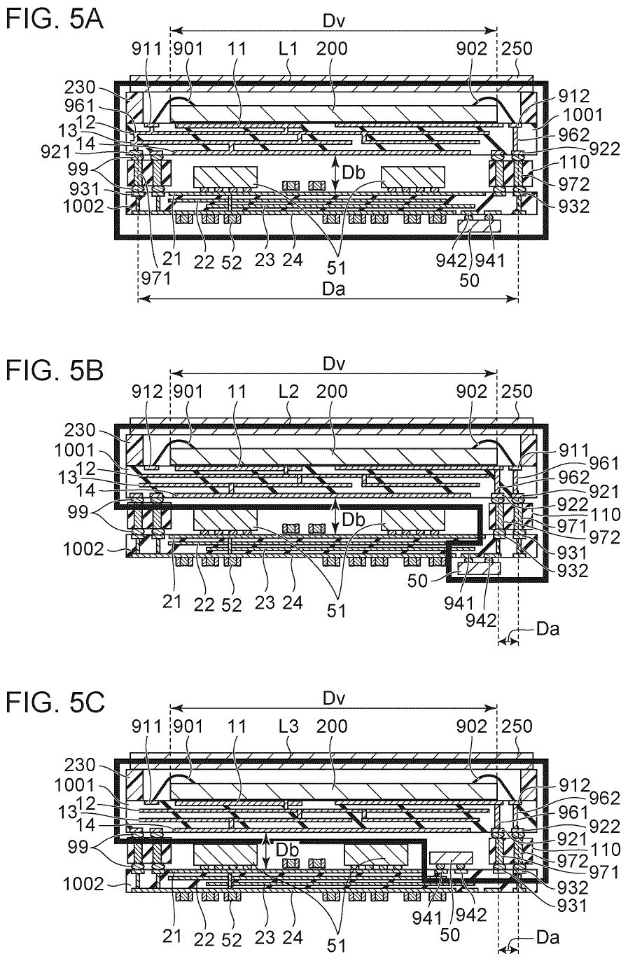

As shown in FIG. 5A, when the distance Da between the power supply wiring line 971 and the grounding wiring line 972 is greater than the dimension Dv (Dv is any one of Dw, Dx, and Dy) of the wiring board 1001 (Dv>Da), a large closed loop L1 is formed. For this reason, inductive noise can occur. On the other hand, as shown in FIGS. 5B and 5C, when the distance Da between the power supply wiring line 971 and the grounding wiring line 972 is less than the distance Dv (Dv is any one of Dw, Dx, and Dy) of the electrooptical component 200 (Da<Dv), small closed loops L2, L3 can be formed. When the integrated circuit component 50 is disposed between the wiring board 1001 and the wiring board 1002 as shown in FIG. 5C, the width of the closed loop L3 in the Z direction can be made smaller than that of the closed loop L1, so it is advantageous in reducing inductive noise.

To effectively reduce inductive noise, arrangement should be performed such that the distance Da satisfies the following expression (1).

$$Da \leq \frac{\sqrt{{Dx}^{2} + {Dy}^{2}}}{10} = 10 / Dw \qquad ( 1 )$$

In other words, it is preferable that the distance Da be less than or equal to 1/10 of the dimension Dw (Da≤Dw/10). At least any one of the dimensions Dw, Dx, Dy is, for example, greater than or equal to 1 mm, may be greater than or equal to 5 mm, may be greater than or equal to 10 mm, may be greater than or equal to 25 mm, may be less than or equal to 100 mm, and may be less than or equal to 50 mm. The distance Da is, for example, less than or equal to 50 mm, may be less than or equal to 10 mm, may be less than or equal to 5 mm, may be less than or equal to 3 mm, and may be less than or equal to 1 mm. The distance Da is, for example, greater than or equal to 10 μm, may be greater than or equal to 50 μm, may be greater than or equal to 100 μm, and may be greater than or equal to 200 μm.

As for the array pitch P of the conductor parts 97 in the connecting member 110, the distance Da can be approximated by (N+0.5)×P in a case where N (N≥0) conductor parts 97 are located between the power supply wiring line 971 and the grounding wiring line 972. The number N of the conductor parts 97 located between the power supply wiring line 971 and the grounding wiring line 972 preferably satisfies 0≤N≤3. In a case where one conductor part 97 is located between the power supply wiring line 971 and the grounding wiring line 972, the distance Da is roughly 1.5×P.

Even in a case where the structure of the connecting member 110 is different, when the above-described expression (1) is satisfied for the distance Da between the power supply wiring line 971 and the grounding wiring line 972 and the size of the electrooptical component 200, the influence of inductive noise is sufficiently suppressed. Furthermore, the distance Da is preferably less than or equal to 1/10 of at least any one of the dimensions Dx and Dy (Da≤≤Dx/10, Da≤Dy/10). The distance Da is preferably less than or equal to 1/10 of the dimension Dx and less than or equal to 1/10 of the dimension Dy. The distance Da between the power supply wiring line 971 and the grounding wiring line 972 is also preferably less than the distance Db between the wiring board 1001 and the wiring board 1002 (Da<Db). The distance Da may be less than or equal to ½ of the distance Db (Da≤Db/2). The distance Da may be less than or equal to ¼ of the distance Db (Da≤Db/4). In this way, reducing the distance Da as much as possible is advantageous in reducing the influence of inductive noise. The distance Db between the wiring board 1001 and the wiring board 1002 can be approximated to the thickness of the connecting member 110. In reducing heat conduction from the wiring board 1001 to the wiring board 1002, the distance Db is preferably greater. The distance Db and the thickness of the connecting member 110 may be greater than the thickness of the wiring board 1001 and may be greater than the thickness of the wiring board 1002. The distance Db is, for example, greater than or equal to 500 μm, may be greater than or equal to 1 mm, may be less than or equal to 3 mm, and may be less than or equal to 5 mm.

As shown in FIG. 4B, the distance between the power supply electrode 921 and the grounding electrode 922 can be approximated to the distance Da between the power supply wiring line 971 and the grounding wiring line 972. On the other hand, the distance Dc between the power supply electrode 911 and the grounding electrode 912 can be set independently of the distance Da. In the present embodiment, the distance Dc is greater than the distance Da (Dc>Da), and the distance Dc may be greater than or equal to twice the distance Da (Dc≥2×Da). However, the distance Dc may be less than the distance Da (Dc<Da), and the distance Dc may be less than or equal to half of the distance Da (Dc≤Da/2). The distance Dc may be greater than half of the distance Da (Dc>Da/2). The distance Dc may be less than twice the distance Da (Dc<2×Da).

As shown in FIG. 4C, the distance between the power supply electrode 931 and the grounding electrode 932 may also be approximated to the distance Da between the power supply wiring line 971 and the grounding wiring line 972. On the other hand, the distance Dd between the power supply electrode 941 and the grounding electrode 942 can be set independently of the distance Da. In the present embodiment, the distance Dd is greater than the distance Da (Dd>Da), and the distance Dd may be greater than or equal to twice the distance Da (Dd≥2×Da). However, the distance Dd may be less than the distance Da (Dd<Da), and the distance Dd may be less than or equal to half of the distance Da (Dd≤Da/2). The distance Dd may be greater than half of the distance Da (Dd>Da/2). The distance Dd may be less than twice the distance Da (Dd<2×Da). In the present embodiment, the distance Dc is greater than the distance Dd (Dc>Dd), and the distance Dc may be less than the distance Dd (Dc<Dd).

The distance De between the power supply electrode 921 and the power supply electrode 911 is greater than the dimension Dx in this example (De>Dx); however, the distance De may be less than the dimension Dx (De<Dx). The distance De is less than the dimension Dw in this example (De<Dw); however, the distance De may be greater than the dimension Dw (De>Dw). The distance De is greater than the distance Da in this example (De>Da); however, the distance De may be less than the distance Da (De<Da). The distance Df between the power supply electrode 931 and the power supply electrode 941 is greater than the distance Dd in this example (Df>Dd); however, the distance Df may be less than the distance Dd (Df<Dd). The distance Df is greater than the distance Da in this example (Df>Da); however, the distance Df may be less than the distance Da (Df<Da). The distance Dd is, for example, greater than or equal to 100 μm, and may be greater than or equal to 300 μm. The distance Dd is, for example, less than or equal to 10 mm, may be less than or equal to 5 mm, may be less than or equal to 3 mm, and may be less than or equal to 1 mm.

The distance Dg between the grounding electrode 922 and the grounding electrode 912 is less than the dimension Dx in this example (Dg<Dx); however, the distance Dg may be greater than the dimension Dx (Dg>Dx). The distance Dg is less than the dimension Dw in this example (Dg<Dw); however, the distance Dg may be greater than the dimension Dw (Dg>Dw). The distance Dg is greater than the distance Da in this example (Dg>Da); however, the distance Dg may be less than the distance Da (Dg<Da). The distance Dh between the grounding electrode 932 and the grounding electrode 942 is greater than the distance Dd in this example (Dh>Dd); however, the distance Dh may be less than the distance Dd (Dh<Dd). The distance Dh is greater than the distance Da in this example (Dh>Da); however, the distance Dh may be less than the distance Da (Dh<Da).

The area of the closed loop can be reduced by reducing the distance Dc between the power supply electrode 911 and the grounding electrode 912. To reduce the influence of inductive noise, the distance Dc between the power supply electrode 911 and the grounding electrode 912 is preferably less than the dimension Dw of the electrooptical component 200 (Dc<Dw). The distance Dc is also preferably less than the dimension Dx (Dc<Dx). The distance Dc is preferably less than the dimension Dy of the electrooptical component 200 (Dc<Dy). However, in this example, to supply a power supply potential and a grounding potential respectively to both sides of the electrooptical component 200, the distance Dc between the power supply electrode 911 and the grounding electrode 912 is greater than the dimension Dx of the electrooptical component 200 (Dc>Dx).

In the above description, to reduce the area of the closed loop, the distance (Da, Dc) between a supply path of a power supply potential and a supply path of a grounding potential is reduced. Not limited to this, the area of the closed loop can be reduced by reducing the length of the supply path of a power supply potential or reducing the length of the supply path of a grounding potential. The length of the supply path of a power supply potential in the closed loop substantially depends on the sum of the distance Df, the distance Db, and the distance De. The length of the supply path of a grounding potential in the closed loop substantially depends on the sum of the distance Dd, the distance Dh, and the distance Dg. Therefore, for example, reducing the distance De or the distance Df by which the supply path of a power supply potential is occupied is also effective for noise reduction. Reducing the distance Df or the distance Dh by which the supply path of a grounding potential is occupied is also effective for noise reduction. Reducing the distance Db is also effective to noise reduction. The distance Db may, for example, range from 1 mm to 5 mm. The distance Db may be less than the dimension Dv (Db<Dv) and may be less than the distance Dd (Db<Dd).

To reduce at least one of the distance De and the distance Dg, at least one of the power supply electrode 911 and the grounding electrode 912 may be disposed at a location that overlaps the connecting member 110. To reduce at least one of the distance Dd and the distance Dh, at least one of the power supply electrode 941 and the grounding electrode 942 may be disposed at a location that overlaps the connecting member 110. As shown in FIGS. 1A, 2A, and 2C, a mode in which the wiring board 1001 and the wiring board 1002 are located between the electrooptical component 200 and the integrated circuit component 50 can be adopted. In this mode, at least one of the power supply electrode 911 and the grounding electrode 912 or at least one of the power supply electrode 941 and the grounding electrode 942 can be disposed at a location that overlaps the connecting member 110, so this mode is preferable. The distance De depends on the dimension Dv of the electrooptical component 200. In the meantime, when the location of the integrated circuit component 50 on the wiring board 1002 can be set as needed, the distance Df is preferably less than the distance De (Df<De). Thus, the supply path of a power supply potential can be shortened as much as possible. Heat generated in the electrooptical component 200 can conduct to the wiring board 1002 via the wiring board 1001 and the connecting member 110. For this reason, in suppressing conduction of heat generated in the electrooptical component 200 to the integrated circuit component 50, the integrated circuit component 50 is preferably located farther from the connecting member 110. Therefore, the distance Df is preferably greater than the distance Dd (Df>Dd).

The area of the closed loop can be reduced by reducing the distance Da between the power supply wiring line 971 and the grounding wiring line 972. As described above, the area of the closed loop can be reduced when at least one of Da<Dv, Da≤Dv/10 (Dv is any one of Dw, Dx, and Dy), Da<Db, Da≤Db/2, and Da≤Db/4 is satisfied. As for the dimensions and distances shown in FIGS. 4A to 4C, for example, the relationship (Da, Dd, Dg)<(Db, Df, Dh)<(Dc, De)<Dv is preferably satisfied. Here, “(A, B)<(C, D)” means that at least any one of A and B is less than at least any one of C and D, and each of A to D corresponds to any one of the above-described distances and dimensions.

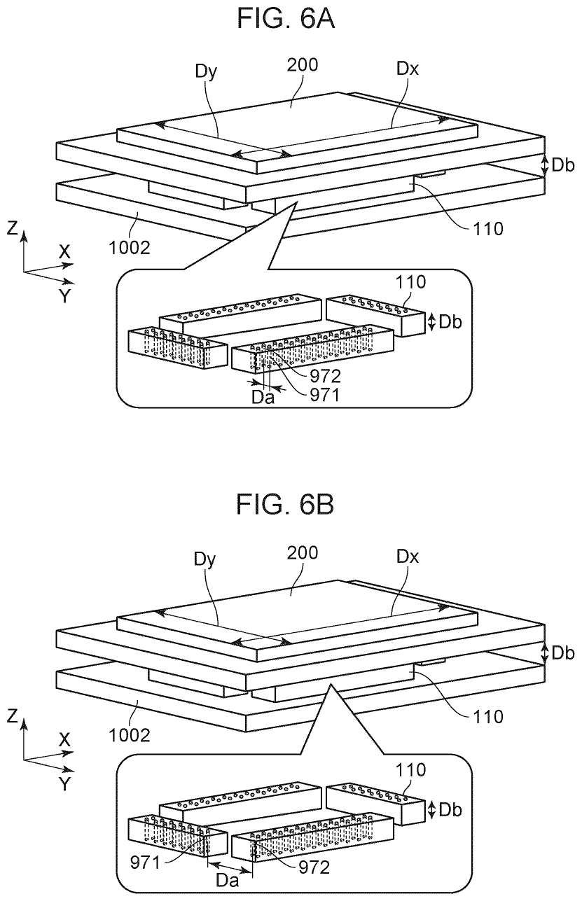

For example, in the rectangular parallelepiped connecting member 110 as shown in FIG. 6A, the power supply wiring line 971 and the grounding wiring line 972 for supplying electric power to the electrooptical component 200 should be disposed in the same connecting member 110 such that the distance Da satisfies the above-described expression. As shown in FIG. 6B, the power supply wiring line 971 and the grounding wiring line 972 respectively provided in different connecting members 110 may be used.

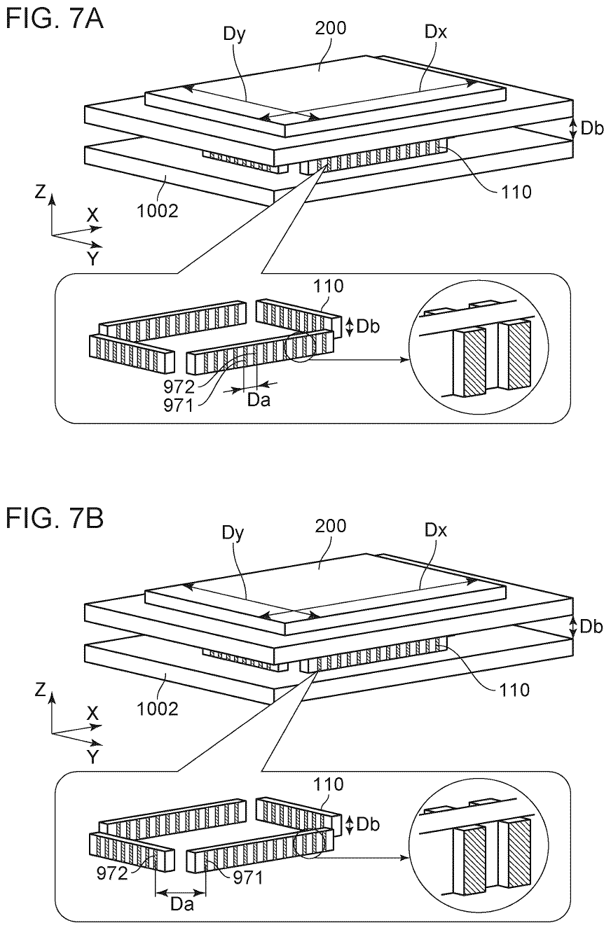

In a case where the electrode has a rectangular shape and each of the connecting members 110 has a rectangular parallelepiped shape as shown in FIG. 7A, the power supply wiring line 971 and the grounding wiring line 972 for supplying electric power to the electrooptical component 200 should be disposed in the same connecting member 110 such that the distance Da satisfies the above expression. Alternatively, as shown in FIG. 7B, the power supply wiring line 971 and the grounding wiring line 972 respectively provided in different connecting members 110 may be used. With the thus configured module 30, heat generated from the electrooptical component 200 does not conduct to the integrated circuit component 50, and Johnson noise of the integrated circuit component 50 is suppressed, with the result that a decrease in the stable operation of the electrooptical component 200 is prevented.

In the description using FIGS. 2A to 7B, the description has been made on the assumption that a wiring line path including the wiring line 971 is the supply path of a power supply potential, and a wiring line path including the wiring line 972 is the supply path of a grounding potential. However, the wiring line path including the wiring line 971 may be the supply path of a grounding potential, and the wiring line path including the wiring line 972 may be the supply path of a power supply potential.

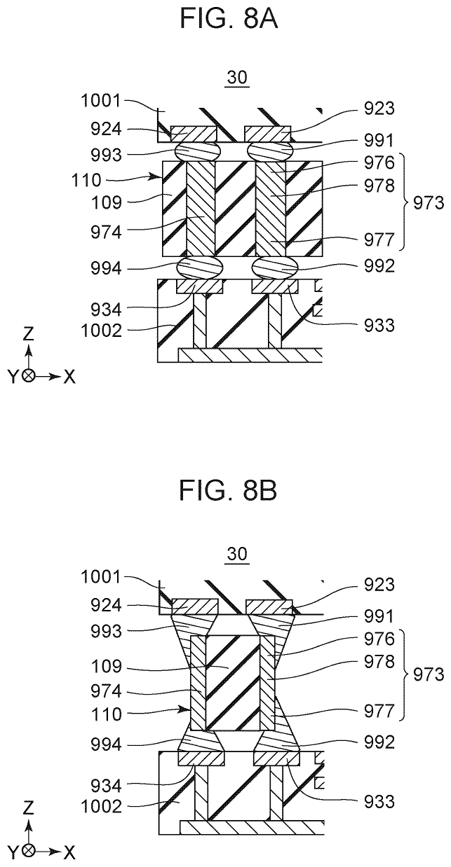

FIG. 8A is an enlarged view of a connecting portion between the connecting member 110 and each of the wiring board 1001 and the wiring board 1002 according to Embodiment 1I shown in FIG. 2A or Embodiment 1II shown in FIG. 2B. FIG. 8B is an enlarged view of a connecting region between the connecting member 110 and each of the wiring board 1001 and the wiring board 1002 according to Embodiment 1III shown in FIG. 2C.

Matters common to Embodiments 1I to 1III will be described. The wiring board 1001 has connection electrodes 923, 924, and the wiring board 1002 has connection electrodes 933, 934. The connecting member 110 includes connection wiring lines 973, 974 serving as the plurality of conductor parts 97 and the insulator part 109 that supports the plurality of conductor parts 97 (the connection wiring lines 973, 974). The connection wiring line 973 has a conductive portion 976, a conductive portion 977, and a conductive portion 978 between the conductive portion 976 and the conductive portion 977 along the Z direction in which the wiring board 1001 and the wiring board 1002 overlap each other. The conductive portion 976 is connected to the connection electrode 923 of the wiring board 1001 via a conductive member 991. The conductive member 991 is in contact with the conductive portion 976 and the connection electrode 923. The conductive portion 977 is connected to the connection electrode 933 of the wiring board 1002 via a conductive member 992. The conductive member 992 is in contact with the conductive portion 977 and the connection electrode 933. The conductive members 991, 992 are examples of the above-described conductive members 99. For example, the conductive members 991, 992 are solder bumps according to Embodiments 1I and 1II and are solder fillets according to Embodiment 1III. The conductive members 991, 992 are separated from each other, and none of the conductive members 991, 992 is in contact with the conductive portion 978. In the Z direction, the conductive member 991 is located between the connection electrode 923 and the conductive portion 976. In the Z direction, the conductive member 992 is located between the connection electrode 933 and the conductive portion 977. In this way, the connection electrode 923, the conductive member 991, the conductive portion 976, the conductive portion 978, the conductive portion 977, the conductive member 992, and the connection electrode 933 are arranged in the Z direction. For this reason, the wiring line path between the wiring board 1001 and the wiring board 1002 can be shortened, and a packing density of connection wiring lines can be increased. Here, the connection wiring line 973 has been described in detail. The connection wiring line 974 is also similar. The connection wiring line 974 is connected to the connection electrode 924 of the wiring board 1001 via the conductive member 993 and is connected to the connection electrode 934 of the wiring board 1002 via the conductive member 994. The conductive members 993, 994 are also examples of the above-described conductive members 99. For example, the conductive members 993, 994 are solder bumps according to Embodiments 1I and 1II and are solder fillets according to Embodiment 1III.

Embodiment 1III shown in FIG. 8B differs from Embodiments 1I and 1II in that the conductive members 99 are in contact with the side surfaces of the connecting member 110. In other words, in the X direction perpendicular to the Z direction, the conductive portion 976 is located between the conductive member 991 and the insulator part 109.

In the X direction perpendicular to the Z direction, the conductive portion 977 is located between the conductive member 992 and the insulator part 109. In a modification of Embodiment 1III, in the Z direction, the conductive member 991 does not need to be located between the connection electrode 923 and the conductive portion 976, and the connection electrode 923 and the conductive portion 976 may be in contact with each other. In the Z direction, the conductive member 992 does not need to be located between the connection electrode 933 and the conductive portion 977, and the connection electrode 933 and the conductive portion 977 may be in contact with each other.

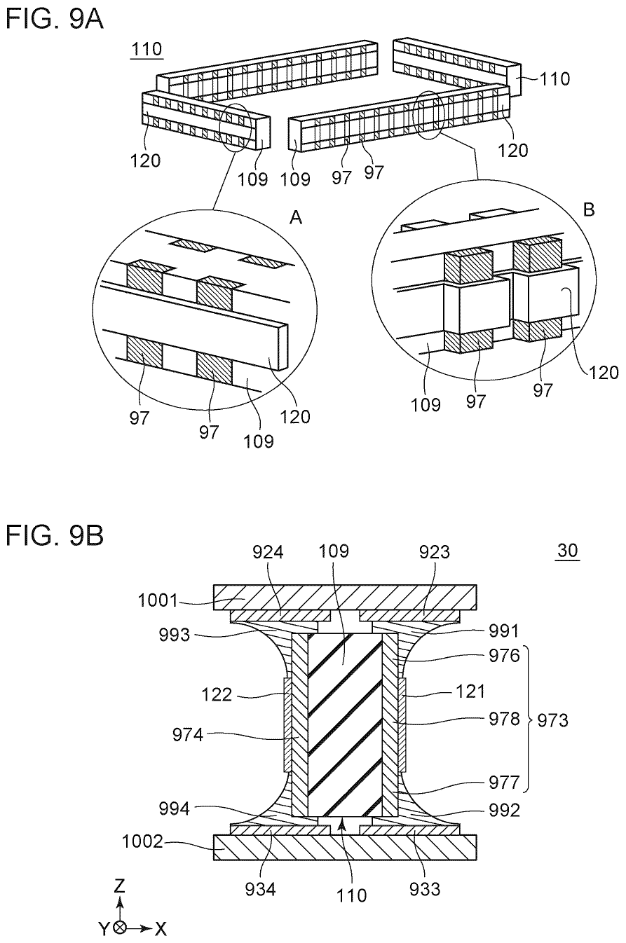

FIG. 9A is a modification of the connecting member 110 shown in FIG. 3C, applicable to Embodiment 1III and the like. The connecting member 110 has a separate part 120 on the plurality of conductor parts 97. Here, the continuous separate part 120 covers the plurality of conductor parts 97. FIG. 9A shows Example A in which the conductor parts 97 are embedded in recesses provided in the insulator part 109 and the side surface of the connecting member 110 is planarized. FIG. 9A also shows Example B in which the plurality of conductor parts 97 is disposed on the flat side surface of the insulator part 109 and the side surface of the connecting member 110 has unevenness. In Example B, recesses are formed by the insulator part 109, protrusions are formed by the conductor parts 97, and the separate part 120 also have unevenness formed along the recesses and protrusions.

FIG. 9B shows an example in which the connecting member 110 shown in FIG. 9A is applied to a module. The mode shown in FIG. 9B differs from the mode shown in FIG. 8B in that separate parts 121, 122 are provided as examples of the separate part 120. The other points may be similar to the mode shown in FIG. 8B, so the description is omitted. The module 30 includes the separate part 121 located between the conductive member 991 and the conductive member 992 in the Z direction. Separation of the conductive member 991 from the conductive member 992 is made easy with the separate part 121. In the X direction perpendicular to the Z direction, the conductive portion 978 is located between the separate part 121 and the insulator part 109. The separate part 121 covers the conductive portion 978 to avoid contact of any one of the conductive members 991, 992 with the conductive portion 978. In the example of FIG. 9B, the thickness of the separate part 121 in the X direction is less than the thickness of the conductive portion 978 in the X direction. Thus, an increase in the dimensions of the connecting member 110 is suppressed. Since the conductive portion 978 is covered with the separate part 121, oxidation or the like of the conductive portion 978 can be suppressed, and, for example, an increase in the resistance of the connection wiring line 973 can be suppressed. In this case, the separate part 121 may be referred to as a protective part for protecting the connection wiring line 973 (particularly, the conductive portion 978). When the thickness of the separate part 121 in the X direction is made greater than the thickness of the conductive portion 978 in the X direction, a protective function is enhanced.

The separate part 120 is disposed such that the plurality of conductor parts 97 does not short-circuit. For this reason, the typical separate part 120 is an insulator, and an organic insulating film, such as solder resist, an inorganic insulating film, such as silicon oxide, and the like may be used as the insulator. When the separate part 120 is formed only on the conductor parts 97, the separate part 120 may be a conductor. In this case, the separate part 121 may be referred to as a conductive part for improving the electrical conductivity of the connection wiring line 973. In FIG. 9B, when the wettability of the conductive members 99 against the separate part 121 that is a conductor is lower than the wettability of the conductive members 99 against the conductive portions 976, 977, the conductive member 991 and the conductive member 992 can be separated favorably. When the separate part 121 is made of a conductor, the resistance of the connection wiring line 973 can be lowered. When the thickness of the separate part 121 in the X direction is made greater than the thickness of the conductive portion 978 in the X direction, the resistance of the connection wiring line 973 can be easily lowered. The same applies to the separate part 122. A connection topology between the wiring board 1001 and the wiring board 1002 via the connecting member 110 has been described with reference to FIGS. 8A to 9B. In relation to such a connection topology, the types and arrangement of integrated circuit components mounted on the wiring boards 1001, 1002 are not limited to the relationship among the electrooptical component 200, and the integrated circuit components 50, 51 and may be variously changed.

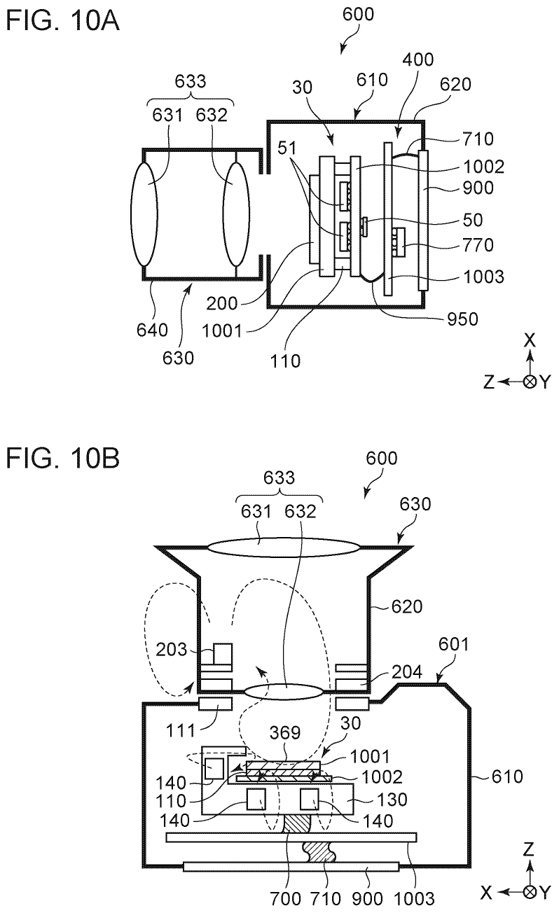

FIG. 10A is a schematic diagram of an apparatus 600 including the module 30, serving as an example of an apparatus according to the embodiment. The apparatus 600, such as a digital camera, a digital camcorder, and a camera-equipped smartphone, includes a module in which electronic components like the electrooptical component 200 and the integrated circuit components 50, 51 are mounted on a printed wiring board. For size reduction, high image quality, and high performance of the image pickup module 30 in which the electrooptical component 200 is an image pickup device, high-density mounting in which a large number of electronic components are disposed on a wiring board with a limited size is desired. The electronic components include relatively large integrated circuit components 51, such as memories, the integrated circuit component 50 for actuating the electrooptical component 200, and passive components 52 like resistors and capacitors. On the other hand, the electrooptical component 200 serving as an image pickup device is desired to be increased in size like APSC size or full size in association with high resolution. Accordingly, the amount of heat generated in the electrooptical component 200 tends to increase. As a way of using the module 30, the module 30 is increasingly used for continuous shooting or long-time moving image shooting, so the electrooptical component 200 further more easily generates heat. As a result, if the temperature of the integrated circuit component 50 that actuates the electrooptical component 200 is increased, Johnson noise occurs, which leads to a problem, that is, a decrease in image quality. However, if the integrated circuit component 50 and the electrooptical component 200 are mounted on the same wiring board, the thermal resistance of the wiring board is constant, and heat conduction from the electrooptical component 200 to the integrated circuit component 50 easily occurs. To reduce the influence of heat while the amount of heat generated tends to increase, a distance between the locations of the integrated circuit components needs to be further increased. Accordingly, the area of the wiring board is increased, and it is difficult to dispose the module in a limited space in a product for which a reduction in size is advancing. A structure that reduces the influence of heat from the electrooptical component 200 on the integrated circuit component 50 is reduced without changing the size of the module 30 and that achieves high image quality is desired to be provided.

FIG. 10A is a schematic diagram of an apparatus 600 including the module 30 serving as an example of an apparatus according to the embodiment. The apparatus 600 may be an apparatus in which a lens and a camera main body are integrated. In this example, the apparatus 600 is a lens interchangeable digital single-lens camera and includes a camera body 610 and a lens barrel 630. The camera body 610 includes a casing 620, the module 30 disposed in the casing 620, and a processing module 400. The lens barrel 630 includes an optical system 633 that forms a light figure on a light incidence plane of the image pickup device when the lens barrel 630 is attached to the camera body 610. The optical system 633 includes a lens 631 disposed on a light incident side and a lens 632 disposed on a light emission side. The lenses 631, 632 are held by a casing 640 of the lens barrel 630. The module 30 and the processing module 400 are electrically connected by a wiring component 950. The module 30 (image pickup module) includes the wiring board 1001, the wiring board 1002, and the connecting member 110. The electrooptical component 200 and the passive components 52 like resistors and capacitors are mounted on the wiring board 1001. Tall components like a memory and the integrated circuit component 50 are mounted on the wiring board 1002. The wiring board 1001 and the wiring board 1002 are electrically connected via the connecting member 110. The processing module 400 includes an integrated circuit component 770 that is an example of an electronic component and a wiring board 1003 on which the integrated circuit component 770 is mounted. The integrated circuit component 770 can be a processing device (processor) that processes a signal output from the integrated circuit component 770. The wiring component 950 preferably has flexibility. A cable, a flexible wiring board, or the like may be used for the wiring component 950. A signal path between the electrooptical component 200 and the integrated circuit component 770, for example, runs from the electrooptical component 200, passes through the wiring board 1001, the connecting member 110, the wiring board 1002, and the wiring component 950, and reaches the integrated circuit component 770. In this case, a passive component (connector) for connecting the wiring component 950 can be mounted on the wiring board 1002.

However, a signal path between the electrooptical component 200 and the integrated circuit component 770 does not need to pass through the connecting member 110. A signal path between the electrooptical component 200 and the integrated circuit component 770 may be formed such that a passive component (connector) for connecting the wiring component 950 is mounted on the wiring board 1001 and the signal path runs from the electrooptical component 200, passes through the wiring component 950, and reaches the integrated circuit component 770. In this case, the signal path is shortened, so a delay and the like are suppressed. The apparatus 600 includes a module 900 (display module) including a display device, such as a liquid crystal display. The module 900 (display module) is capable of displaying an image picked up by an image pickup module. The display module includes a liquid crystal panel or an organic EL panel. The display module may be an electronic viewfinder (EVF). The module 900 is connected to the wiring board 1003 via a connection component 710, such as a flexible wiring board.

The electrooptical component 200 is, for example, a complementary metal oxide semiconductor (CMOS) or a charge coupled device (CCD). The electrooptical component 200 has a function to convert light incoming via the lens barrel 630 to an electrical signal.

FIG. 10B is a schematic diagram of an apparatus 600 including the module 30 according to the embodiment. The apparatus 600 can be a camera, such as a digital still camera, a digital camcorder, a surveillance camera, a network camera, and a Web camera. The apparatus 600 may be a camera in which a lens and a camera main body are integrated. The apparatus 600 is a digital single-lens camera and includes a camera body 610 and a lens barrel 630 detachably mounted to the camera body 610. The camera body 610 includes a casing 620. The casing 620 has a mount 204 to which the lens barrel 630 is detachably mounted. The module 30 having a light incidence plane 369 is disposed inside the casing 620. A direction perpendicular to the light incidence plane 369 is defined as Z direction. The module 30 is held by a metal frame 130. The module 30 includes the wiring board 1001 on which the image pickup device is mounted, the wiring board 1002 that overlaps the wiring board 1001, and the connecting member 110 that connects the wiring board 1001 to the wiring board 1002. A plurality of coils 140 that mechanically actuate the module 30 and that are examples of an inductor element is disposed inside the metal frame 130. Each coil 140 actuates the module 30 in a direction opposite to a camera shake direction by generating Lorentz force. Here, an example of electromagnetically actuating the module 30 with a permanent magnet and the coils 140 that function as electromagnets has been described as a drive unit that mechanically actuates the module 30. Alternatively, a drive unit that actuates the module 30 with a piezoelectric body may be adopted. The image pickup device is a CMOS image sensor, a CCD image sensor, or the like. The outer shape of the image pickup device is formed in a quadrangular shape, specifically, a rectangular shape, when viewed in the Z direction perpendicular to the light incidence plane 369. A direction that is parallel to the light incidence plane 369 and that is a long side direction of the image pickup device is defined as X direction, and a direction that is parallel to the light incidence plane 369 and that is a short side direction of the image pickup device is defined as Y direction. For example, the Y direction is a first direction, and the Z direction is a second direction. The image pickup device photoelectrically converts a light figure formed on the light incidence plane 369 and outputs a pixel signal to the wiring board 1001. The lens barrel 630 includes an optical system 633 that forms a light figure on the light incidence plane 369 of the image pickup device when the lens barrel 630 is attached to the camera body 610.

The lens barrel 630 includes a coil 203 that mechanically actuates the optical system 633 and that is an example of an inductor element. The optical system 633 includes a lens 631 disposed on a light incident side and a lens 632 disposed on a light emission side. The lens barrel 630 is provided with the ring mount 204. The lens 632 is supported on the ring mount 204.

The coil 203 is disposed at a location at which the coil 203 does not block an optical path from the optical system 633 to the light incidence plane 369 of the image pickup device, that is, a location at which the coil 203 is located at the outer periphery of the image pickup device when viewed from the front as shown in FIG. 10B.

The coils 140, 203 operate when supplied with an alternating current having a frequency in a kHz band, that is, a frequency higher than or equal to 1 [kHz] and lower than 1 [MHz]. The coils 140, 203 generate magnetic fluxes therearound when supplied with alternating current. The magnetic fluxes cause inductive noise for the module 30. The direction of each magnetic flux is indicated by the dashed line arrow in FIG. 10B. Because of an alternating current magnetic field generated by alternating current, the direction of the magnetic flux alternately switches between the direction of the dashed line arrow and its opposite direction.

Magnetic fields generated from the inductor elements including the coils 140, 203 and the like shown in FIG. 10B reach the module 30. The closed loop in the module 30 varies in resistance against inductive noise depending on the type of a circuit connected. Specifically, in the module 30, the closed loop of an analog circuit is lower in resistance against inductive noise than the closed loop of a digital circuit. Particularly, wiring lines associated with a pixel array are low in resistance against magnetic field noise because the magnetic field noise directly affects a pixel signal. Induced current more easily flows as a wiring line has a lower impedance and is lower in resistance against magnetic field noise. Once a distribution of voltage occurs in the closed loop of an analog ground due to induced electromotive force, a pixel signal that is an analog signal fluctuates due to the distribution of ground potential. To prevent generation of pattern noise in an output image of the image pickup device, that is, to increase the resistance of the module 30 against magnetic field noise, the area of the closed loop of the analog circuit should be reduced.

The apparatus including the module 30 according to the present embodiment is not limited to an image pickup apparatus, such as a camera, and may be an electronic apparatus, such as a smartphone and a personal computer, or a display apparatus, such as a television and a display. The apparatus can be a transportation apparatus, such as a vehicle, a ship, and a flight vehicle. Alternatively, the apparatus may be a medical apparatus, such as an endoscope and a radiodiagnosis, a measuring apparatus, such as a distance measurement sensor, an analytical instrument, such as a scanning electron microscope, a business machine, such as a printer, a scanner, and a copying machine, or an industrial apparatus, such as a robot and a manufacturing apparatus. In a case where the above-described various apparatuses include a coil that generates a magnetic field, generation of inductive noise is suppressed by adopting the configuration of the module 30.

Here, an example in which the embodiment of the above-described module 30 is applied to the image pickup module has been described. The embodiment of the above-described module 30 may be applied to a display module.

### Example 1A

In FIG. 2A, FR-4 that is glass epoxy resin is used for the wiring board 1001. The outer shape has a size of 43 mm by 50 mm and has a thickness of 0.5 mm. The conductor layer is made of copper foil and is made up of four layers. A plurality of electrodes for connection with the electrooptical component 200 is provided in the first layer of the conductor layer. The electrodes include the power supply electrode 911 and the grounding electrode 912 for supplying electric power that actuates the electrooptical component 200. Electrodes for connection with the connecting member 110 are provided in the fourth layer of the conductor layer. The diameter of each of the electrodes for connection with the connecting member 110 is 0.3 mm, and the electrodes are formed with the closest pitch of 0.6 mm.

The electrooptical component 200 has a size of about 30 mm by 40 mm and has a thickness of 0.7 mm. The electrooptical component 200 is fixed to the wiring board 1001 by die bonding and connected to the electrodes on the wiring board by bonding wires.

The lid 250 that is a cover glass has a size of 40 mm by 50 mm and has a thickness of 0.5 mm. The lid 250 is bonded to the resin frame 230 with a height of 1 mm and a width of 1 mm in order not to contact with the electrooptical component 200. The frame 230 is bonded to the surface of the wiring board 1001.

FR-4 that is glass epoxy resin is used for the wiring board 1002. The outer shape has a size of 43 mm by 50 mm and has a thickness of 0.5 mm. The conductor layer is made of copper foil and is made up of four layers. Chip components, such as a memory that is an integrated circuit component, capacitors, and resistors, and electrodes for connection with the connecting member 110 are provided in the first layer of the conductor layer. The diameter of each of the electrodes for connection with the connecting member 110 is 0.3 mm, and the electrodes are formed with the closest pitch of 0.6 mm. Each of the memories that are the integrated circuit components 51 has a ball grid array (BGA) structure and has a size of 14 mm by 14 mm and a thickness of 1.2 mm. Solder balls provided on the lower surface of the memory are respectively joined to the electrodes provided on the wiring board 1002.

Fourth electrodes for connection with the integrated circuit component 50 are provided in the fourth layer of the conductor layer. The integrated circuit component 50 has a size of 3 mm by 3 mm and a thickness of 0.7 mm.

Connection electrodes are provided on the lower surface of the component and are joined via the conductive members 99 to the fourth electrodes provided in the wiring board 1002.

As shown in FIG. 3A, the connecting member 110 has a frame shape. The outer shape has a size of 34 mm by 44 mm, and the frame has a width of 1.6 mm and a thickness of 2 mm. FR-4 that is glass epoxy resin is used as an insulator. A plurality of conductive portions is provided on the upper surface and the lower surface of the connecting member 110. The conductive portions on opposite upper and lower sides are continuous by the conductor parts 97 of the connecting member. Continuity between the upper and lower sides is obtained by forming through holes and applying Cu plating. The upper and lower ends of each of the through holes are applied with copper plating such that the hole is buried. Thus, a lid is formed to serve as an electrode. The diameter of each of the electrodes is 0.3 mm, and the electrodes are formed with the closest pitch of 0.6 mm.

Electrodes formed on the upper surface of the connecting member 110 are joined to the wiring board 1001 by the conductive members 99. Electrodes formed on the lower surface are joined to the wiring board 1002 by the conductive members 99.

With the thus configured module 30, heat generated from the electrooptical component 200 does not conduct to the integrated circuit component 50, and Johnson noise of the integrated circuit component 50 is suppressed, with the result that a decrease in image quality is prevented.

### Example 1B

In FIG. 2A, FR-4 that is glass epoxy resin is used for the wiring board 1001. The outer shape has a size of 43 mm by 50 mm and has a thickness of 0.5 mm. The conductor layer is made of copper foil and is made up of four layers. A plurality of electrodes for connection with the electrooptical component 200 is provided in the first layer of the conductor layer. The electrodes include the power supply electrode 911 and the grounding electrode 912 for supplying electric power that actuates the electrooptical component 200. Electrodes for connection with the connecting member 110 are provided in the fourth layer of the conductor layer. The diameter of each of the electrodes for connection with the connecting member 110 is 0.3 mm, and the electrodes are formed with the closest pitch of 0.6 mm.

The electrooptical component 200 has a size of about 30 mm by 40 mm and has a thickness of 0.7 mm. The electrooptical component 200 is fixed to the wiring board 1001 by die bonding and connected to the electrodes on the wiring board by bonding wires.

The lid 250 has a size of 40 mm by 50 mm and has a thickness of 0.5 mm. The lid 250 is bonded to the resin frame with a height of 1 mm and a width of 1 mm in order not to contact with the electrooptical component 200. The frame is bonded to the surface of the wiring board 1001.

FR-4 that is glass epoxy resin is used for the wiring board 1002. The outer shape has a size of 43 mm by 50 mm and has a thickness of 0.5 mm. The conductor layer is made of copper foil and is made up of four layers. Chip components, such as a memory that is an integrated circuit component, capacitors, and resistors, and electrodes for connection with the connecting member 110 are provided in the first layer of the conductor layer. The diameter of each of the electrodes for connection with the connecting member 110 is 0.3 mm, and the electrodes are formed with the closest pitch of 0.6 mm. Each of the memories that are the integrated circuit components has a ball grid array (BGA) structure and has a size of 14 mm by 14 mm and a thickness of 1.2 mm. Solder balls provided on the lower surface of the memory are respectively joined to the electrodes provided on the wiring board 1002.

Electrodes for connection with the integrated circuit component 50 are provided in the fourth layer of the conductor layer. The integrated circuit component 50 has a size of 3 mm by 3 mm and a thickness of 0.7 mm. Connection electrodes are provided on the lower surface of the component and are joined via the conductive members 99 to the electrodes provided in the wiring board 1002.

As shown in FIG. 3B, each of the connecting members 110 has a rectangular parallelepiped shape and uses two of each of members with two types of dimensions. The dimensions of one of the members are a width of 1.6 mm, a length of 40 mm, and a height of 2 mm, and the dimensions of the other one of the members are a width of 1.6 mm, a length of 30 mm, and a height of 2 mm. FR-4 that is glass epoxy resin is used as the material of an insulator. A plurality of conductive portions is provided on the upper surface and the lower surface of the connecting member 110. The conductive portions on opposite upper and lower sides are continuous by the conductor parts 97 of the connecting member 110. Copper wires with 00.3 mm are used for the conductors, and the closest pitch is 0.6 mm.

As shown in FIG. 3B, the wiring board 1001 and the wiring board 1002 are electrically connected by using the four rectangular parallelepiped connecting members 110.

The members other than the connecting members 110 are the same ones as those of Example 1A.

In a case where the frame-shaped connecting member 110 shown in FIG. 3A has a size greater than or equal to 20 mm by 20 mm, warpage of about 0.15 mm occurs during heating. For this reason, a defective joint easily occurs at the time of joining with the wiring board. On the other hand, the connecting members 110 shown in FIG. 3B are singulated, and a thermal deformation of each of the connecting members 110 is suppressed to about 50%.

For this reason, a defect is less likely to occur at the time of joining the wiring board to the connecting members 110.

With the thus configured module 30, heat generated from the electrooptical component 200 does not conduct to the integrated circuit component 50, and Johnson noise of the integrated circuit component 50 is suppressed, with the result that a decrease in image quality is prevented.

### Example 1C

In FIG. 2C, FR-4 that is glass epoxy resin is used for the wiring board 1001. The outer shape has a size of 43 mm by 50 mm and has a thickness of 0.5 mm. The conductor layer is made of copper foil and is made up of four layers. A plurality of electrodes for connection with the electrooptical component 200 is provided in the first layer of the conductor layer. The electrodes include the power supply electrode 911 and the grounding electrode 912 for supplying electric power that actuates the electrooptical component 200. Electrodes for connection with the connecting member 110 are provided in the fourth layer of the conductor layer. Electrodes for connection with the connecting members 110 are provided. The size of each electrode is a width of 0.16 mm and a length of 0.4 mm. Arrangement of the electrodes is provided by aligning the center-of-gravity position of the electrodes of the wiring board with the center-of-gravity position of the conductive portions of the connecting members 110.

The electrooptical component 200 has a size of about 30 mm by 40 mm and has a thickness of 0.7 mm. The electrooptical component 200 is fixed to the wiring board 1001 by die bonding and connected to the electrodes on the wiring board by bonding wires.

The lid 250 has a size of 40 mm by 50 mm and has a thickness of 0.5 mm. The lid 250 is bonded to the resin frame with a height of 1 mm and a width of 1 mm in order not to contact with the electrooptical component 200. The frame is bonded to the surface of the wiring board 1001.

FR-4 that is glass epoxy resin is used for the wiring board 1002. The outer shape has a size of 43 mm by 50 mm and has a thickness of 0.5 mm. The conductor layer is made of copper foil and is made up of four layers. Chip components, such as a memory that is an integrated circuit component, capacitors, and resistors, and electrodes for connection with the connecting members 110 are provided in the first layer of the conductor layer. The size of each of the electrodes for connection with the connecting members 110 is a width of 0.16 mm and a length of 0.4 mm. Arrangement of the electrodes is provided by aligning the center-of-gravity position of the electrodes of the wiring board with the center-of-gravity position of the conductive portions of the connecting members 110.

Each of the memories that are the integrated circuit components has a ball grid array (BGA) structure and has a size of 14 mm by 14 mm and a thickness of 1.2 mm. Solder balls provided on the lower surface of the memory are respectively joined to the electrodes provided on the wiring board 1002.

Electrodes for connection with the integrated circuit component 50 are provided in the fourth layer of the conductor layer. The integrated circuit component 50 has a size of 3 mm by 3 mm and a thickness of 0.7 mm. Connection electrodes are provided on the lower surface of the component and are joined via the conductive members 99 to the electrodes provided in the wiring board 1002.

As shown in FIG. 3Cc, each of the connecting members 110 has a rectangular parallelepiped shape and uses two of each of members with two types of dimensions. The dimensions of one of the members are a width of 1.6 mm, a length of 40 mm, and a height of 2 mm, and the dimensions of the other one of the members are a width of 1.6 mm, a length of 30 mm, and a height of 2 mm.

FR-4 that is glass epoxy resin is used as the material of an insulator. The conductive portions each have a rectangular shape, and connection of the upper and lower conductive portions is achieved by electrical connection using the conductor parts 97 of the connecting member 110.

Conductors are obtained by forming copper foil having a thickness of 0.05 mm into a selected size by etching.

The width of each of the conductive portions provided on the upper and lower surfaces is 0.05 mm that is the same as the thickness of the copper foil, and the length is 0.4 mm. The pitch between the adjacent conductive portions is 0.6 mm.

The electrodes of the connecting member 110 and the electrodes of the wiring board are connected by the conductive members 99.

The electrodes of the connecting member 110 of FIGS. 3A and 3B are joined to only within the upper and lower surfaces; whereas, in the structure shown in FIG. 3C, the electrodes can be not only connected to the upper and lower surfaces but also can connect the conductive members 99 to the conductor parts 97 of the connecting member. As shown in FIG. 2C, fillets of the conductive members 99 are formed for the conductor parts 97 of the connecting member and the electrodes of the wiring board, so high reliability is obtained as compared to the joint of the connecting member 110 shown in FIG. 2A.

With the thus configured module 30, heat generated from the electrooptical component 200 does not conduct to the integrated circuit component 50, and Johnson noise of the integrated circuit component 50 is suppressed, with the result that a decrease in image quality is prevented.

### Example 1D

In FIG. 5B, FR-4 that is glass epoxy resin is used for the wiring board 1001. The outer shape has a size of 43 mm by 50 mm and has a thickness of 0.5 mm. The conductor layer is made of copper foil and is made up of four layers. A plurality of electrodes for connection with the electrooptical component 200 is provided in the first layer of the conductor layer. The electrodes include the power supply electrode 911 and the grounding electrode 912 for supplying electric power that actuates the electrooptical component 200. Electrodes for connection with the connecting member 110 are provided in the fourth layer of the conductor layer. The diameter of each of the electrodes for connection with the connecting member 110 is 0.3 mm, and the electrodes are formed with the closest pitch of 0.6 mm. Among the electrodes for connection with the connecting member 110, the closest pair of electrodes is the power supply electrode 921 and the grounding electrode 922. The power supply electrode 911 and the power supply electrode 921 are electrically continuous with wiring lines and vias provided in the wiring board 1001.

The electrooptical component 200 has a size of about 30 mm by 40 mm and has a thickness of 0.7 mm. The electrooptical component 200 is fixed to the wiring board 1001 by die bonding and connected to the electrodes on the wiring board by bonding wires.

The lid 250 has a size of 40 mm by 50 mm and has a thickness of 0.5 mm. The lid 250 is bonded to the resin frame with a height of 1 mm and a width of 1 mm in order not to contact with the electrooptical component 200. The frame is bonded to the surface of the wiring board 1001.

FR-4 that is glass epoxy resin is used for the wiring board 1002. The outer shape has a size of 43 mm by 50 mm and has a thickness of 0.5 mm. The conductor layer is made of copper foil and is made up of four layers. Chip components, such as a memory that is an integrated circuit component, capacitors, and resistors, and electrodes for connection with the connecting members 110 are provided in the first layer of the conductor layer. The diameter of each of the electrodes for connection with the connecting member 110 is 0.3 mm, and the electrodes are formed with the closest pitch of 0.6 mm. The electrodes for connection with the connecting member 110 are the power supply electrode 921 of the wiring board 1001 and the power supply electrode 931.

Each of the memories that are the integrated circuit components has a ball grid array (BGA) structure and has a size of 14 mm by 14 mm and a thickness of 1.2 mm. Solder balls provided on the lower surface of the memory are respectively joined to the electrodes provided on the wiring board 1002.

Electrodes for connection with the integrated circuit component 50 are provided in the fourth layer of the conductor layer.

The integrated circuit component 50 has a size of 3 mm by 3 mm and a thickness of 0.7 mm. A connection electrode is provided on the lower surface of the component and is joined via the conductive member 99 to the power supply electrode 941 provided in the wiring board 1002. The power supply electrode 931 and the power supply electrode 941 are electrically continuous with wiring lines and vias provided in the wiring board 1002.

As shown in FIG. 3A, the connecting member 110 has a frame shape. The outer shape has a size of 34 mm by 44 mm, and the frame has a width of 1.6 mm and a thickness of 2 mm. FR-4 that is glass epoxy resin is used as an insulator. A plurality of conductive portions is provided on the upper surface and the lower surface of the connecting member 110. The conductive portions on the opposite upper and lower sides are continuous by the conductor parts 97 of the connecting member 110. Continuity between the upper and lower sides is obtained by forming through holes and applying Cu plating. The upper and lower ends of each of the through holes are applied with copper plating such that the hole is buried. Thus, a lid is formed to serve as an electrode. The diameter of each of the electrodes is 0.3 mm, and the electrodes are formed with the closest pitch of 0.6 mm.

Electrodes formed on the upper surface of the connecting member 110 are joined to the wiring board 1001 by the conductive members 99. Electrodes formed on the lower surface are joined to the wiring board 1002 by the conductive members 99.

As shown in FIG. 5B, electric power that actuates the electrooptical component 200 is supplied from the integrated circuit component 50 joined on the wiring board.

The path runs from the electrode pair (the power supply electrode 941 and the grounding electrode 942), to which the integrated circuit component 50 is connected, to the power supply electrode 931 and the grounding electrode 932 through the power supply wiring line 981 and the grounding wiring line 982 of the wiring board 1002 in the wiring board 1002. Subsequently, the path runs through the conductor parts 97 (the power supply wiring line 971 and the grounding wiring line 972) connecting the upper and lower electrodes of the connecting member 110 and reaches the power supply electrode 921 and the grounding electrode 922. Subsequently, the path runs from the power supply electrode 921 and the grounding electrode 922, passes through the power supply wiring line 961 and the grounding wiring line 962 of the wiring board 1002, and reaches the power supply electrode 911 and the grounding electrode 912 in the wiring board 1001. Then, the path runs from the power supply electrode 911 and the grounding electrode 912, passes through the conductive member 901 and the conductive member 902, and reaches the electrooptical component 200.

As shown in FIGS. 5B and 4A to 4C, a spaced distance Da between the power supply electrode 921 and the grounding electrode 922 is 0.6 mm that is the closest pitch, and the dimensions of the electrooptical component 200 in a plan view are 30 mm by 40 mm. In the structure, when the above expression (1) is satisfied, the area of the closed loop is reduced, and image quality is improved.

With the thus configured module 30, heat generated from the electrooptical component 200 does not conduct to the integrated circuit component 50, and Johnson noise of the integrated circuit component 50 is suppressed, with the result that a decrease in image quality is also prevented.

### Example 1E

In FIG. 5C, FR-4 that is glass epoxy resin is used for the wiring board 1001. The outer shape has a size of 43 mm by 50 mm and has a thickness of 0.5 mm. The conductor layer is made of copper foil and is made up of four layers. A plurality of electrodes for connection with the electrooptical component 200 is provided in the first layer of the conductor layer. The electrodes include the power supply electrode 911 and the grounding electrode 912 for supplying electric power that actuates the electrooptical component 200. Electrodes for connection with the connecting member 110 are provided in the fourth layer of the conductor layer. The diameter of each of the electrodes for connection with the connecting member 110 is 0.3 mm, and the electrodes are formed with the closest pitch of 0.6 mm. Among the electrodes for connection with the connecting member 110, the closest pair of electrode is the power supply electrode 921 and the grounding electrode 922. The power supply electrode 911 and the grounding electrode 912 are respectively electrically continuous with the power supply electrode 921 and the grounding electrode 922 by the power supply wiring line 961 and the grounding wiring line 962 provided in the wiring board 1001.

The electrooptical component 200 has a size of about 30 mm by 40 mm and has a thickness of 0.7 mm. The electrooptical component 200 is fixed to the wiring board 1001 by die bonding and connected to the electrodes on the wiring board by bonding wires.

The lid 250 has a size of 40 mm by 50 mm and has a thickness of 0.5 mm. The lid 250 is bonded to the resin frame with a height of 1 mm and a width of 1 mm in order not to contact with the electrooptical component 200. The frame is bonded to the surface of the wiring board 1001.

FR-4 that is glass epoxy resin is used for the wiring board 1002. The outer shape has a size of 43 mm by 50 mm and has a thickness of 0.5 mm. The conductor layer is made of copper foil and is made up of four layers. Chip components, such as a memory that is an integrated circuit component, capacitors, and resistors, and electrodes for connection with the connecting members 110 are provided in the first layer of the conductor layer. The diameter of each of the electrodes for connection with the connecting member 110 is 0.3 mm, and the electrodes are formed with the closest pitch of 0.6 mm. Among the electrodes for connection with the connecting member 110, an electrode opposed in pair with the power supply electrode 921 of the wiring board 1001 is the power supply electrode 931.

The power supply electrode 941 for connection with the integrated circuit component 50 is provided in the same plane and is electrically connected to the power supply electrode 931 by a wiring line.

The integrated circuit component 50 has a size of 3 mm by 3 mm and a thickness of 0.7 mm. A connection electrode is provided on the lower surface of the component and is joined via the conductive member 99 to the power supply electrode 941.

Each of the memories that are the integrated circuit components has a ball grid array (BGA) structure and has a size of 14 mm by 14 mm and a thickness of 1.2 mm. Solder balls provided on the lower surface of the memory are respectively joined to the electrodes provided on the wiring board 1002.

As shown in FIG. 3A, the connecting member 110 has a frame shape. The outer shape has a size of 34 mm by 44 mm, and the frame has a width of 1.6 mm and a thickness of 2 mm. FR-4 that is glass epoxy resin is used as an insulator. A plurality of conductive portions is provided on the upper surface and the lower surface of the connecting member 110. The conductive portions on the opposite upper and lower sides are continuous by the conductor parts 97 of the connecting member 110. Continuity between the upper and lower sides is obtained by forming through holes and applying Cu plating. The upper and lower ends of each of the through holes are applied with copper plating such that the hole is buried. Thus, a lid is formed to serve as an electrode. The diameter of each of the electrodes is 0.3 mm, and the electrodes are formed with the closest pitch of 0.6 mm.

Electrodes formed on the upper surface of the connecting member 110 are joined to the wiring board 1001 by the conductive members 99. Electrodes formed on the lower surface are joined to the wiring board 1002 by the conductive members 99.

As shown in FIG. 5C, electric power that actuates the electrooptical component 200 is supplied from the integrated circuit component 50 joined on the wiring board.

The path runs from the pair of fourth power supply electrodes, to which the integrated circuit component 50 is connected, passes through the wiring line of the wiring board, and reaches the power supply electrode 931 in the wiring board 1002. Subsequently, the path runs through the conductor part 97 connecting the upper and lower electrodes of the connecting member 110 and reaches the power supply electrode 921. Subsequently, the path runs from the power supply electrode 921 to the power supply electrode 911 through the wiring line and a first via conductor 961 of the wiring board and reaches the electrooptical component 200 through a bonding wire in the wiring board 1001.

As shown in FIGS. 5C and 4A to 4C, a spaced distance Da between the power supply electrode 921 and the grounding electrode 922 is 0.6 mm that is the closest pitch, and the dimensions of the electrooptical component 200 in a plan view are 30 mm by 40 mm. In the structure, when the above expression (1) is satisfied, the area of the closed loop is reduced, and image quality is improved.

In this Example, the integrated circuit component 50 mounted on the wiring board 1002 is disposed on the same surface with the connecting member 110, so the area of the closed loop can be reduced as compared to the structure shown in FIG. 5B.

With the thus configured module 30, heat generated from the electrooptical component 200 does not conduct to the integrated circuit component 50, and Johnson noise of the integrated circuit component 50 is suppressed, with the result that a decrease in image quality is also prevented.

### Example 1F

In Example 1F, the insulating separate part 120 is formed on the conductor parts 97 of the connecting member 110 of FIG. 3C in Example 1C, and the connecting member 110 as shown in FIG. 9A is used. In this Example, the separate part 120 is a solder resist having a thickness of 15 μm and has a width of 0.2 mm in the Z direction. Solder is used as the conductive members 99. The location of the separate part 120 is on a center part of the side surface of the connecting member 110. In the module 30 using this connecting member 110, as shown in FIG. 9B, the conductive members 99 can be connected to not only the upper and lower surfaces of the connecting member 110 but also the conductor parts 97 of the connecting member 110. The conductive members 99 separated by the separate part 120 for the conductor parts 97 of the connecting member and the electrodes of the wiring boards 1001, 1002 are good-shape solder fillets that draw smooth concave curves. For example, since the conductive members 99 are reliably separated at the center in the upper and lower surface direction by the separate part 121, the upper and lower solder fillets (the conductive member 991 and the conductive member 992) are equally formed. For example, the upper and lower solder fillets (the conductive member 993 and the conductive member 994) are equally formed by the separate part 122.

The length of each solder fillet can be independently controlled in the up and down direction by changing the location and width of the separate part 120 with respect to the conductive members in the up and down direction (Z direction). For this reason, high reliability is obtained as compared to the connecting portions of the connecting member 110 shown in FIG. 2C. With the thus configured module 30, heat generated from the electrooptical component 200 does not conduct to the integrated circuit component 50, and Johnson noise of the integrated circuit component 50 is suppressed, with the result that a decrease in image quality is also prevented.

### Embodiment 2I

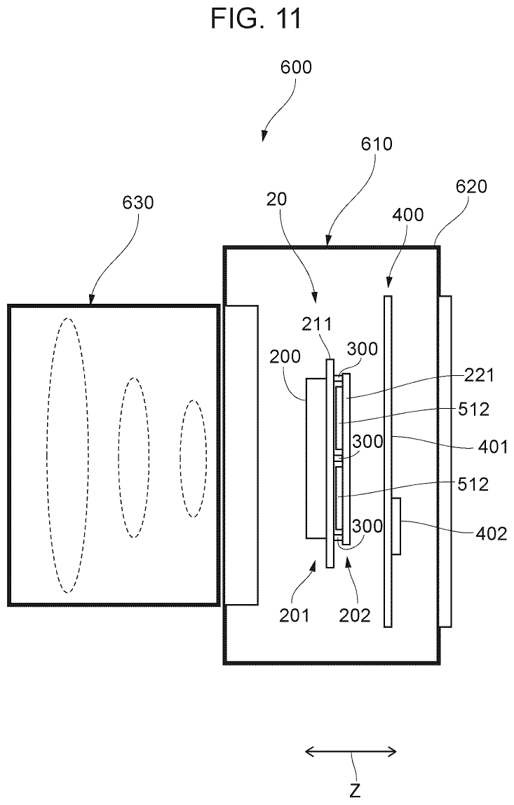

FIG. 11 is a diagram of a digital camera that is an image pickup apparatus serving as an example of an electronic apparatus 600 according to Embodiment 2I. The electronic apparatus 600 is a lens interchangeable digital camera and includes a camera body 610. A lens barrel 630 including lenses is detachably mounted to the camera body 610. The lens barrel 630 is an interchangeable lens, that is, a lens unit.

The camera body 610 includes a casing 620, and an image pickup module 20 and a processing module 400 provided inside the casing 620. The image pickup module 20 and the processing module 400 are electrically connected by a cable (not shown) so as to be communicable with each other.

The image pickup module 20 is an example of an electronic module and has a three-dimensional mounting structure. The image pickup module 20 includes circuit units 201, 202 and a plurality of intermediate connecting members 300. In the present embodiment, the circuit unit 201 is a first circuit unit, and the circuit unit 202 is a second circuit unit. The circuit unit 201 is a printed wiring board, a printed circuit board, or a semiconductor package and is a semiconductor package in the present embodiment. The circuit unit 202 is a printed wiring board, a printed circuit board, or a semiconductor package and is a printed circuit board in the present embodiment. The circuit unit 201 and the circuit unit 202 are disposed with a space from each other in the Z direction that is a lamination direction and are electrically and mechanically connected by the plurality of intermediate connecting members 300. In other words, each intermediate connecting member 300 is used to electrically and mechanically connect the circuit units 201, 202 opposed to each other in the Z direction.

The circuit unit 201 includes a wiring board 211 and the electrooptical component 200 that is an example of a first electronic component mounted on the wiring board 211. The wiring board 211 is a package board.

The wiring board 211 is also a rigid board. The electrooptical component 200 is a semiconductor element, an image pickup element, and an integrated circuit component.

The circuit unit 202 includes a wiring board 221 and a plurality of integrated circuit components 512 that are examples of a second electronic component mounted on the wiring board 221. The wiring board 221 is a printed wiring board. The wiring board 221 is also a rigid board. The integrated circuit components 512 are semiconductor elements, such memories, processors, and controllers, and are memories capable of storing image data in the present embodiment. Electronic components, that is, the integrated circuit components 512 mounted on the wiring board 221 in the present embodiment, are disposed between the wiring board 211 and the wiring board 221. Thus, in the present embodiment, the wiring board 211 and the wiring board 221 are electrically and mechanically connected by the plurality of intermediate connecting members 300 such that the integrated circuit components 512 do not interfere with the wiring board 211.

The electrooptical component 200 is, for example, an image sensor, such as a complementary metal oxide semiconductor (CMOS) image sensor and a charge coupled device (CCD) image sensor. The electrooptical component 200 has a function to convert light incoming via the lens barrel 630 to an electrical signal. The electrooptical component 200 may be a display, such as an organic EL panel and a liquid crystal panel.

The processing module 400 includes a printed wiring board 401 and an image processing apparatus 402 that is a semiconductor apparatus mounted on the printed wiring board 401. The image processing apparatus 402 is, for example, a digital signal processor. The image processing apparatus 402 has a function to acquire an electrical signal from the electrooptical component 200, execute a process of correcting the acquired electrical signal, and generate image data.

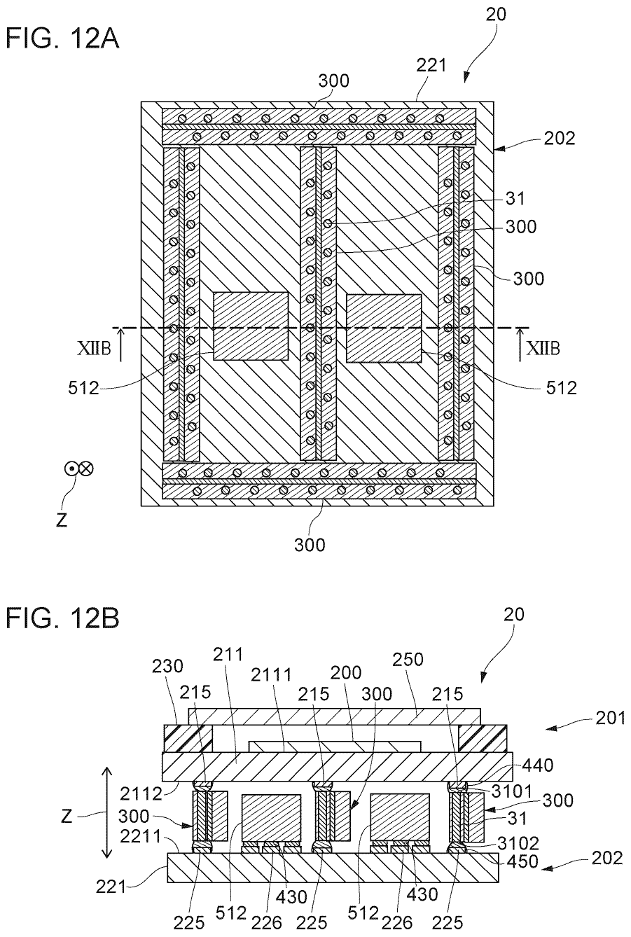

FIG. 12A is a plan view of the image pickup module 20. FIG. 12B is a sectional view of the image pickup module 20. In FIG. 12A, for the sake of illustration, the circuit unit 201 is not shown. FIG. 12B is a sectional view of the image pickup module 20, taken along the line XIIB-XIIB in FIG. 12A. The circuit unit 201 of the image pickup module 20 includes a frame 230 provided on the wiring board 211 and a lid 250 provided on the frame 230. For example, a substrate made of glass is used as the lid 250.

The plurality of intermediate connecting members 300 is disposed so as to surround the plurality of integrated circuit components 512.

In the present embodiment, the number of the intermediate connecting members 300 is five, and the number of the integrated circuit components 512 is two.

In the wiring board 211, a plurality of pads 215 is disposed on a principal surface 2112 on an opposite side to a principal surface 2111 on a side where the electrooptical component 200 is mounted. A solder resist film (not shown) may be provided on the principal surface 2112. At this time, the solder resist film preferably has openings at locations corresponding to the pads 215. The shape of each pad 215 is not limited and may be, for example, a circular shape or a polygonal shape in a plan view. The relationship between the solder resist film and the pads may be any one of SMD and NSMD. A resin having a low thermal expansion coefficient is used for the insulating material of an insulating substrate of the wiring board 211.

In the wiring board 221, a plurality of pads 225 and a plurality of pads 226 are disposed on a principal surface 2211 on a side where the integrated circuit components 512 are mounted. The plurality of integrated circuit components 512 is joined to the plurality of pads 226 by solder 430. A solder resist film (not shown) may be provided on the principal surface 2211. At this time, the solder resist film preferably has openings at locations corresponding to the pads 225, 226. The shape of each of the pads 225, 226 is not limited and may be, for example, a circular shape or a polygonal shape in a plan view. The relationship between the solder resist film and the pads may be any one of SMD and NSMD. A resin, such as FR-4, is used for the insulating material of an insulating substrate of the wiring board 221.

Each intermediate connecting member 300 has a plurality of wiring parts 31 extending in the Z direction. Both end faces 3101, 3102 of each wiring part 31 in the Z direction are exposed to outside. The end face 3101 and the pad 215 are electrically and mechanically connected by solder 440. The end face 3102 and the pad 225 are electrically and mechanically connected by solder 450.

Each of the pads 215, 225, 226 is an electrode that is made of a metal, such as copper, and that is a member having electrical conductivity. Each of the pads 215, 225, 226 is, for example, a signal electrode, a power supply electrode, a ground electrode, or a dummy electrode.

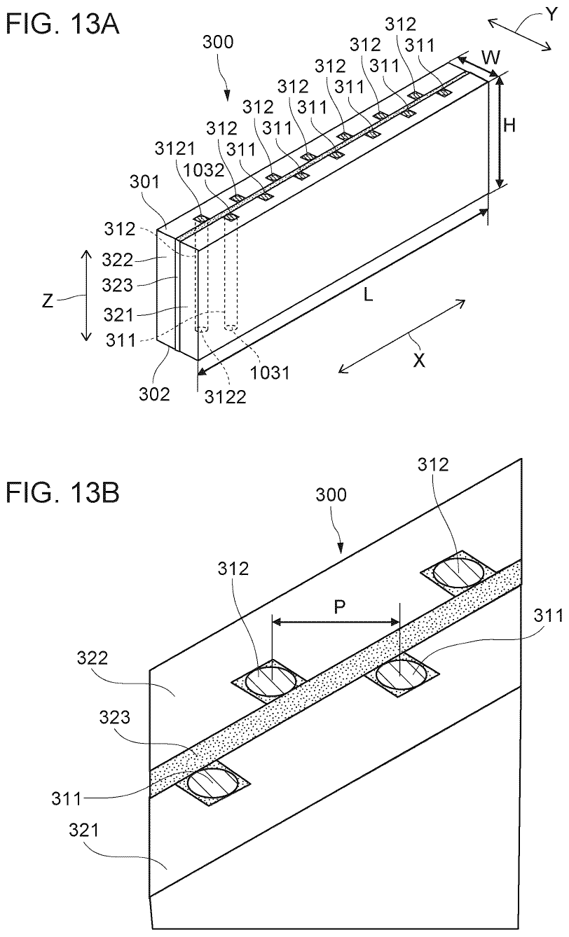

FIG. 13A is a perspective view of the intermediate connecting member 300 according to Embodiment 2I. FIG. 13B is a partially enlarged view of the intermediate connecting member 300 shown in FIG. 13A.

The intermediate connecting member 300 is a rectangular parallelepiped rigid board and has the pair of end faces 301, 302 in the Z direction, used for joining. Here, a longitudinal direction of the intermediate connecting member 300 is the X direction, a width direction of the intermediate connecting member 300 is the Y direction, and a height direction of the intermediate connecting member 300 is the Z direction. The Z direction is a first direction, the X direction is a second direction, and the Y direction is a third direction. The X direction, the Y direction, and the Z direction intersect with one another. In the present embodiment, the X direction, the Y direction, and the Z direction are orthogonal to one another.

The intermediate connecting member 300 has a plurality of wiring parts 311 that are a plurality of first wiring parts and a plurality of wiring parts 312 that are a plurality of second wiring parts. The plurality of wiring parts 31 of FIGS. 12A and 12B is made up of the plurality of wiring parts 311 and the plurality of wiring parts 312.

The intermediate connecting member 300 has an insulating substrate part 321 that is a first insulating substrate part and an insulating substrate part 322 that is a second insulating substrate part. The intermediate connecting member 300 has an insulating layer part 323 disposed between the insulating substrate part 321 and the insulating substrate part 322 and different in material from the insulating substrate part 321 or the insulating substrate part 322.

The plurality of wiring parts 311 is disposed between the insulating substrate part 321 and the insulating layer part 323.

The plurality of wiring parts 311 is disposed with a space from each other in the X direction. The plurality of wiring parts 311 is disposed so as to extend in the Z direction. Thus, a lower surface terminal 1031 and an upper surface terminal 1032 that are both end faces in the Z direction of each of the plurality of wiring parts 311 are exposed to outside at the end faces 301, 302 of the intermediate connecting member 300 so that the lower surface terminal 1031 and the upper surface terminal 1032 can be joined to the wiring boards 211, 221 by solder.

The plurality of wiring parts 312 is disposed between the insulating substrate part 322 and the insulating layer part 323.

The plurality of wiring parts 312 is disposed with a space from each other in the X direction. The plurality of wiring parts 312 is disposed so as to extend in the Z direction. Thus, an upper surface terminal 3121 and a lower surface terminal 3122 that are both end faces in the Z direction of each of the plurality of wiring parts 312 are exposed to outside at the end faces 301, 302 of the intermediate connecting member 300 so that the upper surface terminal 3121 and the lower surface terminal 3122 can be joined to the wiring boards 211, 221 by solder.

The plurality of wiring parts 311 and the plurality of wiring parts 312 are alternately disposed in the X direction. The insulating layer part 323 is disposed between the plurality of wiring parts 311 and the plurality of wiring parts 312. In other words, the plurality of wiring parts 311 and the plurality of wiring parts 312 are disposed with a space from each other in the Y direction. Thus, the plurality of wiring parts 311 and the plurality of wiring parts 312 are arranged in a staggered manner in the X direction. By arranging the plurality of wiring parts 311 and the plurality of wiring parts 312 in a staggered manner in this way, further high-density wiring can be achieved, with the result that a reduction in the size of the image pickup module 20 can be achieved. However, when high-density wiring is not needed, the plurality of wiring parts 311 and the plurality of wiring parts 312 may be arranged not in a staggered manner but may be arranged so as to be opposed to each other.

The insulating layer part 323 is formed as a result of solidification, that is, curing, of an adhesive. In other words, the intermediate connecting member 300 is formed when the insulating substrate part 321, the insulating substrate part 322, the plurality of wiring parts 311, and the plurality of wiring parts 312 are integrated by the insulating layer part 323.

The insulating substrate part 321 and the insulating substrate part 322 are made of the same insulating material. The insulating material of the insulating substrate part 321 and the insulating substrate part 322 is glass epoxy. Glass epoxy is, for example, formed in a manner such that glass woven fabric obtained by weaving glass fibers into a cloth form is impregnated with liquid epoxy resin and thermally cured. Glass epoxy is also called epoxy glass or epoxy glass resin. The insulating layer part 323 is, for example, formed as a result of solidification of an adhesive containing epoxy resin or silicone resin as a main component. Each of the wiring parts 311, 312 is made of a conductive material, for example, copper.

The plurality of wiring parts 311 is formed so as to have the same thickness. Thus, of the plurality of wiring parts 311, wiring lines through which large current flows, for example, the wiring parts that become ground wiring lines, may be made of a material different from those of the other wiring parts, that is, a material having a low electrical resistance. The same applies to the plurality of wiring parts 312.

The length L of the intermediate connecting member 300 in the X direction is shorter than the lengths of the wiring boards 211, 221. The width W of the intermediate connecting member 300 in the Y direction depends on the areas of the principal surfaces 2112, 2211 of the wiring boards 211, 221 and a method of manufacturing the image pickup module 20.

In a case where the intermediate connecting members 300 are self-supported on the wiring board 221 and the intermediate connecting members 300 are soldered to the wiring board 221 in a manufacturing process, the width W of each intermediate connecting member 300 is preferably greater than or equal to 1 mm. In consideration of high-density mounting, the width W of each intermediate connecting member 300 is preferably less than or equal to 5 mm.

Of the electronic components to be mounted on the principal surface 2211 side of the wiring board 221, the highest electronic component is the integrated circuit component 512. The height H of the intermediate connecting member 300 in the Z direction is preferably made greater than the integrated circuit component 512. For example, in a case where the height of the integrated circuit component 512 in the Z direction is 1.6 mm, the height H of the intermediate connecting member 300 is preferably greater than 1.6 mm.

Of the plurality of wiring parts 311 and the plurality of wiring parts 312, the pitch P between the closest two wiring parts 311, 312 is preferably greater than or equal to 0.36 mm and less than or equal to 0.44 mm. Thus, the intermediate connecting members 300 can be highly accurately manufactured while the narrow pitch between the wiring parts 311, 312 is achieved.

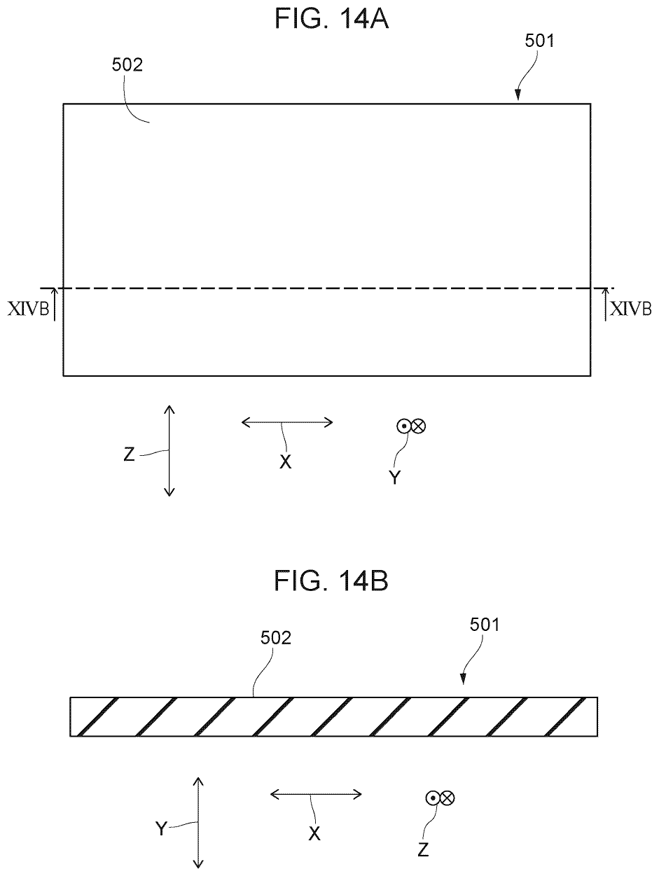

A manufacturing method for the intermediate connecting member 300 will be described. FIGS. 14A, 14B, 15A, 15B, 15C, 16A, 16B, 16C, 17A, 17B, 17C, 18A, and 18B are diagrams for illustrating steps of the manufacturing method for the intermediate connecting member 300.

In the step shown in FIGS. 14A and 14B, a sheet-shaped base material 501 is prepared. FIG. 14A is a plan view of the base material 501. FIG. 14B is a sectional view of the base material 501, taken along the line XIVB-XIVB in FIG. 14A. Although not shown in the drawing, two base materials 501 are prepared. The base material 501 is made of an insulating material, such as glass epoxy, for example, FR-4. The thickness W of the intermediate connecting member 300 shown in FIG. 13A is preferably less than or equal to 5 mm. For this reason, the thickness of the base material 501 is preferably less than or equal to 2.5 mm.

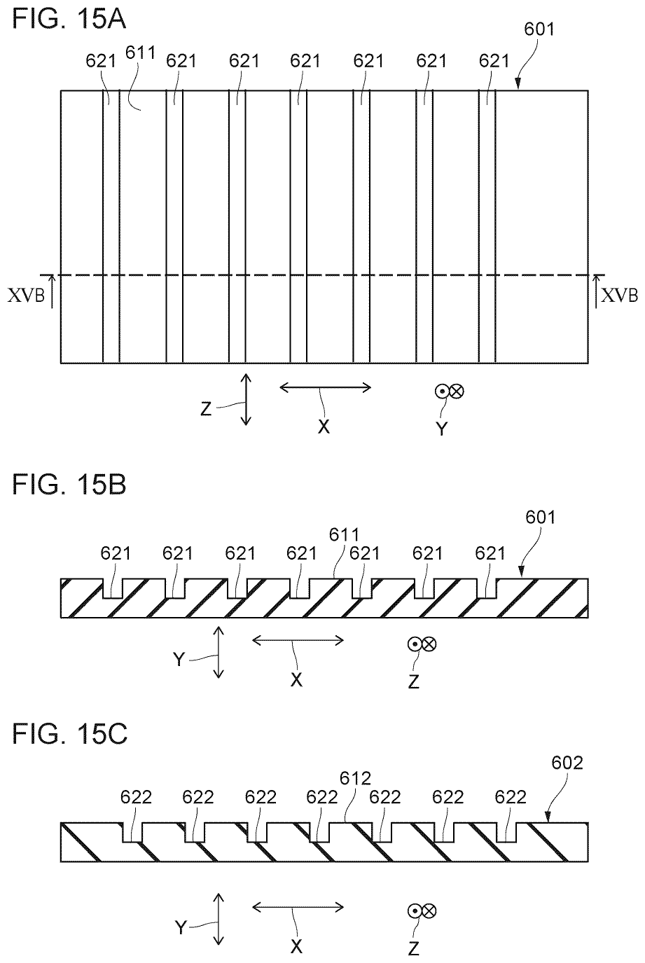

Subsequently, a plurality of grooves is formed on the principal surfaces 502 of the two base materials 501 by working. Thus, in the step shown in FIGS. 15A and 15B, an insulating substrate 601 having a principal surface 611 with a plurality of grooves 621 is formed. FIG. 15A is a plan view of the insulating substrate 601. FIG. 15B is a sectional view of the insulating substrate 601, taken along the line XVB-XVB in FIG. 15A. The grooves 621 are first grooves. The principal surface 611 is a first principal surface. The insulating substrate 601 is a first insulating substrate.

Similarly, in the step shown in FIG. 15C, an insulating substrate 602 having a principal surface 612 with a plurality of grooves 622 is formed. FIG. 15C is a sectional view of the insulating substrate 602. The grooves 622 are second grooves. The principal surface 612 is a second principal surface. The insulating substrate 602 is a second insulating substrate.

The plurality of grooves 621 is formed so as to extend in the Z direction with a space from each other in the X direction. The plurality of grooves 622, as in the case of the plurality of grooves 621, is formed so as to extend in the Z direction with a space from each other in the X direction. The plurality of grooves 621 and the plurality of grooves 622 are formed in a linear shape in the present embodiment and may be formed in a curved shape.

The width and depth of each of the grooves 621, 622 are set according to the thickness of each of the wiring parts 311, 312 intended to be formed. For example, if the thickness of a wire (described later) is φ0.2 mm, the width and depth of each of the grooves 621, 622 are preferably set to about 0.2 mm same as the thickness of the wire. The pitch of the plurality of grooves 621 and the pitch of the plurality of grooves 622 are preferably set to the same pitch, and, for example, each pitch is set to about 0.57 mm.

The sectional shape of each of the grooves 621, 622 is a rectangular shape in the present embodiment; however, the configuration is not limited thereto. The sectional shape may be, for example, a semicircular shape. Work for forming the grooves 621, 622 is suitably machining using a dicer apparatus or a slicer apparatus. Alternatively the base material 501 may be masked with a resist or the like, and may be physically worked with a milling apparatus. The insulating substrates 601, 602 may be molded by using a metal mold having a shape for forming grooves. Forming an insulating substrate having a plurality of grooves close to each other is easier than forming an insulating substrate having a plurality of through holes close to each other. Therefore, the insulating substrate 601 having the plurality of grooves 621 and the insulating substrate 602 having the plurality of grooves 622 can be formed with high accuracy.

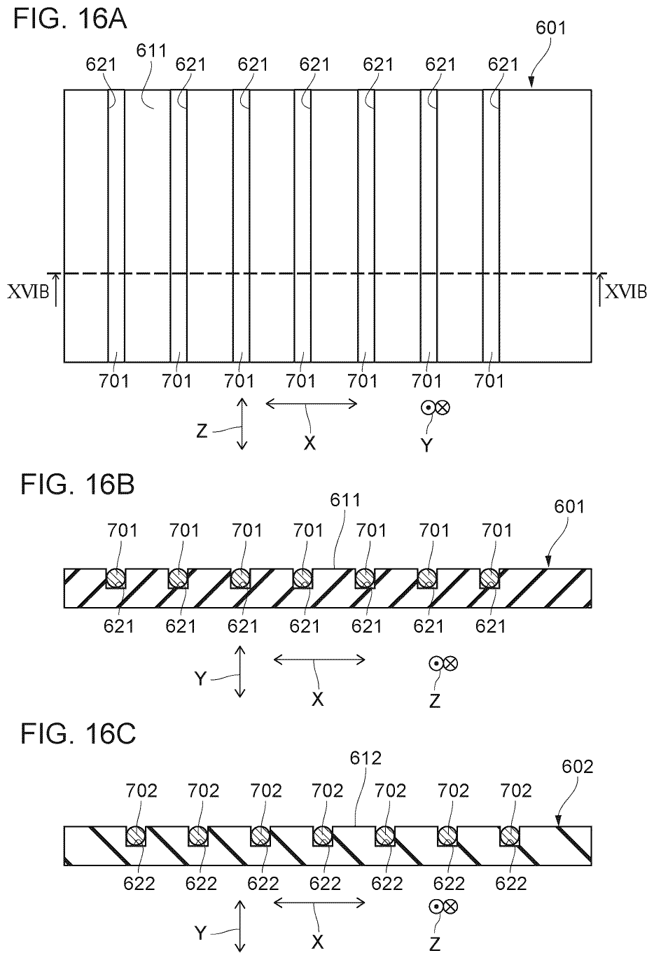

Subsequently, in the step shown in FIGS. 16A and 16B, a plurality of conductive members 701 is respectively disposed in the plurality of grooves 621. FIG. 16A is a plan view of the insulating substrate 601 in which the plurality of conductive members 701 is disposed. FIG. 16B is a sectional view of the insulating substrate 601 in which the plurality of conductive members 701 is disposed, taken along the line XVIB-XVIB in FIG. 16A. The conductive members 701 are first conductive members. Similarly, in the step shown in FIG. 16C, a plurality of conductive members 702 is respectively disposed in the plurality of grooves 622. FIG. 16C is a sectional view of the insulating substrate 602 in which the plurality of conductive members 702 is disposed. The conductive members 702 are second conductive members.

Each of the plurality of conductive members 701 and each of the plurality of conductive members 702 are wires made of a metal, such as copper. The diameter of each conductive member 701 is set to the same diameter in the present embodiment. The diameter of each conductive member 702 is also set to the same diameter in the present embodiment. The diameter of each conductive member 701 and the diameter of each conductive member 702 are also set to the same diameter in the present embodiment.

The sectional shape of the wire is a circular shape in the present embodiment; however, the sectional shape is not limited thereto. The sectional shape of the wire may be a polygonal shape, such as a quadrangular shape. In the step shown in FIGS. 16A and 16B, the plurality of conductive members 701 is respectively fitted to the plurality of grooves 621. In the step shown in FIG. 16C, the plurality of conductive members 702 is respectively fitted to the plurality of grooves 622. Thus, in the following step, falling of each conductive member 701 from a corresponding one of the grooves 621 of the insulating substrate 601 is prevented, and falling of each conductive member 702 from a corresponding one of the grooves 622 of the insulating substrate 602 is prevented.

At the time of fitting each conductive member 701 to a corresponding one of the grooves 621, an adhesive (not shown) may be applied to each groove 621. Similarly, at the time of fitting each conductive member 702 to a corresponding one of the grooves 622, an adhesive (not shown) may be applied to each groove 622. The adhesive to be selected is preferably the one that is cured at room temperature. Thus, falling of each conductive member 701 from a corresponding one of the grooves 621 of the insulating substrate 601 is effectively prevented, and falling of each conductive member 702 from a corresponding one of the grooves 622 of the insulating substrate 602 is effectively prevented.

A method of disposing the conductive members 701, 702 in the grooves 621, 622 is suitably fitting wires to grooves; however, the method is not limited thereto. For example, conductive members may be formed by applying conductive pastes to the grooves with a dispenser or the like and firing the conductive pastes. The material of the conductive members 701, 702 just needs to be a material having electrical conductivity. The material of the conductive members 701, 702 may be, for example, an inorganic material, such as copper, silver, and aluminum, or may be an organic material, such as rubber having electrical conductivity.

The thickness of each of the conductive members 701, 702 is preferably greater than or equal to 0.05 mm and less than or equal to 2 mm in consideration of joint characteristics by solder with the pads of the wiring boards 211, 221 and handling and deformation of the conductive members 701, 702 at the time when the conductive members 701, 702 are disposed in the grooves 621, 622. In consideration of high-density wiring, the thickness of each of the conductive members 701, 702 is more preferably less than or equal to 0.5 mm.

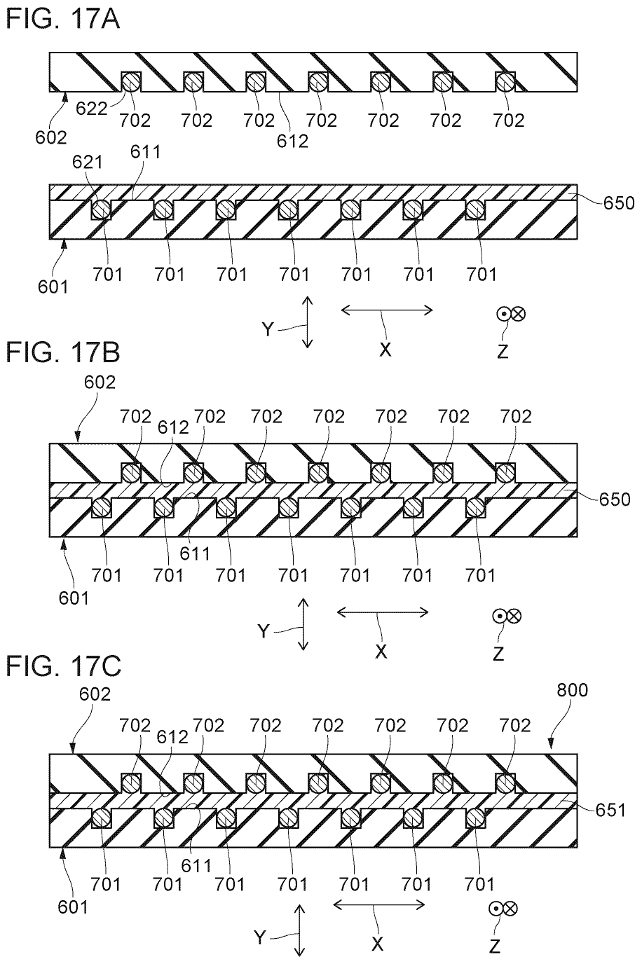

Next, a step of forming a structure 800, shown in FIGS. 17A to 17C, will be described. In this series of steps, the structure 800 is formed by bonding the principal surface 611 of the insulating substrate 601 to the principal surface 612 of the insulating substrate 602 via an insulating member 651 such that a direction in which the plurality of conductive members 701 extends is aligned with a direction in which the plurality of conductive members 702 extends. In this series of steps, the structure 800 is formed by bonding the principal surface 611 of the insulating substrate 601 to the principal surface 612 of the insulating substrate 602 such that the plurality of conductive members 701 and the plurality of conductive members 702 are alternately disposed in the X direction.

Hereinafter, the step of forming the structure 800 will be described in detail with reference to FIGS. 17A to 17C. Initially, in the step shown in FIG. 17A, an adhesive 650 is applied onto the principal surface 611 of the insulating substrate 601. The adhesive 650 is an adhesive having an insulation property and containing, for example, epoxy resin or silicone resin as a main component. The selectable adhesive 650 is, for example, thermally cured at about 100° C.

Subsequently, in the step shown in FIG. 17B, before the adhesive 650 is cured, the principal surface 612 of the insulating substrate 602 is brought into contact with the adhesive 650, and the adhesive 650 is sandwiched by the principal surface 611 and the principal surface 612. The insulating substrate 601 and the insulating substrate 602 are aligned by an alignment device (not shown). Thus, while the thickness of the adhesive 650 is controlled, the principal surface 611 of the insulating substrate 601 and the principal surface 612 of the insulating substrate 602 are bonded to each other with the plurality of conductive members 701 and the plurality of conductive members 702 interposed therebetween. Alignment between the insulating substrate 601 and the insulating substrate 602 may be performed by bringing the end faces of the insulating substrates 601, 602 into contact with an abutment member (not shown) or may be performed by using a preformed alignment mark (not shown). Alternatively, for the purpose of controlling the thickness of the adhesive 650, the adhesive may contain an insulating spacer (thickness regulator).

Then, in the step shown in FIG. 17C, the insulating member 651 is formed by curing the adhesive 650. In this way, by bonding the principal surface 611 of the insulating substrate 601 to the principal surface 612 of the insulating substrate 602 with the adhesive 650, the insulating member 651 in which the adhesive 650 is solidified is formed.

In the present embodiment, the intermediate connecting member 300 is formed by working to form the structure 800. The insulating substrate 601 in the structure 800 corresponds to the insulating substrate part 321 in the intermediate connecting member 300. The insulating substrate 602 in the structure 800 corresponds to the insulating substrate part 322 in the intermediate connecting member 300. The insulating member 651 in the structure 800 corresponds to the insulating layer part 323 in the intermediate connecting member 300. The conductive members 701 in the structure 800 correspond to the wiring parts 311 in the intermediate connecting member 300. The conductive members 702 in the structure 800 correspond to the wiring parts 312 in the intermediate connecting member 300.

The thickness in the Y direction of the insulating member 651 that will be the insulating layer part 323 is preferably greater than or equal to 10 μm from the viewpoint of suppressing peeling of the insulating substrate parts 321, 322 of FIG. 13A in a subsequent reflow step. When the thickness in the Y direction of the insulating member 651 is less than 10 μm, there are concerns that the insulating substrate parts 321, 322 peel off from each other or the conductive members 701, 702 are short-circuited in a case where the conductive members 701, 702 are disposed so as to be opposed to each other. The thickness in the Y direction of the insulating member 651 that will be the insulating layer part 323 is preferably less than or equal to 300 μm in consideration of a deformation or the like of the conductive members. When the thickness in the Y direction of the insulating member 651 exceeds 300 μm, there are concerns that the conductive members deform or the insulating layer part 323 cannot have sufficient mechanical strength due to moisture absorption. In other words, the thickness in the Y direction of the insulating member 651 that will be the insulating layer part 323 is preferably greater than or equal to 10 μm and less than or equal to 300 μm. Thus, the thickness in the Y direction of the insulating layer part 323 is preferably greater than or equal to 10 μm and less than or equal to 300 μm.

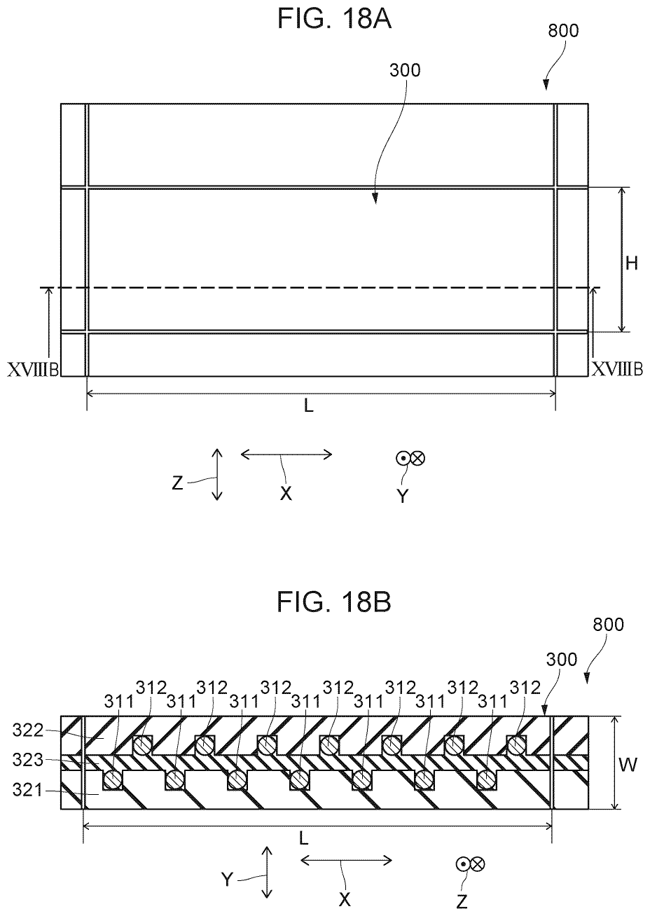

Subsequently, in the step shown in FIGS. 18A and 18B, the structure 800 is cut in the X direction. FIG. 18A is a plan view of the structure 800. FIG. 18B is a sectional view of the structure 800, taken along the line XVIIIB-XVIIIB in FIG. 18A. By cutting the structure 800 in the X direction with an interval of H in the Z direction, terminals 1031, 1032, 3121, 3122 that are end faces of the wiring parts 311, 312 shown in FIG. 13A are exposed. In the present embodiment, by cutting the structure 800 in the X direction and in the Z direction, the intermediate connecting member 300 with a predetermined size, that is, the length L, the height H, and the width W is formed. For example, the intermediate connecting member 300 in which the thickness in the Y direction of each of the insulating substrate parts 321, 322 is 0.5 mm, the thickness in the Y direction of the insulating layer part 323 is 0.085 mm, the length L is 41.0 mm, the height H is 2.0 mm, and the width W is 1.085 mm is formed. A dicer apparatus, a wire saw apparatus, or the like is used to cut the structure 800. In this step, a single intermediate connecting member 300 may be formed from a single structure 800 or a plurality of intermediate connecting members 300 may be formed from a single structure 800. In a case where a plurality of intermediate connecting members 300 is formed from a single structure 800, the single structure 800 may be cut along the X direction at equal intervals with a pitch of H in the Z direction. Alternatively, the single structure 800 may be cut along the Z direction at equal intervals with a pitch of L in the X direction.

A direction in which the structure 800 is cut may be an oblique direction with respect to the conductive members 701, 702. In this case, the end face of each wiring part to be formed has an elliptical shape and has a larger sectional area than that in a case of a circular shape, so a joint area with solder can be expanded.

Through the above-described manufacturing process, the intermediate connecting member 300 in which the wiring parts 311, 312 are disposed with high accuracy as shown in FIG. 13A is obtained. In addition, the intermediate connecting member 300 with high accuracy, including the wiring parts 311, 312 disposed with a narrow pitch with high density, is obtained.

Here, of the plurality of wiring parts 311 and the plurality of wiring parts 312, the pitch of the closest two wiring parts is defined as P. A ratio H/P of the height H in the Z direction of the intermediate connecting member 300 to the pitch P is preferably higher than or equal to four. For example, where the pitch P is 0.4 mm and the height H is 2.0 mm, the ratio H/P is five. In this way, while the wiring parts 311, 312 are formed with high density, the intermediate connecting member 300 having a tall height H can be formed.

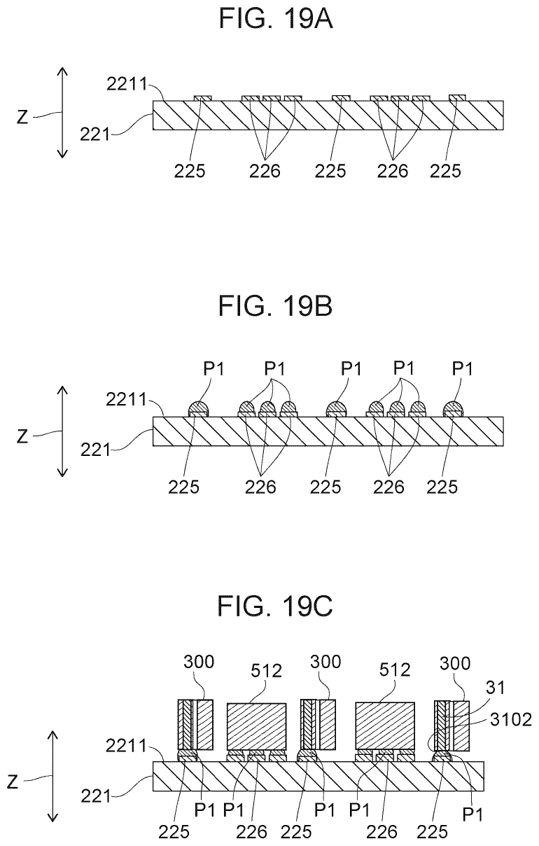

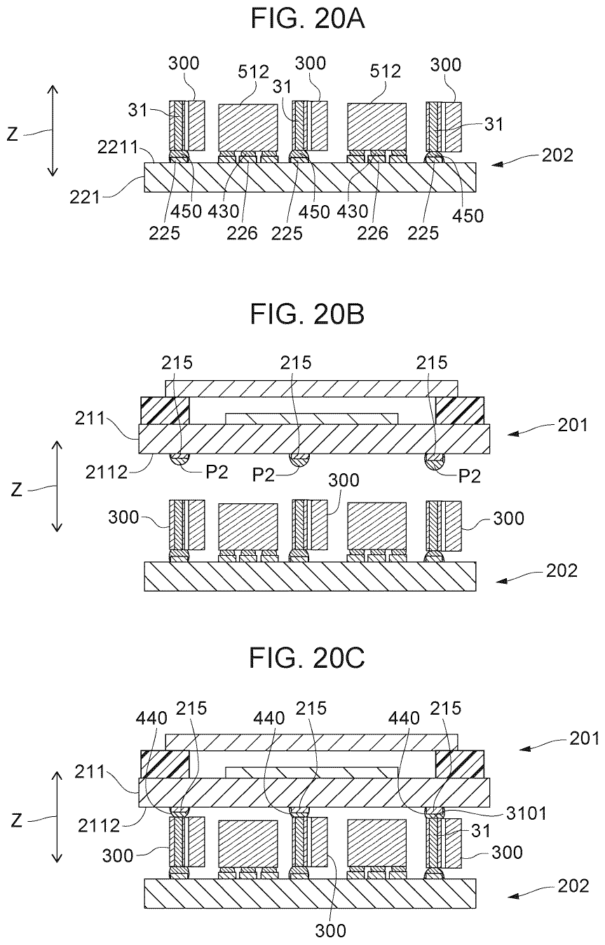

Next, a manufacturing method for the image pickup module 20 will be described. FIGS. 19A, 19B, 19C, 20A, 20B, and 20C are diagrams for illustrating the steps of the manufacturing method for the image pickup module 20 according to Embodiment 2I.

As shown in FIG. 19A, the wiring board 221 is prepared. Subsequently, as shown in FIG. 19B, solder pastes P1 containing solder powder and flux are respectively supplied onto pads 225, 226 of the wiring board 221. For example, Sn—Ag—Cu solder powder is used as the solder powder. The solder pastes P1 can be supplied, for example, by screen printing or with a dispenser.

The solder paste P1 may be supplied so as to cover the entire surface of each of the pads 225, 226 or may be supplied so as to partially cover each of the pads 225, 226 as in the case of so-called offset printing.

Subsequently, as shown in FIG. 19C, the integrated circuit components 512, the intermediate connecting members 300, and chip components (not shown) are mounted on the wiring board 211. The chip components (not shown) are, for example, capacitors or resistor. The integrated circuit components 512, the intermediate connecting members 300, and the chip components (not shown) are mounted on the corresponding pads with a mounter or the like. In other words, the integrated circuit components 512 are mounted on the pads 226, and the intermediate connecting members 300 are mounted on the pads 225. At this time, the intermediate connecting members 300 are mounted on the wiring board 221 such that the solder pastes P1 are in contact with end faces 3102 of wiring parts 31 of the intermediate connecting members 300. The intermediate connecting members 300 are preferably self-supported without a support mechanism after being mounted on the wiring board 221.

Subsequently, the reflow step of heating the solder pastes P1 to a temperature higher than or equal to the melting point of the solder powder to melt and aggregate the solder powder and then cooling the solder pastes P1 to a temperature lower than the melting point of the solder powder to solidify is performed in a reflow furnace (not shown). As the solder solidifies, the integrated circuit components 512, the intermediate connecting members 300, and the chip components (not shown) are electrically and mechanically joined to the wiring board 221 as shown in FIG. 20A. In other words, a structure in which the intermediate connecting members 300 and the circuit unit 202 are joined by solder is manufactured. The wiring parts 31 of the intermediate connecting members 300 and the pads 225 are electrically connected by solder 450.

Subsequently, as shown in FIG. 20B, solder pastes P2 containing solder powder and flux are supplied onto the pads 215 of the wiring board 211. For example, Sn—Ag—Cu solder powder is used as the solder powder. The solder pastes P2 can be supplied, for example, by screen printing or with a dispenser. The solder paste P2 may be supplied so as to cover the entire surface of each of the pads 215 or may be supplied so as to partially cover each of the pads 215 as in the case of so-called offset printing.

Then, as shown in FIG. 20C, the circuit unit 201 is mounted on the intermediate connecting members 300 on the circuit unit 202. The circuit unit 201 is mounted on the intermediate connecting members 300 with a mounter or the like. At this time, the circuit unit 201 is mounted on the intermediate connecting members 300 such that the solder pastes P2 are in contact with end faces 3101 of the wiring parts 31 of the intermediate connecting members 300.

Subsequently, the reflow step of heating the solder pastes P2 to a temperature higher than or equal to the melting point of the solder powder to melt and aggregate the solder powder and then cooling the solder pastes P2 to a temperature lower than the melting point of the solder powder to solidify is performed in a reflow furnace (not shown). As the solder solidifies, the intermediate connecting members 300 and the circuit unit 201 are joined by solder (solder 440), with the result that the image pickup module 20 shown in FIG. 12B is manufactured.

The image pickup module 20 manufactured in this way has no defective solder joint between the intermediate connecting members 300 and the circuit units 201, 202, and the optical performance of the electrooptical component 200 incorporated in the circuit unit 201 can be sufficiently guaranteed.

### Embodiment 2II

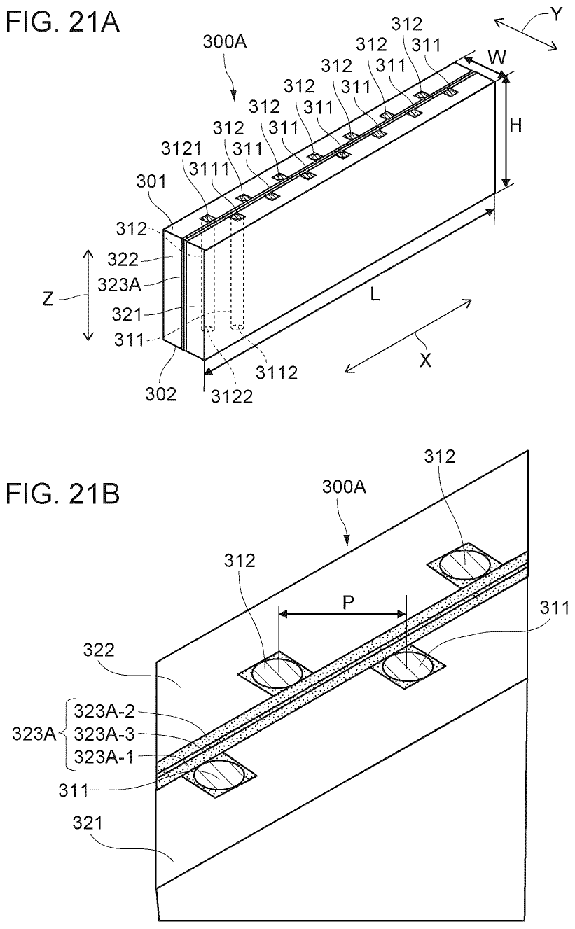

Next, an intermediate connecting member according to Embodiment 2II will be described. FIG. 21A is a perspective view of an intermediate connecting member 300A according to Embodiment 2II. FIG. 21B is a partially enlarged view of the intermediate connecting member 300A shown in FIG. 21A. In Embodiment 2II, like reference signs denote components similar to those of Embodiment 2I, and the description is omitted.

The intermediate connecting member 300A is a rectangular parallelepiped rigid board and has the pair of end faces 301, 302 in the Z direction as joint surfaces. The intermediate connecting member 300A has a plurality of wiring parts 311 and a plurality of wiring parts 312.

The intermediate connecting member 300A has an insulating substrate part 321 and an insulating substrate part 322. The intermediate connecting member 300A has an insulating layer part 323A disposed between the insulating substrate part 321 and the insulating substrate part 322 and different in material from the insulating substrate part 321 or the insulating substrate part 322.

The plurality of wiring parts 311 is disposed between the insulating substrate part 321 and the insulating layer part 323A. The plurality of wiring parts 312 is disposed between the insulating substrate part 322 and the insulating layer part 323A.

The insulating layer part 323A includes three insulating layers 323A-1, 323A-2, 323A-3. The insulating layer 323A-1 is a first insulating layer. The insulating layer 323A-2 is a second insulating layer. The insulating layer 323A-3 is a third insulating layer. The insulating layers 323A-1, 323A-2 are formed as a result of curing of an adhesive having the same material. The insulating layer 323A-3 is disposed between the insulating layer 323A-1 and the insulating layer 323A-2. The insulating layer 323A-3 is different in material from the insulating layers 323A-1, 323A-2. The insulating layers 323A-1, 323A-2 are, for example, formed as a result of curing of an adhesive containing epoxy resin or silicone resin as a main component. The insulating layer 323A-3 is made of, for example, polyimide.

The thickness W in the Y direction of the insulating layer part 323A, as in the case of Embodiment 2I, is preferably greater than or equal to 10 μm and less than or equal to 300 μm.

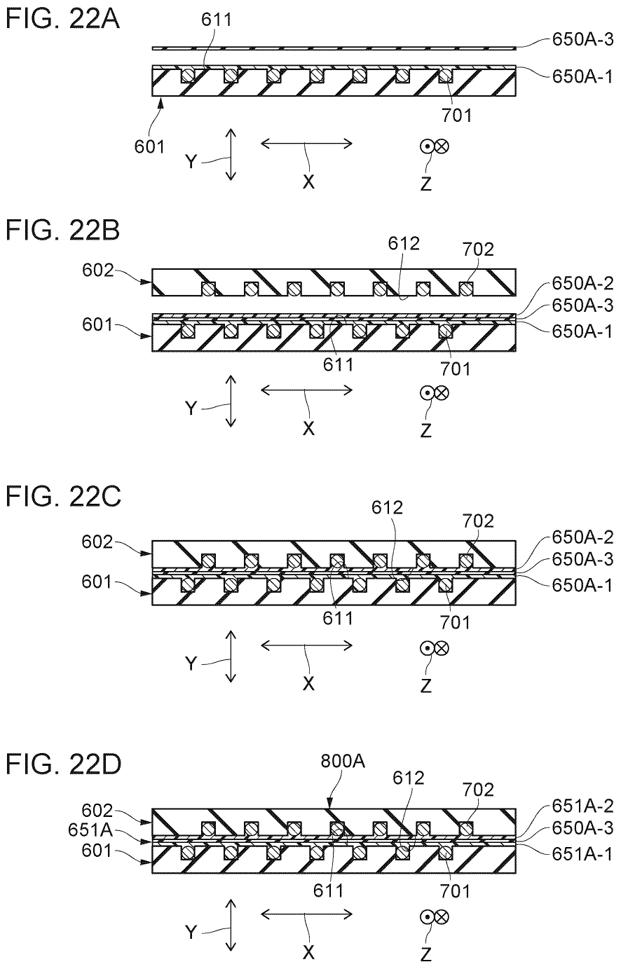

Next, a manufacturing method for the intermediate connecting member 300A according to Embodiment 2II will be described. Hereinafter, steps of the manufacturing method for the intermediate connecting member 300A according to Embodiment 2II will be described with reference to FIGS. 22A to 22D. The manufacturing method for the intermediate connecting member 300A according to Embodiment 2II differs from the manufacturing method for the intermediate connecting member 300 according to Embodiment 2I only in the step of forming a structure shown in FIGS. 17A to 17C. In other words, a structure 800A that is formed in the step shown in FIGS. 22A to 22D differs from the structure 800 that is formed in Embodiment 2I. Therefore, only the step of forming the structure 800A, shown in FIGS. 22A to 22D, will be described. In this series of steps, the structure 800A is formed by bonding the principal surface 611 of the insulating substrate 601 to the principal surface 612 of the insulating substrate 602 via an insulating member 651A such that a direction in which the plurality of conductive members 701 extends is aligned with a direction in which the plurality of conductive members 702 extends. In this series of steps, the structure 800A is formed by bonding the principal surface 611 of the insulating substrate 601 to the principal surface 612 of the insulating substrate 602 such that the plurality of conductive members 701 and the plurality of conductive members 702 are alternately disposed in the X direction.

In the step of forming the structure 800A, shown in FIGS. 22A to 22D, by bonding the principal surface 611 of the insulating substrate 601 to the principal surface 612 of the insulating substrate 602 with an insulating sheet 650A-3 interposed therebetween by using an adhesive, the insulating member 651A is formed. Hereinafter, the step of forming the structure 800A will be described in detail. Initially, in the step shown in FIG. 22A, an adhesive 650A-1 is applied onto the principal surface 611 of the insulating substrate 601. The adhesive 650A-1 is an adhesive having an insulation property and containing, for example, epoxy resin or silicone resin as a main component.

Subsequently, in the step shown in FIG. 22B, the insulating sheet 650A-3 is mounted on the adhesive 650A-1 before the adhesive 650A-1 is cured, and an adhesive 650A-2 having the same components as the adhesive 650A-1 is further applied onto the insulating sheet 650A-3. The insulating sheet 650A-3 is a film sheet of polyimide or the like.

Subsequently, in the step shown in FIG. 22C, the principal surface 612 of the insulating substrate 602 is brought into contact with the adhesive 650A-2. The insulating substrate 601 and the insulating substrate 602 are aligned by an alignment device (not shown). The insulating sheet 650A-3 defines the thickness in the Y direction of each of the adhesives 650A-1, 650A-2 and uniforms the thickness in the Y direction of each of the adhesives 650A-1, 650A-2. Thus, while the thickness of each of the adhesives 650A-1, 650A-2 is controlled, the principal surface 611 of the insulating substrate 601 and the principal surface 612 of the insulating substrate 602 are bonded to each other with the plurality of conductive members 701 and the plurality of conductive members 702 interposed therebetween. Alignment between the insulating substrate 601 and the insulating substrate 602 may be performed by bringing the end faces of the insulating substrates 601, 602 into contact with an abutment member (not shown) or may be performed by using a preformed alignment mark (not shown).

Then, the insulating member 651A shown in FIG. 22D is formed by curing the adhesives 650A-1, 650A-2. The insulating member 651A is made up of the insulating layer 651A-1 that is the cured adhesive 650A-1, the insulating layer 651A-2 that is the cured adhesive 650A-2, and the insulating sheet 650A-3.

In the present embodiment, the intermediate connecting member 300A is formed by cutting the structure 800A. A cutting method is similar to that of Embodiment 2I. The insulating substrate 601 in the structure 800A corresponds to the insulating substrate part 321 in the intermediate connecting member 300A. The insulating substrate 602 in the structure 800A corresponds to the insulating substrate part 322 in the intermediate connecting member 300A.

The insulating member 651A in the structure 800A corresponds to the insulating layer part 323A in the intermediate connecting member 300A. The conductive members 701 in the structure 800A correspond to the wiring parts 311 in the intermediate connecting member 300A. The conductive members 702 in the structure 800A correspond to the wiring parts 312 in the intermediate connecting member 300A.

The insulating layer 651A-1 in the structure 800A corresponds to the insulating layer 323A-1 in the intermediate connecting member 300A. The insulating layer 651A-2 in the structure 800A corresponds to the insulating layer 323A-2 in the intermediate connecting member 300A. The insulating sheet 650A-3 in the structure 800A corresponds to the insulating layer 323A-3 in the intermediate connecting member 300A.

According to Embodiment 2II as well, as in the case of Embodiment 2I, the intermediate connecting member 300A in which the wiring parts 311, 312 are disposed with high accuracy is obtained. In addition, the intermediate connecting member 300A with high accuracy, including the wiring parts 311, 312 disposed with a narrow pitch with high density, is obtained. In Embodiment 2II, the manufacturing method for the image pickup module is similar to that of Embodiment 2I, so the description is omitted.

### Embodiment 2III

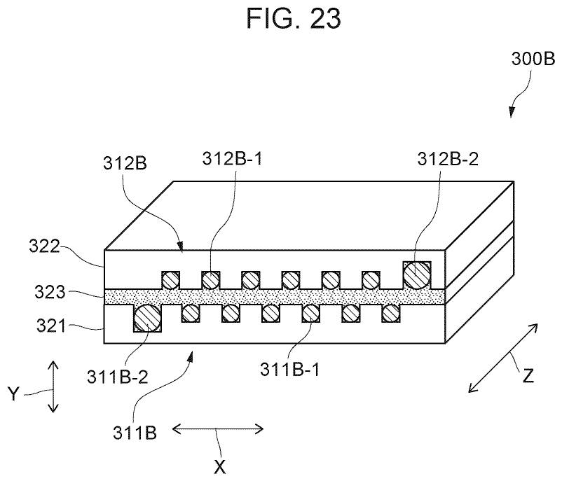

An intermediate connecting member according to Embodiment 2III will be described. FIG. 23 is a perspective view of an intermediate connecting member 300B according to Embodiment 2III. In Embodiment 2III, like reference signs denote components similar to those of Embodiment 2I, and the description is omitted. A manufacturing method for the intermediate connecting member 300B is also similar to that of Embodiment 2I, so the description is omitted.

The intermediate connecting member 300B has an insulating substrate part 321, an insulating substrate part 322, and an insulating layer part 323. The intermediate connecting member 300B has a wiring part group 311B made up of a plurality of first wiring parts and a wiring part group 312B made up of a plurality of second wiring parts. The wiring part groups 311B, 312B are made of metal, such as copper.

The wiring part group 311B includes wiring parts 311B-1 and a wiring part 311B-2 thicker than the wiring parts 311B-1. The wiring part group 312B includes wiring parts 312B-1 and a wiring part 312B-2 thicker than the wiring parts 312B-1.

Thus, a larger current can be passed through the wiring parts 311B-2, 312B-2 than through the wiring parts 311B-1, 312B-1. Thus, the wiring parts 311B-2, 312B-2 can be used as, for example, ground wiring lines. At the time of manufacturing the intermediate connecting member 300B, wires that will be the wiring parts 311B-2, 312B-2 are thicker than wires that will be the wiring parts 311B-1, 312B-1. For example, in a case where the diameter of each of the wiring parts 311B-1, 312B-1 is φ0.2 mm, the diameter of each of the wiring parts 311B-2, 312B-2 that will be ground wiring lines should be thicker like φ0.3 mm.

Each of the wiring part group 311B and the wiring part group 312B should include a wiring part having a first thickness and a wiring part having a second thickness thicker than the first thickness. In the present embodiment, the wiring parts having the first thickness are the wiring parts 311B-1, 312B-1, and the wiring parts having the second thickness are the wiring parts 311B-2, 312B-2. Only the wiring part group 311B may include the wiring part 311B-2 thicker than the wiring part 311B-1, and only the wiring part group 312B may include the wiring part 312B-2 thicker than the wiring part 312B-1. In other words, of the wiring part group 311B and the wiring part group 312B, at least one wiring part should be thicker than the remaining wiring parts. The insulating layer part 323 may be configured as in the case of the insulating layer part 323A according to Embodiment 2II.

### Embodiment 2IV

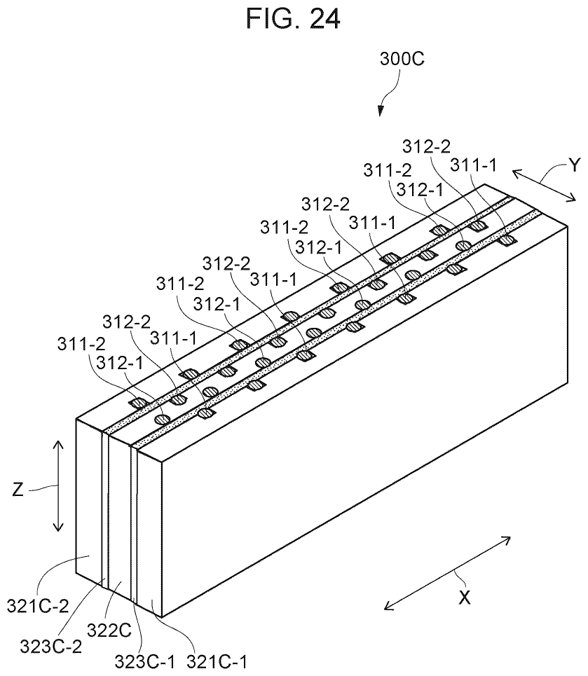

An intermediate connecting member according to Embodiment 2IV will be described. FIG. 24 is a perspective view of an intermediate connecting member 300C according to Embodiment 2IV. In Embodiment 2IV, like reference signs denote components similar to those of Embodiment 2I, and the description is omitted. A manufacturing method for the intermediate connecting member 300C is also similar to that of Embodiment 2I, so the description is omitted. In the intermediate connecting member 300 according to Embodiment 2I, a case where a lamination structure of two insulating substrate parts 321, 322 is provided and the plurality of wiring parts 311 and the plurality of wiring parts 312 are disposed at a connecting part of two insulating substrate parts has been described; however, the configuration is not limited thereto. It is applicable as long as an intermediate connecting member has three or more insulating substrate parts and a plurality of first wiring parts and a plurality of second wiring parts are disposed at a connecting part between mutually adjacent two insulating substrate parts.

The intermediate connecting member 300C according to Embodiment 2IV has three insulating substrate parts 321C-1, 322C, 321C-2. When the insulating substrate part 321C-1 is a first insulating substrate part, the insulating substrate part 322C is a second insulating substrate part. When the insulating substrate part 321C-2 is a first insulating substrate part, the insulating substrate part 322C is a second insulating substrate part. An insulating material of the insulating substrate parts 321C-1, 322C, 321C-2 is, for example, FR-4.

An insulating layer part 323C-1 is disposed between the insulating substrate part 321C-1 and the insulating substrate part 322C. An insulating layer part 323C-2 is disposed between the insulating substrate part 321C-2 and the insulating substrate part 322C. The insulating layer parts 323C-1, 323C-2 are made of an insulating material different from the insulating material of the insulating substrate parts 321C-1, 322C, 321C-2. The insulating layer parts 323C-1, 323C-2 are, for example, formed as a result of curing of an adhesive having an insulation property and containing epoxy resin or silicone resin as a main component.

The intermediate connecting member 300C according to Embodiment 2IV has a plurality of wiring parts 311-1 serving as a plurality of first wiring parts and a plurality of wiring parts 312-1 serving as a plurality of second wiring parts. The plurality of wiring parts 311-1 is disposed so as to extend in the Z direction between the insulating substrate part 321C-1 and the insulating layer part 323C-1, and both end faces of each of the plurality of wiring parts 311-1 in the Z direction are exposed to outside. The plurality of wiring parts 312-1 is disposed so as to extend in the Z direction between the insulating substrate part 322C and the insulating layer part 323C-1, and both end faces of each of the plurality of wiring parts 312-1 in the Z direction are exposed to outside. The plurality of wiring parts 311-1 and the plurality of wiring parts 312-1 are alternately arranged in the X direction.

The intermediate connecting member 300C has a plurality of wiring parts 311-2 serving as a plurality of first wiring parts and a plurality of wiring parts 312-2 serving as a plurality of second wiring parts. The plurality of wiring parts 311-2 is disposed so as to extend in the Z direction between the insulating substrate part 321C-2 and the insulating layer part 323C-2, and both end faces of each of the plurality of wiring parts 311-2 in the Z direction are exposed to outside. The plurality of wiring parts 312-2 is disposed so as to extend in the Z direction between the insulating substrate part 322C and the insulating layer part 323C-2, and both end faces of each of the plurality of wiring parts 312-2 in the Z direction are exposed to outside. The plurality of wiring parts 311-2 and the plurality of wiring parts 312-2 are alternately arranged in the X direction.

As described above, according to Embodiment 2IV as well, as in the case of Embodiment 2I, the intermediate connecting member 300C in which the wiring parts 311-1, 312-1, 311-2, 312-2 are disposed with high accuracy is obtained. According to Embodiment 2IV as well, as in the case of Embodiment 2I, the intermediate connecting member 300C can be manufactured with high accuracy while the wiring structure with a narrow pitch is achieved. The insulating layer parts 323C-1, 323C-2 have similar configurations to that of the insulating layer part 323 according to Embodiment 2I and may have a similar configuration to that of the insulating layer part 323A according to Embodiment 2II.

### Embodiment 2V

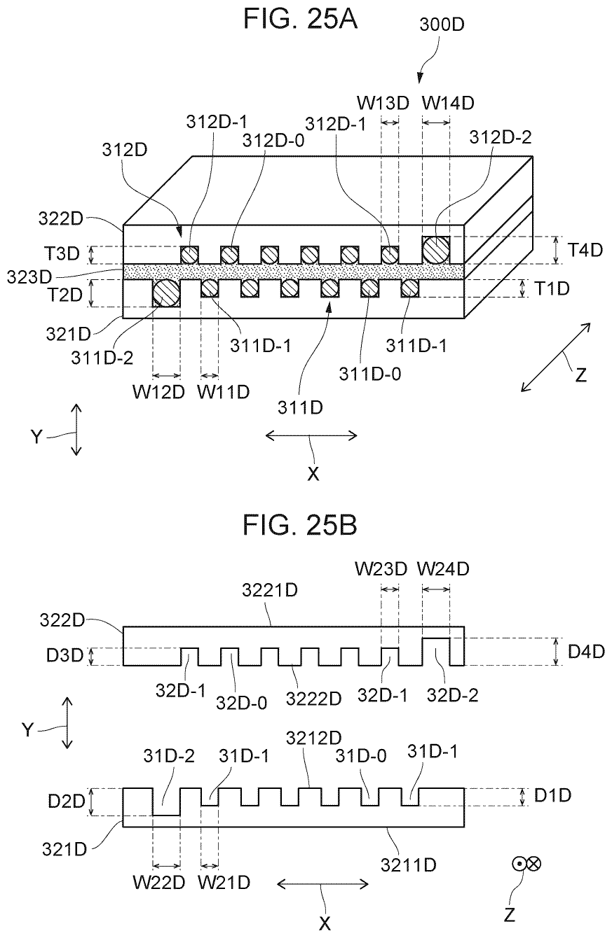

Next, an intermediate connecting member according to Embodiment 2V will be described. FIG. 25A is a perspective view of an intermediate connecting member 300D according to Embodiment 2V. The configuration of the intermediate connecting member 300D according to Embodiment 2V and a manufacturing method therefor are similar to the configuration of the intermediate connecting member 300B according to Embodiment 2III and the manufacturing method therefor. In other words, the manufacturing method for the intermediate connecting member 300D according to Embodiment 2V is similar to the manufacturing method for the intermediate connecting member 300 according to Embodiment 2I.

The intermediate connecting member 300D has a wiring part group 311D having a similar configuration to that of the wiring part group 311B according to Embodiment 2III and a wiring part group 312D having a similar configuration to that of the wiring part group 312B according to Embodiment 2III. The intermediate connecting member 300D has an insulating substrate part 321D having a similar configuration to that of the insulating substrate part 321 according to Embodiment 2III and an insulating substrate part 322D having a similar configuration to that of the insulating substrate part 322 according to Embodiment 2III. The intermediate connecting member 300D has an insulating layer part 323D having a similar configuration to that of the insulating layer part 323 according to Embodiment 2III. The insulating substrate part 321D is a first insulating substrate part. The insulating substrate part 322D is a second insulating substrate part. The insulating substrate part 321D and the insulating substrate part 322D are opposed to each other via the insulating layer part 323D. The insulating substrate parts 321D, 322D are made of the same material as the material of the insulating substrate parts 321, 322 described in Embodiment 2I, for example, glass epoxy. The insulating layer part 323D is made of a material that is different from the material of the insulating substrate part 321D or the material of the insulating substrate part 322D and that is the same as the material of the insulating layer part 323 described in Embodiment 2I, for example, a material formed as a result of solidification of an adhesive containing epoxy resin or silicone resin as a main component.

In Embodiment 2V, the wiring part group 311D has a plurality of, for example, seven wiring parts 311D-0 as a plurality of first wiring parts. The plurality of wiring parts 311D-0 is disposed with a space from each other in the X direction. Each wiring part 311D-0 is disposed so as to extend in the Z direction such that both end faces in the Z direction are exposed to outside. The material of each wiring part 311D-0 is a conductive material, for example, copper. The plurality of wiring parts 311D-0 includes, for example, six wiring parts 311D-1 serving as at least one first wiring part and, for example, one wiring part 311D-2 serving as at least one first wiring part, different in size and/or shape from the wiring part 311D-1. The number of the wiring parts 311D-1 is preferably two or more and is six in Embodiment 2V. The number of the wiring parts 311D-2 is preferably less than the number of the wiring parts 311D-1 and is one in Embodiment 2V.

The wiring part group 312D is disposed with a space in the Y direction from the wiring part group 311D. The wiring part group 312D has a plurality of, for example, seven wiring parts 312D-0 serving as a plurality of second wiring parts. The plurality of wiring parts 312D-0 is disposed with a space from each other in the X direction. Each wiring part 312D-0 is disposed so as to extend in the Z direction such that both end faces in the Z direction are exposed to outside. The material of each wiring part 312D-0 is a conductive material, for example, copper. The plurality of wiring parts 312D-0 includes, for example, six wiring parts 312D-1 serving as at least one second wiring part and, for example, one wiring part 312D-2 serving as at least one second wiring part, different in size and/or shape from the wiring part 312D-1. The number of the wiring parts 312D-1 is preferably two or more and is six in Embodiment 2V. The number of the wiring parts 312D-2 is preferably less than the number of the wiring parts 312D-1 and is one in Embodiment 2V.

In a manufacturing process of the image pickup module according to Embodiment 2V, to increase alignment accuracy between the intermediate connecting member 300D and the wiring board 221 shown in FIG. 19C, an alignment mark is preferably provided on the intermediate connecting member 300D in advance. By providing an alignment mark on the intermediate connecting member 300D, wiring parts can be disposed with high accuracy in the image pickup module.

In a manufacturing process of the intermediate connecting member 300 according to Embodiment 2I, a configuration that the insulating substrate 601 and the insulating substrate 602 are joined to each other by an adhesive as shown in FIG. 17C has been described.

In Embodiment 2V as well, in a manufacturing process of the intermediate connecting member 300D, an insulating substrate corresponding to the insulating substrate part 321D and an insulating substrate corresponding to the insulating substrate part 322D are joined to each other by an adhesive. To increase alignment accuracy at that time, an alignment mark is preferably provided on at least one of the two insulating substrates. By providing an alignment mark on an insulating substrate, wiring parts can be disposed with high accuracy in the intermediate connecting member 300D.

In Embodiment 2V, the wiring part 311D-2 of the plurality of wiring parts 311D-0 and the wiring part 312D-2 of the plurality of wiring parts 312D-0 are used as alignment marks. Of the plurality of wiring parts 311D-0, the wiring part located at an end in the X direction is the wiring part 311D-2. Of the plurality of wiring parts 312D-0, the wiring part located at an end in the X direction is the wiring part 312D-2.

The width in the X direction of each wiring part 311D-1 is a width W11D. The width W11D is a first width. The width in the X direction of the wiring part 311D-2 is a width W12D wider than the width W11D. The width W12D is a second width. In this way, since the width W12D of the wiring part 311D-2 is wider than the width W11D of the wiring part 311D-1, the wiring part 311D-2 can be used as an alignment mark.

The thickness in the Y direction of each wiring part 311D-1 is a thickness T1D. The thickness T1D is a first thickness. The thickness in the Y direction of the wiring part 311D-2 is a thickness T2D thicker than the thickness T1D. The thickness T2D is a second thickness. In this way, since the thickness T2D of the wiring part 311D-2 is thicker than the thickness T1D of the wiring part 311D-1, the wiring part 311D-2 can be used as an alignment mark.

Each of the wiring parts 311D-1, 311D-2 is made up of, for example, wire, and the diameter of the wiring part 311D-2 is greater than the diameter of the wiring part 311D-1. Thus, the width W12D of the wiring part 311D-2 is wider than the width W11D of the wiring part 311D-1, and the thickness T2D of the wiring part 311D-2 is thicker than the thickness T1D of the wiring part 311D-1.

The width in the X direction of each wiring part 312D-1 is a width W13D. The width W13D is a third width. The width in the X direction of the wiring part 312D-2 is a width W14D wider than the width W13D. The width W14D is a fourth width. In this way, since the width W14D of the wiring part 312D-2 is wider than the width W13D of the wiring part 312D-1, the wiring part 312D-2 can be used as an alignment mark.

The thickness in the Y direction of each wiring part 312D-1 is a thickness T3D. The thickness T3D is a third thickness. The thickness in the Y direction of the wiring part 312D-2 is a thickness T4D thicker than the thickness T3D. The thickness T4D is a fourth thickness. In this way, since the thickness T4D of the wiring part 312D-2 is thicker than the thickness T3D of the wiring part 312D-1, the wiring part 312D-2 can be used as an alignment mark.

Each of the wiring parts 312D-1, 312D-2 is made up of, for example, wire, and the diameter of the wiring part 312D-2 is greater than the diameter of the wiring part 312D-1. Thus, the width W14D of the wiring part 312D-2 is wider than the width W13D of the wiring part 312D-1, and the thickness T4D of the wiring part 312D-2 is thicker than the thickness T3D of the wiring part 312D-1.

In Embodiment 2V, the plurality of wiring parts 311D-0 is disposed on the insulating substrate part 321D, and the plurality of wiring parts 312D-0 is disposed on the insulating substrate part 322D. Hereinafter, the configuration of the insulating substrate part 321D on which the wiring parts 311D-0 are disposed and the insulating substrate part 322D on which the wiring parts 312D-0 are disposed will be specifically described. FIG. 25B is a diagram of two insulating substrate parts 321D, 322D according to Embodiment 2V. FIG. 25B is a plan view when the insulating substrate parts 321D, 322D are viewed in the Z direction.

The insulating substrate part 321D has a surface 3211D and a surface 3212D on an opposite side to the surface 3211D in the Y direction. The insulating substrate part 322D has a surface 3221D and a surface 3222D on an opposite side to the surface 3221D in the Y direction. The insulating layer part 323D of FIG. 25A is disposed between the surface 3212D and the surface 3222D. In other words, the surface 3212D and the surface 3222D are opposed to each other via the insulating layer part 323D.

The plurality of wiring parts 311D-0 is disposed on the surface 3212D. The plurality of wiring parts 312D-0 is disposed on the surface 3222D. In other words, the plurality of wiring parts 311D-0 is disposed between the insulating substrate part 321D and the insulating layer part 323D, and the plurality of wiring parts 312D-0 is disposed between the insulating substrate part 322D and the insulating layer part 323D.

A plurality of grooves 31D-0 corresponding to the plurality of wiring parts 311D-0 is formed on the surface 3212D. The plurality of grooves 31D-0 is formed with a space from each other in the X direction. Each groove 31D-0 extends in the Z direction. The plurality of grooves 31D-0 includes a plurality of grooves 31D-1 corresponding to the plurality of wiring parts 311D-1 and a groove 31D-2 corresponding to the wiring part 311D-2. The groove 31D-2 is a first groove.

Each wiring part 311D-1 is disposed in a corresponding one of the grooves 31D-1. The wiring part 311D-2 is disposed in the groove 31D-2. For this reason, the width W22D in the X direction of the groove 31D-2 is wider than the width W21D in the X direction of each groove 31D-1, that is, the width W11D in the X direction of each wiring part 311D-1. The depth D2D in the Y direction of the groove 31D-2 is deeper than the depth D1D in the Y direction of each groove 31D-1, that is, the thickness T1D in the Y direction of each wiring part 311D-1.

The width W21D of each groove 31D-1 is preferably wider than the width W11D of each wiring part 311D-1. In other words, the width W21D of each groove 31D-1 is preferably wider than 1.0 times the width W11D of each wiring part 311D-1. For example, the width W21D of each groove 31D-1 just needs to be greater than or equal to 1.1 times the width W11D of each wiring part 311D-1, may be greater than or equal to 1.5 times, and may be greater than or equal to twice. The width W21D of each groove 31D-1 is preferably less than or equal to 20 times the width W11D of each wiring part 311D-1.

The width W22D of the groove 31D-2 is preferably wider than the width W12D of the wiring part 311D-2. In other words, the width W22D of the groove 31D-2 is preferably wider than 1.0 times the width W12D of the wiring part 311D-2. For example, the width W22D of the groove 31D-2 just needs to be greater than or equal to 1.1 times the width W12D of the wiring part 311D-2, may be greater than or equal to 1.5 times, and may be greater than or equal to twice. The width W22D of the groove 31D-2 is preferably less than or equal to 20 times the width W12D of the wiring part 311D-2.

The depth D1D of each groove 31D-1 is preferably deeper than the thickness T1D of each wiring part 311D-1. In other words, the depth D1D of each groove 31D-1 is preferably deeper than 1.0 times the thickness T1D of each wiring part 311D-1. For example, the depth D1D of each groove 31D-1 just needs to be greater than or equal to 1.1 times the thickness T1D of each wiring part 311D-1, may be greater than or equal to 1.5 times, and may be greater than or equal to twice. The depth D1D of each groove 31D-1 is preferably less than or equal to 20 times the thickness T1D of each wiring part 311D-1.

The depth D2D of the groove 31D-2 is preferably deeper than the thickness T2D of the wiring part 311D-2. In other words, the depth D2D of the groove 31D-2 is preferably deeper than 1.0 times the thickness T2D of the wiring part 311D-2. For example, the depth D2D of the groove 31D-2 just needs to be greater than or equal to 1.1 times the thickness T2D of the wiring part 311D-2, may be greater than or equal to 1.5 times, and may be greater than or equal to twice. The depth D2D of the groove 31D-2 is preferably less than or equal to 20 times the thickness T2D of the wiring part 311D-2.

A plurality of grooves 32D-0 corresponding to the plurality of wiring parts 312D-0 is formed on the surface 3222D. The plurality of grooves 32D-0 is formed with a space from each other in the X direction. Each groove 32D-0 extends in the Z direction. The plurality of grooves 32D-0 includes a plurality of grooves 32D-1 corresponding to the plurality of wiring parts 312D-1 and a groove 32D-2 corresponding to the wiring part 312D-2. The groove 32D-2 is a second groove.

Each wiring part 312D-1 is disposed in a corresponding one of the grooves 32D-1. The wiring part 312D-2 is disposed in the groove 32D-2. For this reason, the width W24D in the X direction of the groove 32D-2 is wider than the width W23D in the X direction of each groove 32D-1, that is, the width W13D in the X direction of each wiring part 312D-1. The depth D4D in the Y direction of the groove 32D-2 is deeper than the depth D3D in the Y direction of each groove 32D-1, that is, the thickness T3D in the Y direction of each wiring part 312D-1.

The width W23D of each groove 32D-1 is preferably wider than the width W13D of each wiring part 312D-1. In other words, the width W23D of each groove 32D-1 is preferably wider than 1.0 times the width W13D of each wiring part 312D-1. For example, the width W23D of each groove 32D-1 just needs to be greater than or equal to 1.1 times the width W13D of each wiring part 312D-1, may be greater than or equal to 1.5 times, and may be greater than or equal to twice. The width W23D of each groove 32D-1 is preferably less than or equal to 20 times the width W13D of each wiring part 312D-1.

The width W24D of the groove 32D-2 is preferably wider than the width W14D of the wiring part 312D-2. In other words, the width W24D of the groove 32D-2 is preferably wider than 1.0 times the width W14D of the wiring part 312D-2. For example, the width W24D of the groove 32D-2 just needs to be greater than or equal to 1.1 times the width W14D of the wiring part 312D-2, may be greater than or equal to 1.5 times, and may be greater than or equal to twice. The width W24D of the groove 32D-2 is preferably less than or equal to 20 times the width W14D of the wiring part 312D-2.

The depth D3D of each groove 32D-1 is preferably deeper than the thickness T3D of each wiring part 312D-1. In other words, the depth D3D of each groove 32D-1 is preferably deeper than 1.0 times the thickness T3D of each wiring part 312D-1. For example, the depth D3D of each groove 32D-1 just needs to be greater than or equal to 1.1 times the thickness T3D of each wiring part 312D-1, may be greater than or equal to 1.5 times, and may be greater than or equal to twice. The depth D3D of each groove 32D-1 is preferably less than or equal to 20 times the thickness T3D of each wiring part 312D-1.

The depth D4D of the groove 32D-2 is preferably deeper than the thickness T4D of the wiring part 312D-2. In other words, the depth D4D of the groove 32D-2 is preferably deeper than 1.0 times the thickness T4D of the wiring part 312D-2. For example, the depth D4D of the groove 32D-2 just needs to be greater than or equal to 1.1 times the thickness T4D of the wiring part 312D-2, may be greater than or equal to 1.5 times, and may be greater than or equal to twice. The depth D4D of the groove 32D-2 is preferably less than or equal to 20 times the thickness T4D of the wiring part 312D-2.

In this way, when viewed in the Z direction, the area of the wiring part 311D-2 is larger than the area of the wiring part 311D-1, and the area of the wiring part 312D-2 is larger than the area of the wiring part 312D-1. Thus, by using each of the wiring parts 311D-2, 312D-2 as an alignment mark, alignment accuracy of the intermediate connecting member 300D with respect to the wiring board 221 shown in FIG. 19C increases. When viewed in the Z direction, since the area of each of the wiring parts 311D-2, 312D-2 is large, a self-alignment effect of the intermediate connecting member 300D with respect to the wiring board 221 at the time of joining the wiring board 221 to the intermediate connecting member 300D by solder increases.

In Embodiment 2V, the wiring part 311D-2 having a width of W12D and a thickness of T2D and included in the plurality of wiring parts 311D-0 and the wiring part 312D-2 having a width of W14D and a thickness of T4D and included in the plurality of wiring parts 312D-0 are shifted in the X direction. In other words, of the plurality of wiring parts 311D-0 and the plurality of wiring parts 312D-0, a spaced distance between the wiring part 311D-2 and the wiring part 312D-2 is longer than a spaced distance between other two wiring parts. Thus, in a manufacturing process of the image pickup module according to Embodiment 2V, alignment accuracy of the intermediate connecting member 300D with respect to the wiring board 221 further increases. At the time of joining the wiring board 221 to the intermediate connecting member 300D by solder, a self-alignment effect of the intermediate connecting member 300D with respect to the wiring board 221 further increases. In a manufacturing process of the intermediate connecting member 300D, alignment accuracy at the time of joining an insulating substrate corresponding to the insulating substrate part 321D to an insulating substrate corresponding to the insulating substrate part 322D by an adhesive further increases.

A case where the wiring part 311D-2 and the wiring part 312D-2 are used as alignment marks has been described; however, the configuration is not limited thereto. For example, the wiring part 312D-2 and the groove 32D-2 may be omitted, and the wiring part 311D-2 may be used as an alignment mark. In the intermediate connecting member 300D, the wiring part group 312D, that is, the plurality of wiring parts 312D-0, may be omitted. In this case as well, the wiring part 311D-2 should be used as an alignment mark.

It is suitable in a case where the width W12D of the wiring part 311D-2 is wider than the width W11D of each wiring part 311D-1 and the thickness T2D of the wiring part 311D-2 is thicker than the thickness T1D of each wiring part 311D-1; however, the configuration is not limited thereto. For example, in a case where the width W12D of the wiring part 311D-2 is wider than the width W11D of each wiring part 311D-1, the thickness T2D of the wiring part 311D-2 may be less than or equal to the thickness T1D of each wiring part 311D-1. At this time, preferably, the width W22D of the groove 31D-2 is wider than the width W21D of each groove 31D-1, and the depth D2D of the groove 31D-2 is less than or equal to the depth D1D of each groove 31D-1. Similarly, in a case where the thickness T2D of the wiring part 311D-2 is thicker than the thickness T1D of each wiring part 311D-1, the width W12D of the wiring part 311D-2 may be less than or equal to the width W11D of each wiring part 311D-1. At this time, preferably, the depth D2D of the groove 31D-2 is deeper than the width D1D of each groove 31D-1, and the width W22D of the groove 31D-2 is less than or equal to the width W21D of each groove 31D-1. In other words, the groove 31D-2 should be a groove wider in width than each groove 31D-1, that is, each wiring part 311D-1, and/or deeper than each groove 31D-1, that is, the thickness of each wiring part 311D-1. In these cases as well, the wiring part 311D-2 may be used as an alignment mark.

Similarly, it is suitable in a case where the width W14D of the wiring part 312D-2 is wider than the width W13D of each wiring part 312D-1 and the thickness T4D of the wiring part 312D-2 is thicker than the thickness T3D of each wiring part 312D-1; however, the configuration is not limited thereto. For example, in a case where the width W14D of the wiring part 312D-2 is wider than the width W13D of each wiring part 312D-1, the thickness T4D of the wiring part 312D-2 may be less than or equal to the thickness T3D of each wiring part 312D-1. At this time, preferably, the width W24D of the groove 32D-2 is wider than the width W23D of each groove 32D-1, and the depth D4D of the groove 32D-2 is less than or equal to the depth D3D of each groove 32D-1. Similarly, in a case where the thickness T4D of the wiring part 312D-2 is thicker than the thickness T3D of each wiring part 312D-1, the width W14D of the wiring part 312D-2 may be less than or equal to the width W13D of each wiring part 312D-1. At this time, preferably, the depth D4D of the groove 32D-2 is deeper than the width D3D of each groove 32D-1, and the width W24D of the groove 32D-2 is less than or equal to the width W23D of each groove 32D-1. In other words, the groove 32D-2 should be a groove wider in width than each groove 32D-1, that is, each wiring part 312D-1, and/or deeper than each groove 32D-1, that is, the thickness of each wiring part 312D-1. In these cases as well, the wiring part 312D-2 may be used as an alignment mark.

A case where the wiring part group 311D, that is, the plurality of wiring parts 311D-0, includes one wiring part 311D-2 has been described; however, the configuration is not limited thereto. The wiring part group 311D may include two or more wiring parts 311D-2. At this time, of the plurality of wiring parts 311D-0, each of the two wiring parts located at both ends in the X direction is preferably the wiring part 311D-2.

Similarly, a case where the wiring part group 312D, that is, the plurality of wiring parts 312D-0, includes one wiring part 312D-2 has been described; however, the configuration is not limited thereto. The wiring part group 312D may include two or more wiring parts 312D-2. At this time, of the plurality of wiring parts 312D-0, each of the two wiring parts located at both ends in the X direction is preferably the wiring part 312D-2.

A case where each of the plurality of wiring parts 311D-0 is wire has been described; however, the configuration is not limited thereto. Each of the plurality of wiring parts 311D-0 should be a conductor. Thus, one or some or all of the plurality of wiring parts 311D-0 may be, for example, conductor patterns.

Similarly, a case where each of the plurality of wiring parts 312D-0 is wire has been described; however, the configuration is not limited thereto. Each of the plurality of wiring parts 312D-0 should be a conductor.

Thus, one or some or all of the plurality of wiring parts 312D-0 may be, for example, conductor patterns.

A case where the wiring parts 311D-2, 312D-2 are respectively disposed in the grooves 31D-2, 32D-2 has been described; however, the configuration is not limited thereto. One or both of the wiring parts 311D-2, 312D-2 may be omitted. In this case, a groove with no wiring part may be used as an alignment mark. Part of the insulating layer part 323D fills the groove with no wiring part.

### Embodiment 2VI

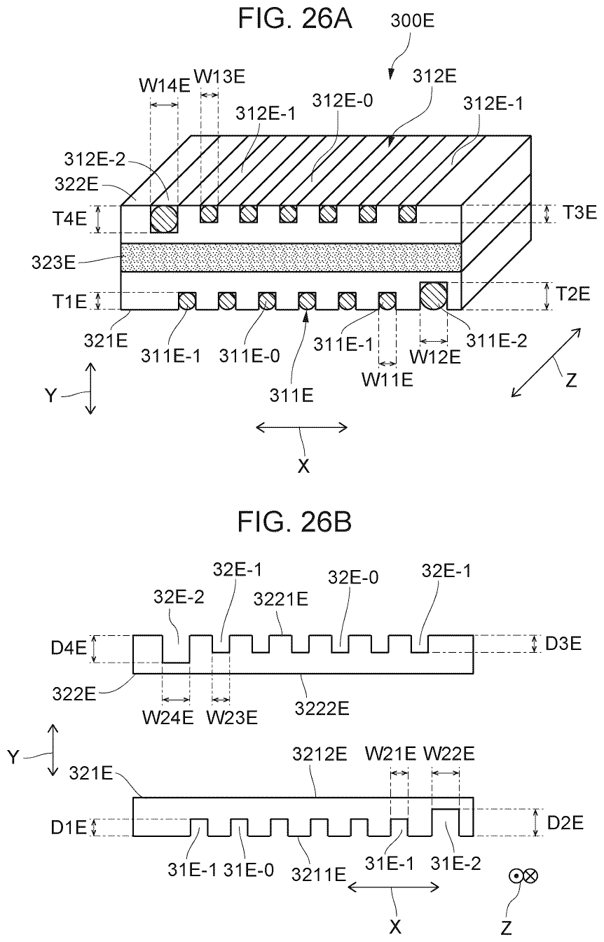

Next, an intermediate connecting member according to Embodiment 2VI will be described. FIG. 26A is a perspective view of an intermediate connecting member 300E according to Embodiment 2VI. The configuration of the intermediate connecting member 300E according to Embodiment 2VI and a manufacturing method therefor are similar to the configuration of the intermediate connecting member 300B according to Embodiment 2III and the manufacturing method therefor. In other words, the manufacturing method for the intermediate connecting member 300E according to Embodiment 2VI is similar to the manufacturing method for the intermediate connecting member 300 according to Embodiment 2I.

The intermediate connecting member 300E has a wiring part group 311E and a wiring part group 312E. The intermediate connecting member 300E has an insulating substrate part 321E, an insulating substrate part 322E, and an insulating layer part 323E. The insulating substrate part 321E is a first insulating substrate part. The insulating substrate part 322E is a second insulating substrate part. The insulating substrate part 321E and the insulating substrate part 322E are opposed to each other via the insulating layer part 323E. The insulating substrate parts 321E, 322E are made of the same material as the material of the insulating substrate parts 321, 322 described in Embodiment 2I, for example, glass epoxy. The insulating layer part 323E is made of a material that is different from the material of the insulating substrate part 321E or the material of the insulating substrate part 322E and that is the same as the material of the insulating layer part 323 described in Embodiment 2I, for example, a material formed as a result of solidification of an adhesive containing epoxy resin or silicone resin as a main component.

In Embodiment 2VI, the wiring part group 311E has a plurality of, for example, seven wiring parts 311E-0 as a plurality of first wiring parts. The plurality of wiring parts 311E-0 is disposed with a space from each other in the X direction. Each wiring part 311E-0 is disposed so as to extend in the Z direction such that both end faces in the Z direction are exposed to outside. The material of each wiring part 312E-0 is a conductive material, for example, copper. The plurality of wiring parts 311E-0 includes, for example, six wiring parts 311E-1 serving as at least one first wiring part and, for example, one wiring part 311E-2 serving as at least one first wiring part, different in size and/or shape from the wiring part 311E-1. The number of the wiring parts 311E-1 is preferably two or more and is six in Embodiment 2VI. The number of the wiring parts 311E-2 is preferably less than the number of the wiring parts 311E-1 and is one in Embodiment 2VI.

The wiring part group 312E is disposed with a space in the Y direction from the wiring part group 311E. The wiring part group 312E has a plurality of, for example, seven wiring parts 312E-0 serving as a plurality of second wiring parts. The plurality of wiring parts 312E-0 is disposed with a space from each other in the X direction. Each wiring part 312E-0 is disposed so as to extend in the Z direction such that both end faces in the Z direction are exposed to outside. The material of each wiring part 312E-0 is a conductive material, for example, copper. The plurality of wiring parts 312E-0 includes, for example, six wiring parts 312E-1 serving as at least one second wiring part and, for example, one wiring part 312E-2 serving as at least one second wiring part, different in size and/or shape from the wiring part 312E-1. The number of the wiring parts 312E-1 is preferably two or more and is six in Embodiment 2VI. The number of the wiring parts 312E-2 is preferably less than the number of the wiring parts 312E-1 and is one in Embodiment 2VI.

Here, in a manufacturing process of an electronic module, an intermediate connecting member needs to be aligned with high accuracy with respect to a wiring board that is a joining target. In a manufacturing process of the image pickup module according to Embodiment 2VI, to increase alignment accuracy between the intermediate connecting member 300E and the wiring board 221 shown in FIG. 19C, an alignment mark is preferably provided on the intermediate connecting member 300D in advance. By providing an alignment mark on the intermediate connecting member 300E, wiring parts can be disposed with high accuracy in the image pickup module.

In a manufacturing process of the intermediate connecting member 300E according to Embodiment 2VI, an insulating substrate corresponding to the insulating substrate part 321E and an insulating substrate corresponding to the insulating substrate part 322E are joined to each other by an adhesive. To increase alignment accuracy at that time, an alignment mark is preferably provided on at least one of the two insulating substrates. By providing an alignment mark on an insulating substrate, wiring parts can be disposed with high accuracy in the intermediate connecting member 300E.

In Embodiment 2VI, the wiring part 311E-2 of the plurality of wiring parts 311E-0 and the wiring part 312E-2 of the plurality of wiring parts 312E-0 are used as alignment marks. Of the plurality of wiring parts 311E-0, the wiring part located at an end in the X direction is the wiring part 311E-2. Of the plurality of wiring parts 312E-0, the wiring part located at an end in the X direction is the wiring part 312E-2.

The width in the X direction of each wiring part 311E-1 is a width W11E. The width W11E is a first width. The width in the X direction of the wiring part 311E-2 is a width W12E wider than the width W11E. The width W12E is a second width. In this way, since the width W12E of the wiring part 311E-2 is wider than the width W11E of the wiring part 311E-1, the wiring part 311E-2 can be used as an alignment mark.

The thickness in the Y direction of each wiring part 311E-1 is a thickness T1E. The thickness T1E is a first thickness. The thickness in the Y direction of the wiring part 311E-2 is a thickness T2E thicker than the thickness T1E. The thickness T2E is a second thickness. In this way, since the thickness T2E of the wiring part 311E-2 is thicker than the thickness T1E of the wiring part 311E-1, the wiring part 311E-2 can be used as an alignment mark.

Each of the wiring parts 311E-1, 311E-2 is made up of, for example, wire, and the diameter of the wiring part 311E-2 is greater than the diameter of the wiring part 311E-1. Thus, the width W12E of the wiring part 311E-2 is wider than the width W11E of the wiring part 311E-1, and the thickness T2E of the wiring part 311E-2 is thicker than the thickness T1E of the wiring part 311E-1.

The width in the X direction of each wiring part 312E-1 is a width W13E. The width W13E is a third width. The width in the X direction of the wiring part 312E-2 is a width W14E wider than the width W13E. The width W14E is a fourth width. In this way, since the width W14E of the wiring part 312E-2 is wider than the width W13E of the wiring part 312E-1, the wiring part 312E-2 can be used as an alignment mark.

The thickness in the Y direction of each wiring part 312E-1 is a thickness T3E. The thickness T3E is a third thickness. The thickness in the Y direction of the wiring part 312E-2 is a thickness T4E thicker than the thickness T3E. The thickness T4E is a fourth thickness. In this way, since the thickness T4E of the wiring part 312E-2 is thicker than the thickness T3E of the wiring part 312E-1, the wiring part 312E-2 can be used as an alignment mark.

Each of the wiring parts 312E-1, 312E-2 is made up of, for example, wire, and the diameter of the wiring part 312E-2 is greater than the diameter of the wiring part 312E-1. Thus, the width W14E of the wiring part 312E-2 is wider than the width W13E of the wiring part 312E-1, and the thickness T4E of the wiring part 312E-2 is thicker than the thickness T3E of the wiring part 312E-1.

In Embodiment 2VI, the plurality of wiring parts 311E-0 is disposed on the insulating substrate part 321E, and the plurality of wiring parts 312E-0 is disposed on the insulating substrate part 322E. Hereinafter, the configuration of the insulating substrate part 321E on which the wiring parts 311E-0 are disposed and the insulating substrate part 322E on which the wiring parts 312E-0 are disposed will be specifically described. FIG. 26B is a diagram of two insulating substrate parts 321E, 322E according to Embodiment 2VI. FIG. 26B is a plan view when the insulating substrate parts 321E, 322E are viewed in the Z direction.

The insulating substrate part 321E has a surface 3211E and a surface 3212E on an opposite side to the surface 3211E. The insulating substrate part 322E has a surface 3221E and a surface 3222E on an opposite side to the surface 3221E. The insulating layer part 323E of FIG. 26A is disposed between the surface 3212E and the surface 3222E. In other words, the surface 3212E and the surface 3222E are opposed to each other via the insulating layer part 323E.

The plurality of wiring parts 311E-0 is disposed on the surface 3211E. The plurality of wiring parts 312E-0 is disposed on the surface 3221E. In other words, the plurality of wiring parts 311E-0 is disposed on the outer surface 3211E of the insulating substrate part 321E, and the plurality of wiring parts 312E-0 is disposed on the outer surface 3221E of the insulating substrate part 322E. An insulating layer (not shown) may be provided on each of the surface 3211E and the surface 3221E.

A plurality of grooves 31E-0 corresponding to the plurality of wiring parts 311E-0 is formed on the surface 3211E. The plurality of grooves 31E-0 is formed with a space from each other in the X direction. Each groove 31E-0 extends in the Z direction. The plurality of grooves 31E-0 includes a plurality of grooves 31E-1 corresponding to the plurality of wiring parts 311E-1 and a groove 31E-2 corresponding to the wiring part 311E-2. The groove 31E-2 is a first groove.

Each wiring part 311E-1 is disposed in a corresponding one of the grooves 31E-1. The wiring part 311E-2 is disposed in the groove 31E-2. For this reason, the width W22E in the X direction of the groove 31E-2 is wider than the width W21E in the X direction of each groove 31E-1, that is, the width W11E in the X direction of each wiring part 311E-1. The depth D2E in the Y direction of the groove 31E-2 is deeper than the depth D1E in the Y direction of each groove 31E-1, that is, the thickness T1E in the Y direction of each wiring part 311E-1.

The width W21E of each groove 31E-1 is preferably wider than the width W11E of each wiring part 311E-1. In other words, the width W21E of each groove 31E-1 is preferably wider than 1.0 times the width W11E of each wiring part 311E-1. For example, the width W21E of each groove 31E-1 just needs to be greater than or equal to 1.1 times the width W11E of each wiring part 311E-1, may be greater than or equal to 1.5 times, and may be greater than or equal to twice. The width W21E of each groove 31E-1 is preferably less than or equal to 20 times the width W11E of each wiring part 311E-1.

The width W22E of the groove 31E-2 is preferably wider than the width W12E of the wiring part 311E-2. In other words, the width W22E of the groove 31E-2 is preferably wider than 1.0 times the width W12E of the wiring part 311E-2. For example, the width W22E of the groove 31E-2 just needs to be greater than or equal to 1.1 times the width W12E of the wiring part 311E-2, may be greater than or equal to 1.5 times, and may be greater than or equal to twice. The width W22E of the groove 31E-2 is preferably less than or equal to 20 times the width W12E of the wiring part 311E-2.

The depth D1E of each groove 31E-1 is preferably deeper than the thickness T1E of each wiring part 311E-1. The depth D1E of each groove 31E-1 is preferably deeper than 1.0 times the thickness T1E of each wiring part 311E-1. For example, the depth D1E of each groove 31E-1 just needs to be greater than or equal to 1.1 times the thickness T1E of each wiring part 311E-1, may be greater than or equal to 1.5 times, and may be greater than or equal to twice. The depth D1E of each groove 31E-1 is preferably less than or equal to 20 times the thickness T1E of each wiring part 311E-1.

The depth D2E of the groove 31E-2 is preferably deeper than the thickness T2E of the wiring part 311E-2. In other words, the depth D2E of the groove 31E-2 is preferably deeper than 1.0 times the thickness T2E of the wiring part 311E-2. For example, the depth D2E of the groove 31E-2 just needs to be greater than or equal to 1.1 times the thickness T2E of the wiring part 311E-2, may be greater than or equal to 1.5 times, and may be greater than or equal to twice. The depth D2E of the groove 31E-2 is preferably less than or equal to 20 times the thickness T2E of the wiring part 311E-2.

A plurality of grooves 32E-0 corresponding to the plurality of wiring parts 312E-0 is formed on the surface 3221E. The plurality of grooves 32E-0 is formed with a space from each other in the X direction. Each groove 32E-0 extends in the Z direction. The plurality of grooves 32E-0 includes a plurality of grooves 32E-1 corresponding to the plurality of wiring parts 312E-1 and a groove 32E-2 corresponding to the wiring part 312E-2. The groove 32E-2 is a second groove.

Each wiring part 312E-1 is disposed in a corresponding one of the grooves 32E-1. The wiring part 312E-2 is disposed in the groove 32E-2. For this reason, the width W24E in the X direction of the groove 32E-2 is wider than the width W23E in the X direction of each groove 32E-1, that is, the width W13E in the X direction of each wiring part 312E-1. The depth D4E in the Y direction of the groove 32E-2 is deeper than the depth D3E in the Y direction of each groove 32E-1, that is, the thickness T3E in the Y direction of each wiring part 312E-1.

The width W23E of each groove 32E-1 is preferably wider than the width W13E of each wiring part 312E-1. In other words, the width W23E of each groove 32E-1 is preferably wider than 1.0 times the width W13E of each wiring part 312E-1. For example, the width W23E of each groove 32E-1 just needs to be greater than or equal to 1.1 times the width W13E of each wiring part 312E-1, may be greater than or equal to 1.5 times, and may be greater than or equal to twice. The width W23E of each groove 32E-1 is preferably less than or equal to 20 times the width W13E of each wiring part 312E-1.

The width W24E of the groove 32E-2 is preferably wider than the width W14E of the wiring part 312E-2. In other words, the width W24E of the groove 32E-2 is preferably wider than 1.0 times the width W14E of the wiring part 312E-2. For example, the width W24E of the groove 32E-2 just needs to be greater than or equal to 1.1 times the width W14E of the wiring part 312E-2, may be greater than or equal to 1.5 times, and may be greater than or equal to twice. The width W24E of the groove 32E-2 is preferably less than or equal to 20 times the width W14E of the wiring part 312E-2.

The depth D3E of each groove 32E-1 is preferably deeper than the thickness T3E of each wiring part 312E-1. In other words, the depth D3E of each groove 32E-1 is preferably deeper than 1.0 times the thickness T3E of each wiring part 312E-1. For example, the depth D3E of each groove 32E-1 just needs to be greater than or equal to 1.1 times the thickness D3E of each wiring part 312E-1, may be greater than or equal to 1.5 times, and may be greater than or equal to twice. The depth D3E of each groove 32E-1 is preferably less than or equal to 20 times the thickness T3E of each wiring part 312E-1.

The depth D4E of the groove 32E-2 is preferably deeper than the thickness T4E of the wiring part 312E-2. In other words, the depth D4E of the groove 32E-2 is preferably deeper than 1.0 times the thickness T4E of the wiring part 312E-2. For example, the depth D4E of the groove 32E-2 just needs to be greater than or equal to 1.1 times the thickness T4E of the wiring part 312E-2, may be greater than or equal to 1.5 times, and may be greater than or equal to twice. The depth D4E of the groove 32E-2 is preferably less than or equal to 20 times the thickness T4E of the wiring part 312E-2.

In this way, when viewed in the Z direction, the area of the wiring part 311E-2 is larger than the area of the wiring part 311E-1, and the area of the wiring part 312E-2 is larger than the area of the wiring part 312E-1. Thus, by using each of the wiring parts 311E-2, 312E-2 as an alignment mark, alignment accuracy of the intermediate connecting member 300E with respect to the wiring board 221 shown in FIG. 19C increases. When viewed in the Z direction, since the area of each of the wiring parts 311E-2, 312E-2 is large, a self-alignment effect of the intermediate connecting member 300E with respect to the wiring board 221 at the time of joining the wiring board 221 to the intermediate connecting member 300E by solder increases.

In Embodiment 2VI, the wiring part 311E-2 having a width of W12E and a thickness of T2E and included in the plurality of wiring parts 311E-0 and the wiring part 312E-2 having a width of W14E and a thickness of T4E and included in the plurality of wiring parts 312E-0 are shifted in the X direction. In other words, of the plurality of wiring parts 311E-0 and the plurality of wiring parts 312E-0, a spaced distance between the wiring part 311E-2 and the wiring part 312E-2 is longer than a spaced distance between other two wiring parts. Thus, in a manufacturing process of the image pickup module according to Embodiment 2VI, alignment accuracy of the intermediate connecting member 300E with respect to the wiring board 221 further increases. At the time of joining the wiring board 221 to the intermediate connecting member 300E by solder, a self-alignment effect of the intermediate connecting member 300E with respect to the wiring board 221 further increases. In a manufacturing process of the intermediate connecting member 300E, alignment accuracy at the time of joining an insulating substrate corresponding to the insulating substrate part 321E to an insulating substrate corresponding to the insulating substrate part 322E by an adhesive further increases.

A case where the wiring part 311E-2 and the wiring part 312E-2 are used as alignment marks has been described; however, the configuration is not limited thereto. For example, the wiring part 312E-2 and the groove 32E-2 may be omitted, and the wiring part 311E-2 may be used as an alignment mark. In the intermediate connecting member 300E, the wiring part group 312E, that is, the plurality of wiring parts 312E-0, may be omitted. In this case as well, the wiring part 311E-2 should be used as an alignment mark.

It is suitable in a case where the width W12E of the wiring part 311E-2 is wider than the width W11E of each wiring part 311E-1 and the thickness T2E of the wiring part 311E-2 is thicker than the thickness T1E of each wiring part 311E-1; however, the configuration is not limited thereto. For example, in a case where the width W12E of the wiring part 311E-2 is wider than the width W11E of each wiring part 311E-1, the thickness T2E of the wiring part 311E-2 may be less than or equal to the thickness T1E of each wiring part 311E-1. At this time, preferably, the width W22E of the groove 31E-2 is wider than the width W21E of each groove 31E-1, and the depth D2E of the groove 31E-2 is less than or equal to the depth D1E of each groove 31E-1. Similarly, in a case where the thickness T2E of the wiring part 311E-2 is thicker than the thickness T1E of each wiring part 311E-1, the width W12E of the wiring part 311E-2 may be less than or equal to the width W11E of each wiring part 311E-1. At this time, preferably, the depth D2E of the groove 31E-2 is deeper than the depth D1E of each groove 31E-1, and the width W22E of the groove 31E-2 is less than or equal to the width W21E of each groove 31E-1. In other words, the groove 31E-2 should be a groove wider in width than each groove 31E-1, that is, each wiring part 311E-1, and/or deeper than each groove 31E-1, that is, the thickness of each wiring part 311E-1. In these cases as well, the wiring part 311E-2 may be used as an alignment mark.

Similarly, it is suitable in a case where the width W14E of the wiring part 312E-2 is wider than the width W13E of each wiring part 312E-1 and the thickness T4E of the wiring part 312E-2 is thicker than the thickness T3E of each wiring part 312E-1; however, the configuration is not limited thereto. For example, in a case where the width W14E of the wiring part 312E-2 is wider than the width W13E of each wiring part 312E-1, the thickness T4E of the wiring part 312E-2 may be less than or equal to the thickness T3E of each wiring part 312E-1. At this time, preferably, the width W24E of the groove 32E-2 is wider than the width W23E of each groove 32E-1, and the depth D4E of the groove 32E-2 is less than or equal to the depth D3E of each groove 32E-1. Similarly, in a case where the thickness T4E of the wiring part 312E-2 is thicker than the thickness T3E of each wiring part 312E-1, the width W14E of the wiring part 312E-2 may be less than or equal to the width W13E of each wiring part 312E-1. At this time, preferably, the width D4E of the groove 32E-2 is deeper than the depth D3E of each groove 32E-1, and the width W24E of the groove 32E-2 is less than or equal to the width W23E of each groove 32E-1. In other words, the groove 32E-2 should be a groove wider in width than each groove 32E-1, that is, each wiring part 312E-1, and/or deeper than each groove 32E-1, that is, the thickness of each wiring part 312E-1. In these cases as well, the wiring part 312E-2 may be used as an alignment mark.

A case where the wiring part group 311E, that is, the plurality of wiring parts 311E-0, includes one wiring part 311E-2 has been described; however, the configuration is not limited thereto. The wiring part group 311E may include two or more wiring parts 311E-2. At this time, of the plurality of wiring parts 311E-0, each of the two wiring parts located at both ends in the X direction is preferably the wiring part 311E-2.

Similarly, a case where the wiring part group 312E, that is, the plurality of wiring parts 312E-0, includes one wiring part 312E-2 has been described; however, the configuration is not limited thereto. The wiring part group 312E may include two or more wiring parts 312E-2. At this time, of the plurality of wiring parts 312E-0, each of the two wiring parts located at both ends in the X direction is preferably the wiring part 312E-2.

A case where each of the plurality of wiring parts 311E-0 is wire has been described; however, the configuration is not limited thereto. Each of the plurality of wiring parts 311E-0 should be a conductor. Thus, one or some or all of the plurality of wiring parts 311E-0 may be, for example, conductor patterns.

Similarly, a case where each of the plurality of wiring parts 312E-0 is wire has been described; however, the configuration is not limited thereto. Each of the plurality of wiring parts 312E-0 should be a conductor.

Thus, one or some or all of the plurality of wiring parts 312E-0 may be, for example, conductor patterns.

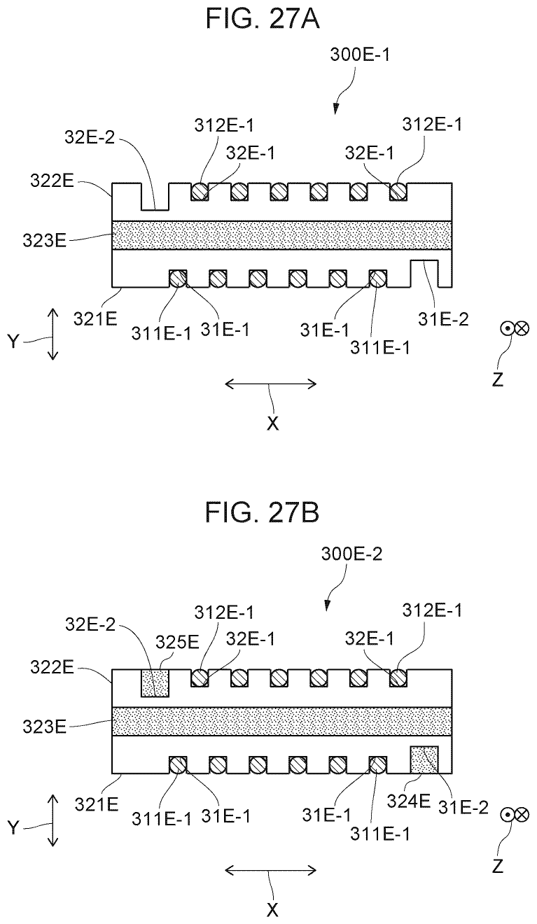

FIGS. 27A and 27B are diagrams of intermediate connecting members 300E-1, 300E-2 according to modifications. In Embodiment 2VI, a case where the wiring parts 311E-2, 312E-2 are respectively disposed in the grooves 31E-2, 32E-2 has been described; however, the configuration is not limited thereto. One or both of the wiring parts 311E-2, 312E-2 of FIG. 26A may be omitted. In the modifications of FIGS. 27A and 27B, both the wiring parts 311E-2, 312E-2 are omitted. The grooves 31E-2, 32E-2 of the intermediate connecting member 300E-1 shown in FIG. 27A are not filled with anything, and the grooves 31E-2, 32E-2 are used as alignment marks.

Insulators 324E, 325E are respectively disposed in the grooves 31E-2, 32E-2 of the intermediate connecting member 300E-2 shown in FIG. 27B. The insulators 324E, 325E are insulators (not shown) made of a material or with a color different from the insulating substrate parts 321E, 322E, and the insulators 324E, 325E are used as alignment marks.

### Embodiment 2VII

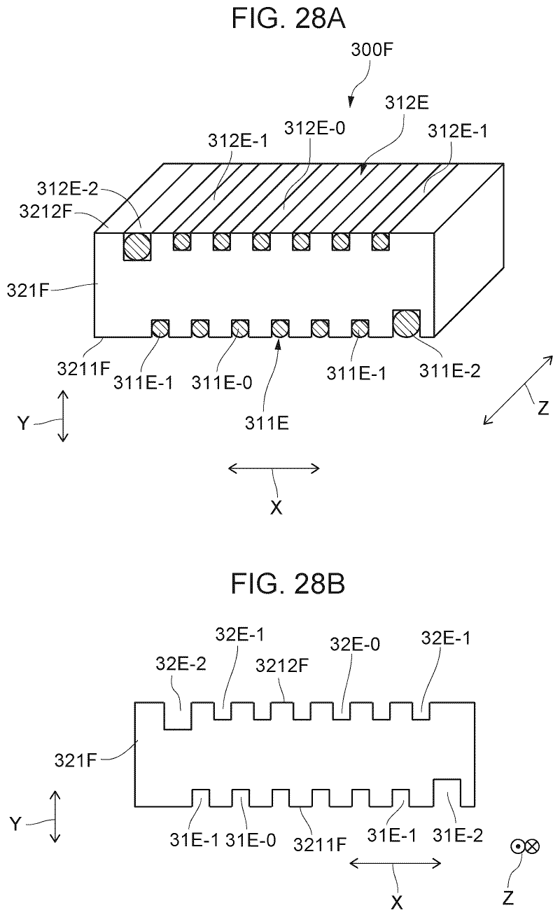

Next, an intermediate connecting member according to Embodiment 2VII will be described. FIG. 28A is a perspective view of an intermediate connecting member 300F according to Embodiment 2VII. The intermediate connecting member 300F according to Embodiment 2VII is configured such that, in the intermediate connecting member 300E according to Embodiment 2VI, the insulating substrate part 321E, the insulating substrate part 322E, and the insulating layer part 323E are replaced with an insulating substrate part 321F. A manufacturing method for the intermediate connecting member 300F according to Embodiment 2VII is configured such that, in the manufacturing method for the intermediate connecting member 300E according to Embodiment 2VI, the step of bonding the insulating substrate part 321E and the insulating substrate part 322E is omitted.

The intermediate connecting member 300F, as in the case of Embodiment 2VI, has a wiring part group 311E and a wiring part group 312E. The intermediate connecting member 300F has the insulating substrate part 321F. The insulating substrate part 321F is a first insulating substrate part. The insulating substrate part 321F is made of the same material as the material of the insulating substrate parts 321, 322 described in Embodiment 2I, for example, glass epoxy.

In Embodiment 2VII, the wiring part group 311E has a plurality of, for example, seven wiring parts 311E-0 as a plurality of first wiring parts. The material of each wiring part 311E-0 is a conductive material, for example, copper. The plurality of wiring parts 311E-0 includes at least one, for example, six wiring parts 311E-1, and at least one, for example, one wiring part 311E-2. The wiring part group 312E is disposed with a space in the Y direction from the wiring part group 311E. The wiring part group 312E has, for example, seven wiring parts 312E-0 serving as a plurality of second wiring parts. The plurality of wiring parts 311E-0 includes at least one, for example, six wiring parts 312E-1, and at least one, for example, one wiring part 312E-2.

In a manufacturing process of the image pickup module according to Embodiment 2VII, to increase alignment accuracy between the intermediate connecting member 300F and the wiring board 221 shown in FIG. 19C, an alignment mark is preferably provided on the intermediate connecting member 300F in advance. By providing an alignment mark on the intermediate connecting member 300F, wiring parts can be disposed with high accuracy in the image pickup module.

In Embodiment 2VII, the wiring part 311E-2 of the plurality of wiring parts 311E-0 and the wiring part 312E-2 of the plurality of wiring parts 312E-0 are used as alignment marks. Of the plurality of wiring parts 311E-0, the wiring part located at an end in the X direction is the wiring part 311E-2. Of the plurality of wiring parts 312E-0, the wiring part located at an end in the X direction is the wiring part 312E-2. The widths and thicknesses of each wiring part 311E-1, wiring part 311E-2, each wiring part 312E-1, and wiring part 312E-2 are as described in Embodiment 2VI.

Each of the plurality of wiring parts 311E-0 and the plurality of wiring parts 312E-0 is made up of, for example, wire. In Embodiment 2VII, the plurality of wiring parts 311E-0 and the plurality of wiring parts 312E-0 are disposed in the same insulating substrate part 321F. Hereinafter, the configuration of the insulating substrate part 321F on which the wiring parts 311E-0 and the wiring parts 312E-0 are disposed will be specifically described.

FIG. 28B is a diagram of the insulating substrate part 321F according to Embodiment 2VII. FIG. 28B is a plan view when the insulating substrate part 321F is viewed in the Z direction. The insulating substrate part 321F has a surface 3211F and a surface 3212F on an opposite side to the surface 3211F in the Y direction.

The plurality of wiring parts 311E-0 is disposed on the surface 3211F. The plurality of wiring parts 312E-0 is disposed on the surface 3212F. In other words, the plurality of wiring parts 311E-0 is disposed on the outer surface 3211F of the insulating substrate part 321F, and the plurality of wiring parts 312E-0 is disposed on the outer surface 3212F of the insulating substrate part 321F. An insulating layer (not shown) may be provided on each of the surface 3211F and the surface 3212F.

A plurality of grooves 31E-0 corresponding to the plurality of wiring parts 311E-0 and configured similarly to those of Embodiment 2VI is formed on the surface 3211F. The plurality of grooves 31E-0 is formed with a space from each other in the X direction. Each groove 31E-0 extends in the Z direction. The plurality of grooves 31E-0 includes a plurality of grooves 31E-1 corresponding to the plurality of wiring parts 311E-1 and a groove 31E-2 corresponding to the wiring part 311E-2. The groove 31E-2 is a first groove. Each wiring part 311E-1 is disposed in a corresponding one of the grooves 31E-1. The wiring part 311E-2 is disposed in the groove 31E-2.

A plurality of grooves 32E-0 corresponding to the plurality of wiring parts 312E-0 and configured similarly to those of Embodiment 2VI is formed on the surface 3212F. The plurality of grooves 32E-0 is formed with a space from each other in the X direction. Each groove 32E-0 extends in the Z direction. The plurality of grooves 32E-0 includes a plurality of grooves 32E-1 corresponding to the plurality of wiring parts 312E-1 and a groove 32E-2 corresponding to the wiring part 312E-2. The groove 32E-2 is a second groove. Each wiring part 312E-1 is disposed in a corresponding one of the grooves 32E-1. The wiring part 312E-2 is disposed in the groove 32E-2.

In Embodiment 2VII, the widths and depths of each groove 31E-1, groove 31E-2, each groove 32E-1, and groove 32E-2 are as described in Embodiment 2VI.

In this way, when viewed in the Z direction, the area of the wiring part 311E-2 is larger than the area of the wiring part 311E-1, and the area of the wiring part 312E-2 is larger than the area of the wiring part 312E-1. Thus, by using each of the wiring parts 311E-2, 312E-2 as an alignment mark, alignment accuracy of the intermediate connecting member 300F with respect to the wiring board 221 shown in FIG. 19C increases. When viewed in the Z direction, since the area of each of the wiring parts 311E-2, 312E-2 is large, a self-alignment effect of the intermediate connecting member 300F with respect to the wiring board 221 at the time of joining the wiring board 221 to the intermediate connecting member 300F by solder increases.

In Embodiment 2VII, the wiring part 311E-2 included in the plurality of wiring parts 311E-0 and the wiring part 312E-2 included in the plurality of wiring parts 312E-0 are shifted in the X direction. In other words, of the plurality of wiring parts 311E-0 and the plurality of wiring parts 312E-0, a spaced distance between the wiring part 311E-2 and the wiring part 312E-2 is longer than a spaced distance between other two wiring parts. Thus, in a manufacturing process of the image pickup module according to Embodiment 2VII, alignment accuracy of the intermediate connecting member 300F with respect to the wiring board 221 further increases.

In Embodiment 2VII as well, modifications similar to the modifications of Embodiment 2VI are possible.

### Embodiment 2VIII

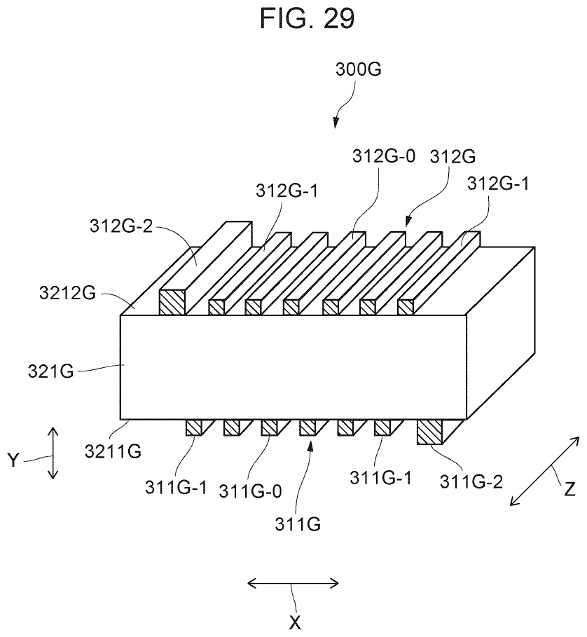

Next, an intermediate connecting member according to Embodiment 2VIII will be described. FIG. 29 is a perspective view of an intermediate connecting member 300G according to Embodiment 2VIII.

The intermediate connecting member 300G has a wiring part group 311G and a wiring part group 312G. The intermediate connecting member 300G has an insulating substrate part 321G that is a first insulating substrate part. The insulating substrate part 321G is made of the same material as the material of the insulating substrate parts 321, 322 described in Embodiment 2I, for example, glass epoxy.

In Embodiment 2VIII, the wiring part group 311G has, for example, seven wiring parts 311G-0 as a plurality of first wiring parts. The material of each wiring part 311G-0 is a conductive material, for example, copper. The plurality of wiring parts 311G-0 includes at least one, for example, six wiring parts 311G-1, and at least one, for example, one wiring part 311G-2. The wiring part group 312G is disposed with a space in the Y direction from the wiring part group 311G. The wiring part group 312G has, for example, seven wiring parts 312G-0 serving as a plurality of second wiring parts. The plurality of wiring parts 312G-0 includes at least one, for example, six wiring parts 312G-1, and at least one, for example, one wiring part 312G-2.

In a manufacturing process of the image pickup module according to Embodiment 2VIII, to increase alignment accuracy between the intermediate connecting member 300G and the wiring board 221 shown in FIG. 19C, an alignment mark is preferably provided on the intermediate connecting member 300G in advance. By providing an alignment mark on the intermediate connecting member 300G, wiring parts can be disposed with high accuracy in the image pickup module.

In Embodiment 2VIII, the wiring part 311G-2 of the plurality of wiring parts 311G-0 and the wiring part 312G-2 of the plurality of wiring parts 312G-0 are used as alignment marks. Of the plurality of wiring parts 311G-0, the wiring part located at an end in the X direction is the wiring part 311G-2. Of the plurality of wiring parts 312G-0, the wiring part located at an end in the X direction is the wiring part 312G-2. The widths and thicknesses of each wiring part 311G-1, wiring part 311G-2, each wiring part 312G-1, and wiring part 312G-2 are as described in Embodiment 2VI.

Each of the plurality of wiring parts 311G-0 and the plurality of wiring parts 312G-0 is made up of, for example, a conductor pattern. In Embodiment 2VIII, the plurality of wiring parts 311G-0 and the plurality of wiring parts 312G-0 are disposed in the same insulating substrate part 321G.

The insulating substrate part 321G has a surface 3211G and a surface 3212G on an opposite side to the surface 3211G in the Y direction. The plurality of wiring parts 311G-0 is disposed on the surface 3211G. The plurality of wiring parts 312G-0 is disposed on the surface 3212G. In other words, the plurality of wiring parts 311G-0 is disposed on the outer surface 3211G of the insulating substrate part 321G, and the plurality of wiring parts 312G-0 is disposed on the outer surface 3212G of the insulating substrate part 321G. An insulating layer (not shown) may be provided on each of the surface 3211G and the surface 3212G.

In this way, when viewed in the Z direction, the area of the wiring part 311G-2 is larger than the area of the wiring part 311G-1, and the area of the wiring part 312G-2 is larger than the area of the wiring part 312G-1. Thus, by using each of the wiring parts 311G-2, 312G-2 as an alignment mark, alignment accuracy of the intermediate connecting member 300G with respect to the wiring board 221 shown in FIG. 19C increases. When viewed in the Z direction, since the area of each of the wiring parts 311G-2, 312G-2 is large, a self-alignment effect of the intermediate connecting member 300G with respect to the wiring board 221 at the time of joining the wiring board 221 to the intermediate connecting member 300G by solder increases.

In Embodiment 2VIII, the wiring part 311G-2 included in the plurality of wiring parts 311G-0 and the wiring part 312G-2 included in the plurality of wiring parts 312G-0 are shifted in the X direction. In other words, of the plurality of wiring parts 311G-0 and the plurality of wiring parts 312G-0, a spaced distance between the wiring part 311G-2 and the wiring part 312G-2 is longer than a spaced distance between other two wiring parts. Thus, in a manufacturing process of the image pickup module according to Embodiment 2VIII, alignment accuracy of the intermediate connecting member 300G with respect to the wiring board 221 further increases.

In Embodiment 2VIII, a case where the wiring part 311G-2 and the wiring part 312G-2 are used as alignment marks has been described; however, the configuration is not limited thereto. For example, the wiring part 312G-2 may be omitted, and the wiring part 311G-2 may be used as an alignment mark. In the intermediate connecting member 300G, the wiring part group 312G, that is, the plurality of wiring parts 312G-0, may be omitted. In this case as well, the wiring part 311G-2 should be used as an alignment mark.

The widths and/or thicknesses of the wiring parts 311G-2, 312G-2 in Embodiment 2VIII may also be modified similarly to the modifications of the widths and/or thicknesses of the wiring parts 311D-2, 312D-2 in Embodiment 2V.

A case where the wiring part group 311G, that is, the plurality of wiring parts 311G-0, includes one wiring part 311G-2 has been described; however, the configuration is not limited thereto. The wiring part group 311G may include two or more wiring parts 311G-2. At this time, of the plurality of wiring parts 311G-0, each of the two wiring parts located at both ends in the X direction is preferably the wiring part 311G-2.

Similarly, a case where the wiring part group 312G, that is, the plurality of wiring parts 312G-0, includes one wiring part 312G-2 has been described; however, the configuration is not limited thereto. The wiring part group 312G may include two or more wiring parts 312G-2. At this time, of the plurality of wiring parts 312G-0, each of the two wiring parts located at both ends in the X direction is preferably the wiring part 312G-2.

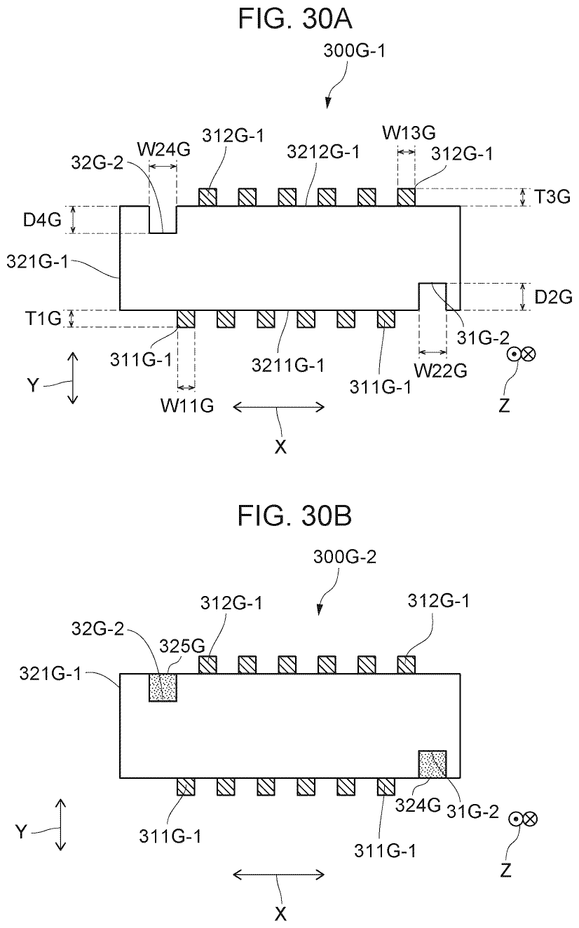

FIGS. 30A and 30B are diagrams of intermediate connecting members 300G-1, 300G-2 according to modifications. Initially, the intermediate connecting member 300G-1 according to the modification shown in FIG. 30A will be described. The intermediate connecting member 300G-1 has an insulating substrate part 321G-1, a plurality of wiring parts 311G-1, and a plurality of wiring parts 312G-1. The insulating substrate part 321G-1 has a surface 3211G-1 having grooves 31G-2 and a surface 3212G-1 having grooves 32G-2. The surface 3212G-1 is a surface on an opposite side to the surface 3211G-1 in the Y direction. The groove 31G-2 is a first groove, and the groove 32G-2 is a second groove.

The groove 31G-2 is preferably a groove that is wider than the width W11G of each wiring part 311G-1 and/or deeper than the thickness T1G of each wiring part 311G-1. In the intermediate connecting member 300G-1 according to the modification shown in FIG. 30A, the width W22G in the X direction of the groove 31G-2 is wider than the width W11G in the X direction of the wiring part 311G-1. The depth D2G in the Y direction of the groove 31G-2 is deeper than the thickness T1G in the Y direction of the wiring part 311G-1.

The groove 32G-2 is preferably a groove that is wider than the width W13G of each wiring part 312G-1 and/or deeper than the thickness T3G of each wiring part 312G-1. In the intermediate connecting member 300G-1 according to the modification shown in FIG. 30A, the width W24G in the X direction of the groove 32G-2 is wider than the width W13G in the X direction of the wiring part 312G-1. The depth D4G in the Y direction of the groove 32G-2 is deeper than the thickness T3G in the Y direction of the wiring part 312G-1.

With the above configuration, by using each of the grooves 31G-2, 32G-2 as alignment marks, alignment accuracy of the intermediate connecting member 300G-1 with respect to the wiring board 221 shown in FIG. 19C increases.

The groove 31G-2 and the groove 32G-2 are preferably shifted in the X direction. In the intermediate connecting member 300G-1, the groove 32G-2 may be omitted. The insulating substrate part 321G-1 may have a plurality of grooves 31G-2 or may have a plurality of grooves 32G-2.

The intermediate connecting member 300G-2 according to the modification shown in FIG. 30B will be described. The intermediate connecting member 300G-2, as in the case of the intermediate connecting member 300G-1, has an insulating substrate part 321G-1, a plurality of wiring parts 311G-1, and a plurality of wiring parts 312G-1. Insulators 324G, 325G are respectively disposed in the grooves 31G-2, 32G-2 of the intermediate connecting member 300G-2 shown in FIG. 30B. The insulators 324G, 325G are insulators (not shown) made of a material or with a color different from the insulating substrate parts 321G-1, and the insulators 324G, 325G are used as alignment marks.

With the above configuration, by using the insulators 324G, 325G as alignment marks, alignment accuracy of the intermediate connecting member 300G-2 with respect to the wiring board 221 shown in FIG. 19C increases.

The groove 31G-2 and the groove 32G-2 are preferably shifted in the X direction. In the intermediate connecting member 300G-2, the groove 32G-2 and the insulator 325G may be omitted. The insulating substrate part 321G-1 may have a plurality of grooves 31G-2 or may have a plurality of grooves 32G-2.

The present invention is not limited to the above-described embodiments, and many modifications are applicable within the technical concept of the present invention. For example, a plurality of embodiments may be combined. The matter of part of at least one embodiment may be deleted or replaced. A new matter may be added to at least one embodiment. For example, in Embodiments 2VI to 2VIII, at least part, other than both end faces in the Z direction, of each of the plurality of wiring parts 312 may be covered with an insulating film, such as a solder resist film, provided on the insulating substrate part 321. A short circuit and corrosion of the plurality of wiring parts 312 can be suppressed by the insulating film.

In the above-described embodiments, a case where the electronic component is an image sensor or a memory element has been described as an example; however, the configuration is not limited thereto. For example, the electronic component may be a semiconductor apparatus or power IC for image processing. For example, the electronic component may be a semiconductor apparatus or control IC for communication. An example in which the electronic module is an image pickup module has been described as an example; however, the configuration is not limited thereto. For example, the electronic module may be a memory module, a signal processing module, a power module, a communication module, or a control module.

A case where the electronic apparatus is a digital camera has been described as an example; however, the configuration is not limited thereto. For example, the electronic apparatus may be a mobile communication device. For example, the electronic apparatus may be an information device, such as a smartphone and a personal computer, or a communication device, such as a modem and a router. Alternatively, the electronic apparatus may be a business machine, such as a printer and a copying machine, a medical apparatus, such as a radiographic apparatus, a magnetic imaging apparatus, an ultrasonic imaging apparatus, and an endoscope, an industrial apparatus, such as a robot and a semiconductor manufacturing apparatus, or a transportation apparatus, such as a vehicle, a plane, and a ship. In a case where wiring lines are provided in a limited space in the casing of an electronic apparatus, a reduction in the size and high density of the electronic apparatus are possible when the intermediate connecting member 300 is used. The electronic module according to the present invention is applicable to any electronic apparatus.

### Embodiment 3I

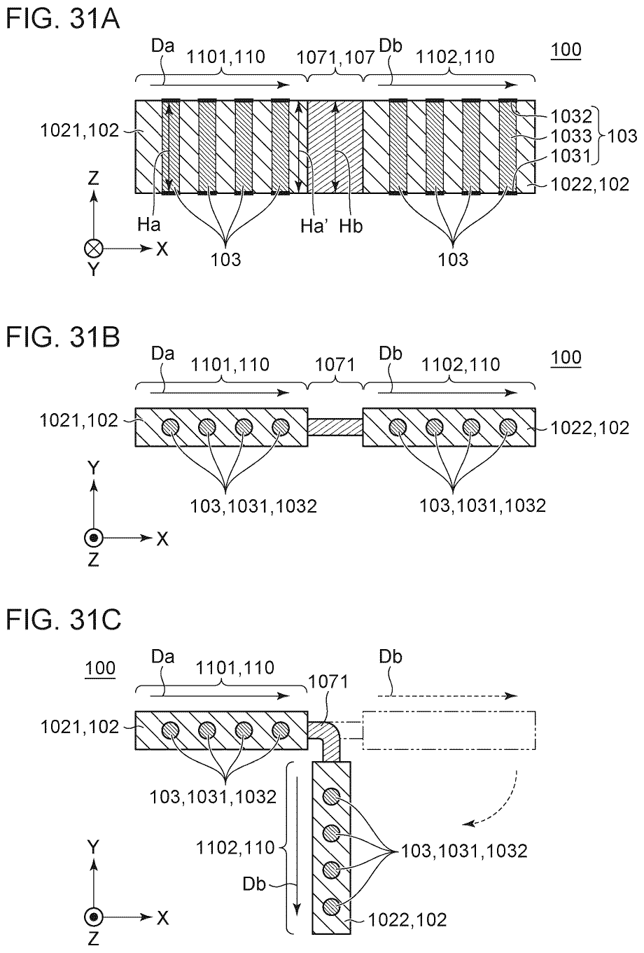

A wiring component 100 according to Embodiment 3I will be described with reference to FIGS. 31A to 31C. FIG. 31A is a side view of the wiring component 100. FIGS. 31B and 31C are a top view or a bottom view of the wiring component 100.

The wiring component 100 includes a wiring part 1101, a wiring part 1102, and a coupling part 1071. Hereinafter, the plurality of wiring parts 1101, 1102 provided in one wiring component 100 are collectively referred to as wiring parts 110. At least one coupling part 1071 provided in one wiring component 100 is collectively referred to as coupling part 107. The wiring part 1101 has a plurality of wiring lines 103 arranged in a direction Da. The wiring part 1102 has a plurality of wiring lines 103 arranged in a direction Db. In FIGS. 31A and 31B, the direction Da and the direction Db are illustrated as directions along the X direction. The wiring part 1101 includes an insulating member 1021 that supports the plurality of wiring lines 103 of the wiring part 1101. The wiring part 1102 includes an insulating member 1022 that supports the plurality of wiring lines 103 of the wiring part 1102. In each of the plurality of wiring parts 110 provided in one wiring component 100, insulating members 1021, 1022 that support the plurality of wiring lines 103 are collectively referred to as insulating members 102. The coupling part 1071 couples the wiring part 1101 to the wiring part 1102. The coupling part 1071 is provided between the wiring part 1101 and the wiring part 1102.

Each of the plurality of wiring lines 103 of the wiring part 1101 and the plurality of wiring lines 103 of the wiring part 1102 has a pair of terminals (a lower surface terminal 1031 and an upper surface terminal 1032) arranged along the Z direction that intersects with the direction Da and the direction Db. The wiring line 103 includes a path 1033 connecting a pair of terminals (the lower surface terminal 1031 and the upper surface terminal 1032). The lower surface terminal 1031 is a part of the wiring line 103, exposed at the lower surface of the wiring part 110, and the upper surface terminal 1032 is a part of the wiring line 103, exposed at the upper surface of the wiring part 110. In this example, the path 1033 is not exposed at the side surface of the wiring part 110; however, the path 1033 may be exposed at the side surface of the wiring part 110.

FIGS. 31B and 31C show that the wiring component 100 deforms. In FIG. 31C, the wiring part 1102 has the plurality of wiring lines 103 arranged in the direction Db indicated by the continuous arrow. In FIG. 31C, the direction Db indicated by the dashed line is the direction Db in FIG. 31B, written for reference. In FIG. 31C, the direction Db indicated by the continuous arrow is illustrated as a direction along the Y direction. The wiring component 100 according to the present embodiment allows to change between a direction in which the plurality of wiring lines 103 of the wiring part 1101 is arranged and a direction in which the plurality of wiring lines 103 of the wiring part 1102 is arranged, as a result of deformation of the coupling part 1071. The wiring component 100 shown in FIG. 31C is bent at the coupling part 1071. A difference between an angle formed between the direction Da and the direction Db before deformation of the coupling part 107 and an angle formed between the direction Da and the direction Db after deformation of the coupling part 107 is preferably larger than or equal to 30 degrees. A difference between an angle formed between the direction Da and the direction Db before deformation of the coupling part 107 and an angle formed between the direction Da and the direction Db after deformation of the coupling part 107 is more preferably larger than or equal to 45 degrees and further preferably larger than or equal to 60 degrees. In FIG. 31B, an angle formed between the direction Da and the direction Db is, for example, zero degrees. In FIG. 31C, an angle formed between the direction Da and the direction Db is, for example, 90 degrees.

The wiring part 1101 and the wiring part 1102 have a structure that is more difficult to deform than the coupling part 1071. In other words, the coupling part 1071 has a structure that is easier to deform than the wiring part 1101 and the wiring part 1102. Deformation of the coupling part 1071 may be elastic deformation; however, deformation of the coupling part 1071 is preferably plastic deformation. In a case where the coupling part 1071 has a structure that is difficult to deform, if the wiring component 100 is attempted to be forcibly bent with excessive force, the coupling part 1071 is broken, and the wiring component 100 snaps, with the result that coupling is not maintained. The hardness of the coupling part 1071 is set as needed so that the coupling part 1071 does not get broken in an ordinary use of the wiring component 100.

In comparison with a mode in which the wiring part 1101 and the wiring part 1102 are individual components and not coupled to each other, handling of the wiring component 100 is easy since the wiring parts 110 are coupled by the coupling part 1071. In comparison with a mode in which the wiring part 1101 and the wiring part 1102 are rigidly fixed to each other, since the coupling part 1071 deforms, the wiring parts 1101, 1102 can be disposed according to a user's request, so general-purpose properties improve. In this way, by providing the deformable coupling part 1071, the convenience of the wiring component 100 improves.

### Embodiment 3II

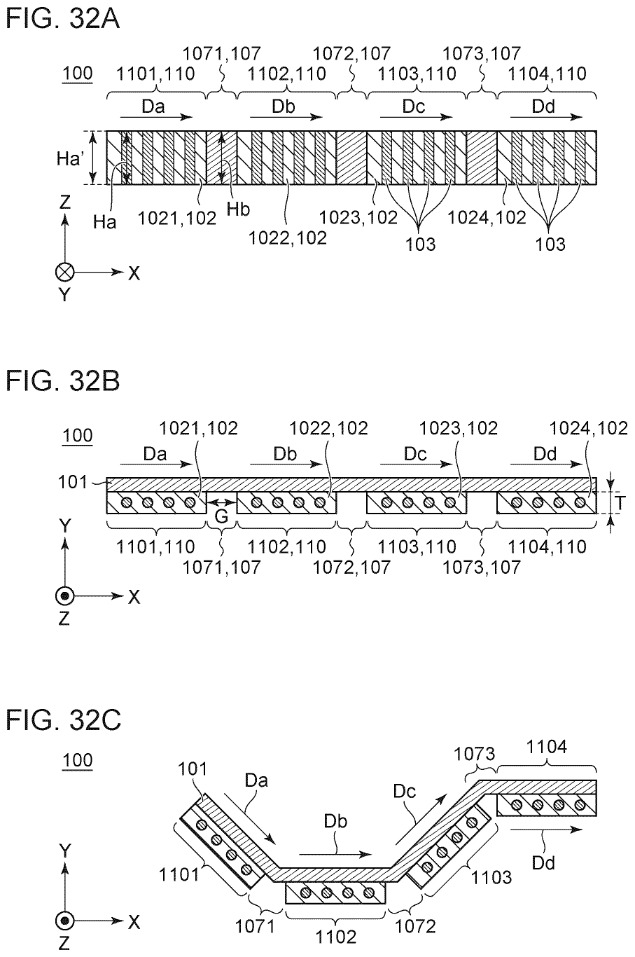

A wiring component 100 according to Embodiment 3II will be described with reference to FIGS. 32A to 32C. In Embodiment 3II, the description of matters common to those in Embodiment 3I is omitted. FIG. 32A is a side view of the wiring component 100. FIGS. 32B and 32C are a top view or a bottom view of the wiring component 100.

The wiring component 100 includes a wiring part 1103 and a coupling part 1072. The wiring part 1103 has a plurality of wiring lines 103 arranged in a direction Dc. In FIGS. 32A and 32B, the direction Dc is illustrated as a direction along the X direction. The wiring part 1103 includes an insulating member 1023 that supports the plurality of wiring lines 103 of the wiring part 1103. The coupling part 1072 couples the wiring part 1102 to the wiring part 1103. The coupling part 1072 is provided between the wiring part 1102 and the wiring part 1103.

The wiring component 100 includes a wiring part 1104 and a coupling part 1073. The wiring part 1104 has a plurality of wiring lines 103 arranged in a direction Dd. In FIGS. 32A and 32B, the direction Dd is illustrated as a direction along the X direction. The wiring part 1104 includes an insulating member 1024 that supports the plurality of wiring lines 103 of the wiring part 1104.

The coupling part 1073 couples the wiring part 1103 to the wiring part 1104. The coupling part 1073 is provided between the wiring part 1103 and the wiring part 1104.

Hereinafter, the plurality of coupling parts 1071, 1072, 1073 provided in one wiring component 100 are collectively referred to as coupling parts 107. The number of the coupling parts 107 provided in one wiring component 100 may be greater than or equal to four.

Each of the plurality of wiring lines 103 of the wiring parts 1103, 1104 has a pair of terminals (a lower surface terminal 1031 and an upper surface terminal 1032) arranged along the Z direction that intersects with the direction Da, the direction Db, the direction Dc, and the direction Dd.

The dimension of the coupling part 1071 in the Z direction that intersects with the directions Da, Db in which the wiring lines 103 are arranged is defined as height Hb. The dimension of the wiring line 103 of the wiring part 110 (the wiring part 1101 or the wiring part 1102) in the Z direction that intersects with the directions Da, Db in which the wiring lines 103 are arranged is defined as height Ha. The wiring line 103 of which the height Ha is defined is one of the plurality of wiring lines 103, and, preferably, each of the plurality of wiring lines 103 has an equal height Ha. The height Ha is a distance between the outer surface of the lower surface terminal 1031 and the outer surface of the upper surface terminal 1032 of one wiring line 103. The height Hb can be greater than or equal to the height Ha (Hb≥Ha). In this example, the dimension (height Hb) of the coupling part 107 (coupling part 1071) in the Z direction that intersects with the direction in which the wiring lines 103 are arranged is equal to the dimension (height Ha) of each of the wiring lines 103 of the wiring part 110 (the wiring part 1101 or the wiring part 1102) in the Z direction that intersects with the direction in which the wiring lines 103 are arranged (Ha=Hb).

Typically, the lower surface or the upper surface of the insulating member 102 and the outer surface of the lower surface terminal 1031 or the upper surface terminal 1032 can be present in the same plane. In this case, the height Ha can be equal to the dimension (height Ha′) of the insulating member 102 (the insulating member 1021, the insulating member 1022, the insulating member 1023, or the insulating member 1024) in the Z direction that intersects with the directions Da, Db in which the wiring lines 103 are arranged (Ha=Ha′). However, the height Ha of the wiring line 103 may be different from the height Ha′ of the insulating member 102. In other words, if the lower surface terminal 1031 or the upper surface terminal 1032 is set back (recessed) from the lower surface or the upper surface of the insulating member 102, the height Ha of the wiring line 103 can be less than the height Ha′ of the insulating member 102 (Ha<Ha′). If the lower surface terminal 1031 or the upper surface terminal 1032 is jutted (projected) from the lower surface or the upper surface of the insulating member 102, the height Ha of the wiring line 103 can be greater than the height Ha′ of the insulating member 102 (Ha>Ha′). The height Ha can be greater than or equal to the dimension (height Ha′) of the insulating member 102 (the insulating member 1021, the insulating member 1022, the insulating member 1023, or the insulating member 1024) in the Z direction that intersects with the directions Da, Db in which the wiring lines 103 are arranged. In other words, the height Hb of the substrate 101 can be greater than or equal to the height Ha′ of the insulating member 102.

A distance (gap G) between the wiring part 1101 and the wiring part 1102 is preferably less than the dimension (thickness T) of the wiring part 110 (the wiring part 1101 or the wiring part 1102) in the Y direction orthogonal to the directions Da, Db in which the wiring lines 103 are arranged. A distance (gap G) between the wiring part 1101 and the wiring part 1102 is preferably less than the dimension (thickness T) of the wiring part 110 (the wiring part 1101 or the wiring part 1102) in the Y direction orthogonal to the Z direction that intersects with the directions Da, Db in which the wiring lines 103 are arranged.

FIGS. 32B and 32C show that the wiring component 100 deforms. In FIG. 32C, the wiring part 1103 has a plurality of wiring lines 103 arranged in a direction Dc. In FIG. 32C, the direction Dc is illustrated as an oblique direction with respect to the X direction and the Y direction. The wiring component 100 according to the present embodiment allows to change between the direction Db in which the plurality of wiring lines 103 of the wiring part 1102 is arranged and the direction Dc in which the plurality of wiring lines 103 of the wiring part 1103 is arranged, as a result of deformation of the coupling part 1072. The wiring component 100 according to the present embodiment allows to change between the direction Dc in which the plurality of wiring lines 103 of the wiring part 1103 is arranged and the direction Dd in which the plurality of wiring lines 103 of the wiring part 1104 is arranged, as a result of deformation of the coupling part 1073. In FIG. 32B, an angle formed between the direction Db and the direction Dc is, for example, zero degrees. In FIG. 32C, an angle formed between the direction Db and the direction Dc is, for example, 45 degrees. In FIG. 32B, an angle formed between the direction Dc and the direction Dd is, for example, zero degrees. In FIG. 32C, an angle formed between the direction Dc and the direction Dd is, for example, 45 degrees. Not limited to the example of FIG. 32C, the direction in which the wiring lines 103 of the wiring part 110 are arranged can be selectively set within the range of zero degrees to 90 degrees.

The wiring component 100 according to Embodiment 3II includes the substrate 101 provided over the wiring part 1101 and the wiring part 1102. The substrate 101 is further provided over the wiring part 1103 and the wiring part 1104. The plurality of wiring parts 110 (the wiring parts 1101, 1102, 1103, 1104) includes the substrate 101. The plurality of coupling parts 107 (1071, 1072, 1073) also includes the substrate 101. Deformation of the coupling part 107 is also given from deformation of the substrate 101.

Deformation of the substrate 101 may be elastic deformation; however, deformation of the substrate 101 is preferably plastic deformation. The wiring part 1102 and the wiring part 1103 each have a structure that is more difficult to deform than the coupling part 1072. The wiring part 1103 and the wiring part 1104 each have a structure that is more difficult to deform than the coupling part 1073. In other words, the coupling parts 1071, 1072, 1073 each have a structure that is easier to deform than the wiring parts 1101, 1102, 1103, 1104.

The substrate 101 preferably has a configuration that is easier to deform than the insulating member 102. For example, a rigid board should be used for the insulating member 102, and a flexible board should be used for the substrate 101. The coupling part 107 may be different in easiness of deformation before and after deformation. For example, the coupling part 107 may be configured to be easy to deform before the coupling part 107 is bent and may be configured to be difficult to deform after the coupling part 107 is bent.

A thermosetting resin may be used for the substrate 101, the substrate 101 may be configured to be easy to plastically deform before thermal curing of the substrate 101 and may be configured to be difficult to plastically deform (configured to elastically deform) after thermal curing of the substrate 101. A thermoplastic resin may be used for the substrate 101, the substrate 101 may be configured to be softened to be easy to plastically deform as a result of heating of the substrate 101, and the substrate 101 may be configured to be hardened to be difficult to plastically deform (hardened to elastically deform) as a result of cooling of the substrate 101.

The coupling part 107 may be made up of only an insulator or may be made up of only a conductor. A metal plate or a metal tape may be used as the substrate 101. A shape memory alloy may be used for the substrate 101. The substrate 101 may be caused to memorize the shape such that the substrate 101 takes a certain posture (for example, a linear shape) at a certain temperature and the substrate 101 takes another posture (for example, a curved shape) at another temperature. The coupling part 107 may be made up of a composite member of an insulator and a conductor.

For example, a member obtained by forming a conductor film on an insulator may be used as the substrate 101.

The wiring part 1101 includes an insulating member 1021 that supports the plurality of wiring lines 103 of the wiring part 1101, and the insulating member 1021 is bonded to the substrate 101 via a binding material. The wiring part 1102 includes an insulating member 1022 that supports the plurality of wiring lines 103 of the wiring part 1102, and the insulating member 1022 is bonded to the substrate 101 via a binding material. In this way, in the wiring parts 110, the plurality of insulating members 102 (the insulating members 1021, 1022, 1023, 1024) that each support the plurality of wiring lines 103 of a corresponding one of the wiring parts 110 can be bonded to the substrate 101 via a binding material. A binding material is a member that joins two members by bonding and can be a pressure sensitive adhesive double coated tape or a member made from curing (solidification) of a liquid adhesive.

### Embodiment 3III

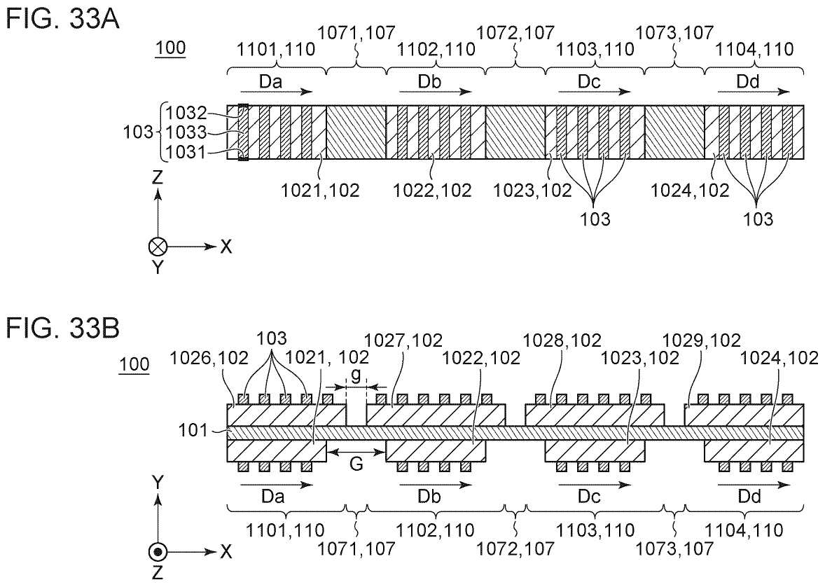

A wiring component 100 according to Embodiment 3III will be described with reference to FIGS. 33A and 33B. In Embodiment 3III, the description of matters common to the other embodiments is omitted. FIG. 33A is a side view of the wiring component 100. FIG. 33B is a top view or a bottom view of the wiring component 100.

In Embodiment 3III, the wiring part 1101 has first-group wiring lines 103 and fifth-group wiring lines 103. The substrate 101 is located between the first-group wiring lines 103 and the fifth-group wiring lines 103.

The wiring part 1101 includes an insulating member 1021 that supports the first-group wiring lines 103 and an insulating member 1026 that supports the fifth-group wiring lines 103. The substrate 101 is located between the insulating member 1021 and the insulating member 1026.

The wiring part 1102 has second-group wiring lines 103 and sixth-group wiring lines 103. The substrate 101 is located between the second-group wiring lines 103 and the sixth-group wiring lines 103. The wiring part 1102 includes an insulating member 1022 that supports the second-group wiring lines 103 and an insulating member 1027 that supports the sixth-group wiring lines 103. The substrate 101 is located between the insulating member 1022 and the insulating member 1027. The wiring part 1103 has third-group wiring lines 103 and seventh-group wiring lines 103. The substrate 101 is located between the third-group wiring lines 103 and the seventh-group wiring lines 103. The wiring part 1103 includes an insulating member 1023 that supports the third-group wiring lines 103 and an insulating member 1028 that supports the seventh-group wiring lines 103. The substrate 101 is located between the insulating member 1023 and the insulating member 1028. The wiring part 1104 has fourth-group wiring lines 103 and eighth-group wiring lines 103. The substrate 101 is located between the fourth-group wiring lines 103 and the eighth-group wiring lines 103. The wiring part 1104 includes an insulating member 1024 that supports the fourth-group wiring lines 103 and an insulating member 1029 that supports the eighth-group wiring lines 103. The substrate 101 is located between the insulating member 1024 and the insulating member 1029.

In this way, when the wiring lines 103 are disposed on both surfaces of the substrate 101, the number of wiring lines can be increased. In this example, the path 1033 is exposed at the side surface of the wiring part 110; however, the path 1033 does not need to be exposed at the side surface of the wiring part 110.

### Embodiment 3IV

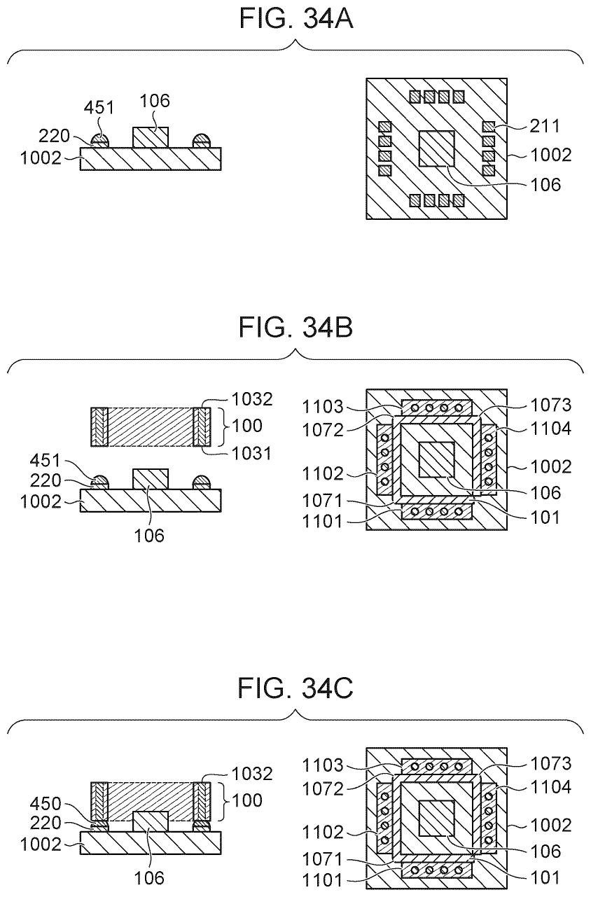

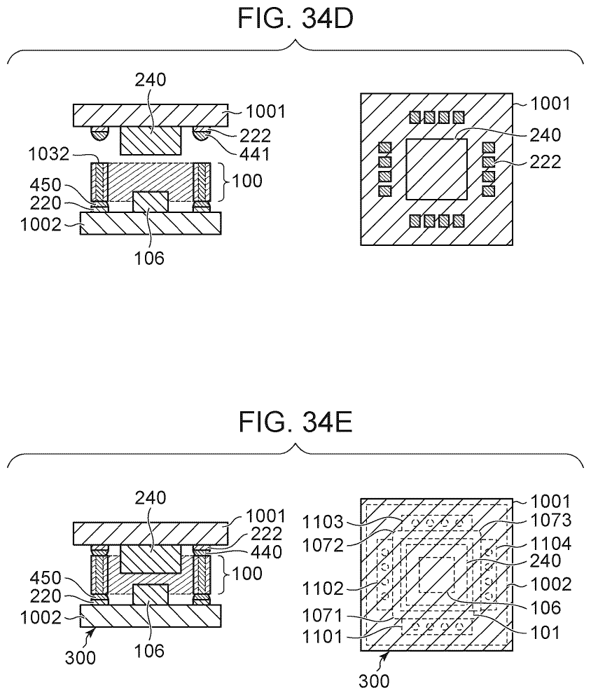

A manufacturing method for a module using the wiring component 100 will be described with reference to FIGS. 34A to 34F. In FIGS. 34A to 34F, the left side is a sectional view, and the right side is a plan view.

In step Sa shown in FIG. 34A, a wiring board 1002 having electrodes 220 is prepared. A solder paste 451 is disposed on each electrode 220. An electronic component 106 is disposed on the wiring board 1002. The electronic component 106 may be already fixed to the wiring board 1002 at the stage of step Sb or a solder paste before being heated may be provided between the electronic component 106 and the wiring board 1002 at the stage of step Sb.

In step Sb shown in FIG. 34B, the wiring component 100 described in another embodiment (in this example, the wiring component 100 described in Embodiment 3II) is prepared. The wiring component 100 includes a substrate 101 that is a component of the coupling parts 1071, 1072, 1073. The substrate 101 has a part included in the wiring part 1101, a part included in the wiring part 1102, a part included in the wiring part 1103, and a part included in the wiring part 1104.

The wiring component 100 is deformed into an adequate shape. In the wiring component 100 before deformation, an angle formed between the direction in which the wiring lines 103 of the wiring part 1101 are arranged and a direction in which the wiring lines 103 of the wiring part 1102 are arranged is defined as θa. In the wiring component 100 after deformation, an angle formed between the direction in which the wiring lines 103 of the wiring part 1101 are arranged and the direction in which the wiring lines 103 of the wiring part 1102 are arranged is defined as Gb. Typically, the angle θb is larger than the angle θa. For example, the wiring component 100 before deformation is in a state where the plurality of wiring parts 110 is arranged in a straight line or in a state where the plurality of wiring parts 110 is folded, and the angle θa is smaller than 45 degrees, for example, zero degrees. On the other hand, the wiring component 100 after deformation is obtained by bending the straight wiring component 100 or expanding the folded wiring component 100, and the angle θb is larger than or equal to 45 degrees, for example, 90 degrees.

Similarly, in the wiring component 100 before deformation, an angle formed between the direction in which the wiring lines 103 of the wiring part 1102 are arranged and the direction in which the wiring lines 103 of the wiring part 1103 are arranged is defined as θc. In the wiring component 100 after deformation, an angle formed between the direction in which the wiring lines 103 of the wiring part 1102 are arranged and the direction in which the wiring lines 103 of the wiring part 1103 are arranged is defined as ωd. Typically, the angle θd is larger than the angle θc. In the wiring component 100 before deformation, an angle formed between the direction in which the wiring lines 103 of the wiring part 1103 are arranged and the direction in which the wiring lines 103 of the wiring part 1104 are arranged is defined as θe. In the wiring component 100 after deformation, an angle formed between the direction in which the wiring lines 103 of the wiring part 1103 are arranged and the direction in which the wiring lines 103 of the wiring part 1104 are arranged is defined as θf. Typically, the angle θf is larger than the angle θe. In the wiring component 100 before deformation, an angle formed between the direction in which the wiring lines 103 of the wiring part 1104 are arranged and the direction in which the wiring lines 103 of the wiring part 1101 are arranged is defined as θg. In the wiring component 100 after deformation, an angle formed between the direction in which the wiring lines 103 of the wiring part 1104 are arranged and the direction in which the wiring lines 103 of the wiring part 1101 are arranged is defined as θh. Typically, the angle θh is larger than the angle θg.

In this example, as a result of deformation, the part of the substrate 101, included in the wiring part 1101, and the part of the substrate 101, included in the wiring part 1103, can be located between the plurality of wiring lines 103 included in the wiring part 1101 and the plurality of wiring lines 103 included in the wiring part 1103. The part of the substrate 101, included in the wiring part 1102, and the part of the substrate 101, included in the wiring part 1104, can be located between the plurality of wiring lines 103 included in the wiring part 1102 and the plurality of wiring lines 103 included in the wiring part 1104. In other words, the wiring component 100 is deformed such that the plurality of wiring lines 103 surrounds the substrate 101.

In another example, as a result of deformation, the plurality of wiring lines 103 included in the wiring part 1101 and the plurality of wiring lines 103 included in the wiring part 1103 can be located between the part of the substrate 101, included in the wiring part 1101, and the part of the substrate 101, included in the wiring part 1103. The plurality of wiring lines 103 included in the wiring part 1102 and the plurality of wiring lines 103 included in the wiring part 1104 can be located between the part of the substrate 101, included in the wiring part 1102, and the part of the substrate 101, included in the wiring part 1104. In other words, the wiring component 100 is deformed such that the substrate 101 surrounds the plurality of wiring lines 103.

In a case where the wiring lines 103 are present only on one side of the substrate 101 as in the case of Embodiment 3II, when the plurality of wiring lines 103 is disposed so as to surround the substrate 101, a larger number of the wiring lines 103 can be disposed as compared to a case where the substrate 101 is disposed so as to surround the plurality of wiring lines 103. This is because, when the wiring component 100 is bent into a state where the wiring lines 103 are placed on the inner side of the substrate 101, the space between the wiring parts 110 narrows; whereas, when the wiring component 100 is bent into a state where the wiring lines 103 are placed on the outer side of the substrate 101, the space between the wiring parts 110 widens. For this reason, in comparison with a case where the wiring component 100 is bent into a state where the wiring lines 103 are placed on the inner side of the substrate 101, the influence of mechanical interference between the adjacent wiring parts 110 is small when the wiring component 100 is bent into a state where the wiring lines 103 are placed on the outer side of the substrate 101. To bend the wiring component 100 into a state where the wiring lines 103 are placed on the inner side of the substrate 101, the length of the coupling part 107 is appropriately greater than or equal to twice the thickness T of the wiring part 110. However, when the wiring component 100 is bent into a state where the wiring lines 103 are placed on the outer side of the substrate 101, the gap G between the wiring parts 110 can be less than or equal to the thickness T of the wiring part 110. By reducing the gap G between the wiring parts 110 and increasing the length of the wiring part 110, the number of the wiring lines 103 can be increased.

The gap G between the wiring parts 110 (for example, a distance between the wiring part 1101 and the wiring part 1102) is preferably less than the dimension (thickness T) of the wiring part 110 (the wiring part 1101 or the wiring part 1102) in the direction (Y direction) orthogonal to the directions Da, Db in which the wiring lines 103 are arranged. The gap G between the wiring parts 110 (for example, a distance between the wiring part 1101 and the wiring part 1102) is preferably less than the dimension (thickness T) of the wiring part 110 (the wiring part 1101 or the wiring part 1102) in the direction (Y direction) orthogonal to Z direction in which the wiring lines 103 extend.

When the wiring lines 103 are provided on both surfaces of the substrate 101 as in the case of Embodiment 3III, a plurality of outer wiring lines 103 surrounds the substrate 101 and the substrate 101 surrounds a plurality of inner wiring lines 103. In Embodiment 3III, the gap g between any adjacent two of the insulating members 1026, 1027, 1028, 1029 is greater than the gap G between any adjacent two of the insulating members 1021, 1022, 1023, 1024. The wiring component 100 is disposed such that the insulating members 1026, 1027, 1028, 1029 surround the substrate 101 and the substrate 101 surrounds the insulating members 1021, 1022, 1023, 1024. This is because, on the outer side where the influence of mechanical interference between the adjacent wiring parts 110 is small, the length of the wiring part 110 can be increased by reducing the gap g between the wiring parts 110.

The wiring component 100 deformed in this way is disposed on the wiring board 1002. The wiring component 100 and the wiring board 1002 are aligned with each other. Alignment is performed such that, for example, the lower surface terminals 1031 and the electrodes 220 are opposed to each other.

In step Sc shown in FIG. 34C, the wiring component 100 is disposed on the wiring board 1002. Then, one (lower surface terminal 1031) of each pair of terminals of the wiring component 100 is connected to a corresponding one of the electrodes 220 of the wiring board 1002. For example, each lower surface terminal 1031 of the wiring component 100 and the corresponding electrode 220 of the wiring board 1002 are electrically connected by solder 450 obtained from a solder paste 451 by melting the solder paste 451 in a reflow furnace and cooling the solder paste 451.

In step Sd shown in FIG. 34D, a wiring board 1001 having electrodes 222 is prepared. A solder paste 441 is disposed on each electrode 222. An electronic component 240 is disposed on the wiring board 1001. The electronic component 240 may be already fixed to the wiring board 1001 at the stage of step Sd or a solder paste before being heated may be provided between the electronic component 240 and the wiring board 1001 at the stage of step Sd.

Furthermore, in step Sd, the wiring component 100, the wiring board 1002, and the wiring board 1001 are disposed such that the wiring component 100 is located between the wiring board 1002 and the wiring board 1001. Then, the wiring component 100 and the wiring board 1001 are aligned with each other. Alignment is performed such that, for example, the upper surface terminals 1032 and the electrodes 222 are opposed to each other.

In step Se shown in FIG. 34E, the other one (upper surface terminal 1032) of each pair of terminals of the wiring component 100 is connected to a corresponding one of the electrodes 222 of the wiring board 1001. For example, each upper surface terminal 1032 of the wiring component 100 and the corresponding electrode 222 of the wiring board 1001 are electrically connected by solder 440 obtained from a solder paste 441 by melting the solder paste 441 in a reflow furnace and cooling the solder paste 441.

The electronic component 106 is mounted on the wiring board 1002 at a selected stage. Before the wiring board 1002 and the wiring component 100 are fixed to each other in step Sc, the wiring board 1001 and the electronic component 106 may be fixed to each other. Alternatively, at the time when the wiring board 1002 and the wiring component 100 are fixed to each other in step Sc, the wiring board 1001 and the electronic component 106 may be fixed to each other. In this case, printing or reflow of solder paste for fixing the wiring component 100 to the wiring board 1002 may be concurrently performed with printing or reflow of solder paste for fixing the electronic component 106 to the wiring board 1002. After the wiring board 1002 and the wiring component 100 are fixed to each other in step Sc, the wiring board 1001 and the electronic component 106 may be fixed to each other; however, the wiring component 100 can interfere with disposing the electronic component 106. In this example, the electronic component 106 is mounted on the wiring board 1002 on the wiring component 100 side (wiring board 1001 side). When the electronic component 106 is mounted on the wiring board 1002 on an opposite side to the wiring component 100, there is a low possibility that the wiring component 100 interferes with arrangement of the electronic component 106. An electronic component may be mounted on each side of the wiring board 1002.

The electronic component 240 is mounted on the wiring board 1001 at a selected stage. Before the wiring board 1001 and the wiring component 100 are fixed to each other in step Se, the wiring board 1001 and the electronic component 240 may be fixed to each other. Alternatively, at the time when the wiring board 1001 and the wiring component 100 are fixed to each other in step Sd, the wiring board 1001 and the electronic component 240 may be fixed to each other. In this case, printing or reflow of solder paste for fixing the wiring component 100 to the wiring board 1001 may be concurrently performed with printing or reflow of solder paste for fixing the electronic component 240 to the wiring board 1001. After the wiring board 1002 and the wiring component 100 are fixed to each other in step Sc, the wiring board 1001 and the electronic component 106 may be fixed to each other; however, the wiring component 100 can interfere with disposing the electronic component 106.

In this example, the electronic component 240 is mounted on the wiring board 1001 on the wiring component 100 side (wiring board 1002 side). When the electronic component 240 is mounted on an opposite side to the wiring component 100 with respect to the wiring board 1001, there is a low possibility that the wiring component 100 interferes with arrangement of the electronic component 240. In other words, the electronic component 240 should be mounted on the wiring board 1001 such that the wiring board 1001 is located between the wiring board 1002 and the electronic component 240. An electronic component may be mounted on each side of the wiring board 1001.

The electronic component 106 and the electronic component 240 may be electrically connected to each other via the wiring component 100. One of the electronic component 106 and the electronic component 240 may output a signal or electric power to supply the signal or electric power via the wiring component 100 to the other one of the electronic component 106 and the electronic component 240.

The dimension (height Hb) of the substrate 101 (coupling part 107) in the Z direction that intersects with the directions Da, Db in which the wiring lines 103 are arranged can be greater than or equal to the dimension (height Ha) of each of the wiring lines 103 of the wiring part 110 (the wiring part 1101 or the wiring part 1102) in the Z direction that intersects with the directions Da, Db in which the wiring lines 103 are arranged. With this configuration, a gap between the substrate 101 (coupling part 107) and the wiring board 1001 or a gap between the substrate 101 (coupling part 107) and the wiring board 1002 can be reduced.

The thus manufactured module 30 includes the wiring board 1002, the wiring board 1001 that overlaps the wiring board 1002, and the wiring component 100. The wiring component 100 is disposed between the wiring board 1002 and the wiring board 1001. One (lower surface terminal 1031) of each pair of terminals (the lower surface terminal 1031 and the upper surface terminal 1032) of the wiring component 100 is connected to a corresponding one of the electrodes 220 of the wiring board 1002. The other one (upper surface terminal 1032) of each pair of terminals (the lower surface terminal 1031 and the upper surface terminal 1032) of the wiring component 100 is connected to a corresponding one of the electrodes 222 of the wiring board 1001. In the module 30, the wiring component 100 is an intermediate member disposed between the wiring board 1001 and the wiring board 1002 and functions as a connecting member that electrically connects the wiring board 1001 to the wiring board 1002, so the wiring component 100 may be referred to as intermediate connecting member.

In the thus configured module 30, the coupling part 107 is provided between the wiring parts 110, entry of foreign matter to a space between the wiring board 1002 and the wiring board 1001 (a space surrounded by the wiring component 100) can be suppressed. Since the coupling part 107 is deformable, stress that can be generated due to thermal expansion of the wiring boards 1001, 1002 can be reduced. Due to such a reason, the reliability of the module 30 can be improved. By using a conductor for at least part of the coupling part 107, the coupling part 107 can function as an electromagnetic shield for an electronic component between the wiring board 1001 and the wiring board 1002.

The module 30 can be mounted on various apparatuses. An apparatus can include a module and a casing that accommodates the module. Since the wiring board 1001 and the wiring board 1002 can be mounted with high density in the casing with a limited space, the performance of the apparatus is improved or a reduction in the size of the apparatus is achieved. The apparatus that applies the present embodiment can be an electronic apparatus, such as a camera, a smartphone, a tablet, and a personal computer. The apparatus that applies the present embodiment can be a business machine, such as a copying machine and a printer. The apparatus that applies the present embodiment can be a medical apparatus, such as a CT, X-rays, and an endoscope. The apparatus that applies the present embodiment can be an industrial apparatus, such as a robot and a semiconductor manufacturing apparatus.

An image pickup apparatus, such as a digital camera and a camera-equipped smartphone, which is an example of an electronic apparatus, includes a circuit board or an image pickup module, in which an electronic component, such as an image sensor, is mounted on a wiring board. With size reduction, high image quality, and high performance of an image pickup apparatus, an electronic component is also reduced in size and increased in performance. For an image pickup module, further high-density mounting of relatively large, high (thick) semiconductor components, such as electronic components, and a large number of electronic components on a wiring board has been proceeding. On the other hand, an image pickup apparatus is proceeding to be increased in size, such as APSC size and full size, in association with high resolution.

Accordingly, a wiring board is also requested for a high-density mounting structure of electronic components. Laminated circuit boards are known as one of high-density mounting structures. In the laminated circuit boards, wiring boards on which semiconductor devices, electronic components, and the like are mounted are stacked in layers and electrically connected.

There are methods, such as connection using solder balls and connection using a wiring component with wiring lines and solder as means for electrically connecting laminated circuit boards.

In the future, a tall wiring component with further high-density, narrow-pitch wiring lines is expected for lamination of wiring boards. A highly accurate, easy-to-assemble wiring component is requested for a wiring board.

However, it is difficult to hold a tall insulating substrate cut into a long rectangular shape in a self-supported state and accurately dispose the insulating substrate. An integrated frame-shaped wiring component is easy to be assembled; however, the wiring component is formed from a substrate larger than the outer shape of an integrated frame, so a substrate inside the frame is wasted, with the result that an environmental load tends to increase.

According to the present embodiment, it is possible to provide a tall wiring component with high-density, narrow-pitch wiring lines, easy to manufacture with less environmental load, and a manufacturing method therefor.

### Embodiment 3V

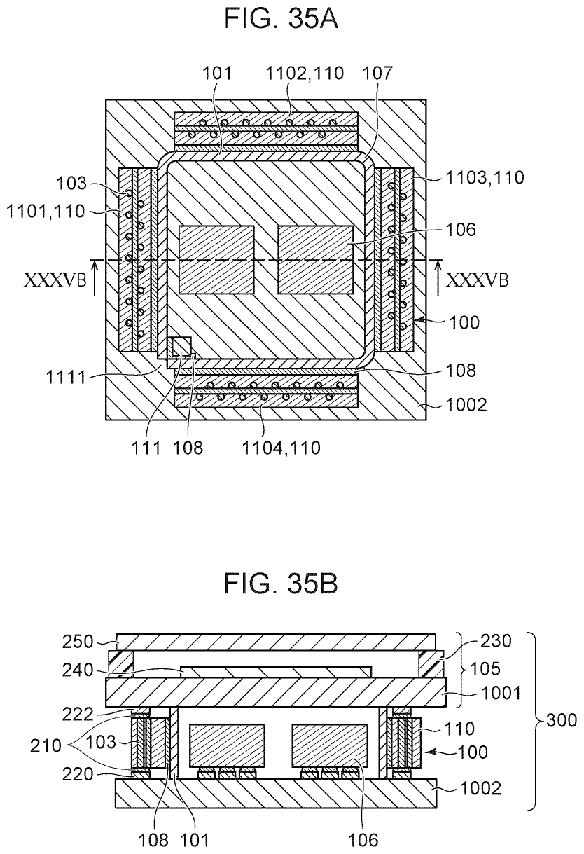

FIGS. 35A and 35B are schematic diagrams of an image pickup module that is an example of the module 30 using the wiring component 100 according to the present embodiment. FIG. 35A is a projection view seen through from above. FIG. 35B is a sectional view taken along the line XXXVB-XXXVB in FIG. 35A.

The module 30 includes a unit 105, a wiring board 1002, and a wiring component 100. In the unit 105, an image sensor (image pickup element) 240, a frame 230, and a lid 250 are mounted on a wiring board 1001. Tall components, that is, electronic components 106 and the like, are mounted on the wiring board 1002.

In the wiring component 100, wiring parts 110 are bonded by binding materials 108 to a substrate 101 having bendable coupling parts 107. The four wiring parts 110 are disposed so as to surround the two electronic components 106. Here, the electronic component 106 is a memory, such as a DRAM memory and a flash memory, and may be a power IC, a digital signal processor (DSP), a controller, or the like.

The electrodes 222 of the wiring board 1001, the electrodes 220 of the wiring board 1002, and the wiring lines 103 of the wiring parts 110 of the wiring component 100 are electrically and mechanically connected via solder 210.

The electrodes 220, 222 are electrodes made of a metal having electrical conductivity, such as copper, and each may be, for example, a signal electrode, a power supply electrode, a ground electrode, or a dummy electrode. Each of the wiring board 1001 and the wiring board 1002 is a rigid board made of an insulating material, such as glass fiber-containing epoxy resin, and may be a flexible board. Each of the wiring board 1001 and the wiring board 1002 can be a printed wiring board. A method of forming wiring lines on the wiring board 1001 and the wiring board 1002 is not limited to printing and may be formed by photolithography. Each of the wiring boards 1001, 1002 may be a ceramic board or a glass board.

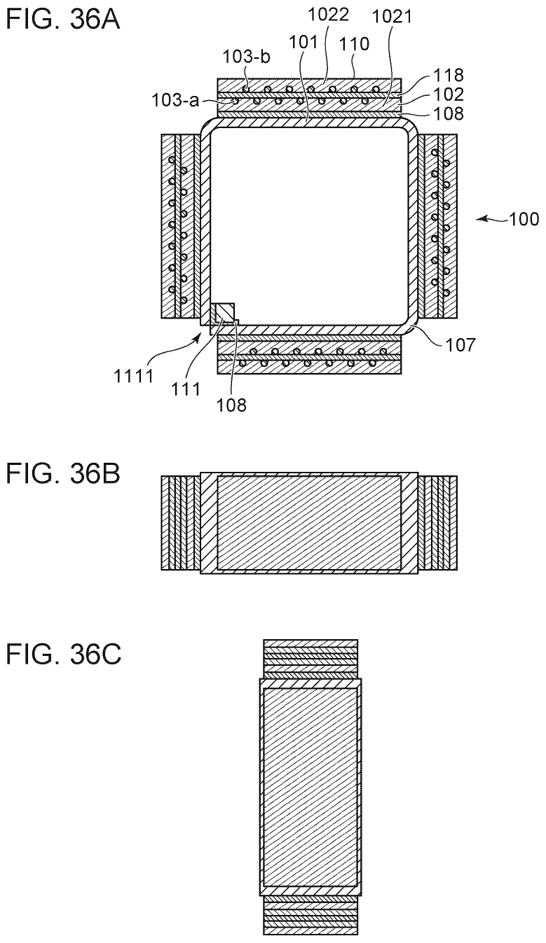

FIGS. 36A to 36C are schematic diagrams of a wiring component according to the present embodiment. FIG. 36A is a top view of an example of the structure of the wiring component. FIG. 36B is a front view of FIG. 36A. FIG. 36C is a side view of FIG. 36A.

In the wiring component 100, wiring parts 110 are bonded by binding materials 108 to a substrate 101 having bendable coupling parts 107. The substrate 101 of the wiring component 100 is fixed to a corner connecting member 111 at a substrate terminal end part 1111 by using a binding material 108, a fitting method, or the like.

The substrate 101 may be a conductive material, such as a metal, or may be an insulating material, such as Teflon (registered trademark) and polyimide. The bendable coupling part 107 may have the same shape and be made of the same material as the substrate 101 as long as the material is bendable. The bendable coupling part 107 is worked into a bendable state by forming grooves, slits, or the like in the substrate 101 in advance.

The height Hb of the substrate 101 is greater than or equal to the height Ha of each wiring line 103 of the wiring part 110. The material of the substrate 101 preferably has such a hardness that the substrate 101 can define the height of solder at the time when the solder melts during a flow process. Ordinarily, the height of solder ranges from about 0.05 mm to about 0.5 mm, so a difference between the height Hb of the substrate 101 and the height Ha of each wiring line 103 is preferably less than or equal to 1 mm.

Although it varies depending on the material, a thinner one is preferable because a larger mounting area is intended to be ensured as much as possible. In consideration of a hardness that the height of solder can be defined as well, the thickness of the substrate 101 is preferably less than or equal to about 1 mm, so the thickness of the substrate 101 is preferably less than or equal to 0.5 mm.

The wiring parts 110 are disposed at locations, other than the bendable coupling parts 107, where the electrodes 220 of the wiring board 1002 and the wiring lines 103 of the wiring component 100 are electrically and mechanically connected via the solder 210.

The wiring part 110 is formed such that an insulating member 1021 having wiring lines 103-a and an insulating member 1026 having wiring lines 103-b are bonded to each other by an insulating binding material 118. The wiring lines 103 are continuous from the upper surface to the lower surface. The insulating member 102 is a rigid board made of an insulating material, such as glass fiber-containing epoxy resin. In consideration of high-density mounting components, ensuring the mounting area, and the like, the thickness of the wiring part is preferably less than or equal to about 5 mm, so the thickness of the insulating substrate is preferably less than or equal to 2.5 mm.

The wiring part 110 may have a strip shape cut in a long rectangular shape. The size is designed as needed according to the board sizes of the wiring board 1001 and the wiring board 1002, the electrodes, and the like. Unlike an integrated frame-shaped wiring component that is formed from a large board and in which a board inside the frame is wasted, a large number of wiring parts 110 can be manufactured from a large board. Major wastes are chips that occur at the time of cutting into a long rectangular shape, and an environmental load can be extremely reduced. Chips can be further reduced by reducing the width of a blade of a dicing apparatus or the like used at the time of cutting, so an environmental load can be reduced.

The wiring lines 103 may be made from crimped metal foils or metal wires buried in grooves (not shown), may be plated with metal in through holes machined by a drill or the like, or may be formed by applying conductive paste with a dispenser or the like and firing the conductive paste. The shape of each wiring line may be round or square. The material of each wiring line 103 may be an inorganic material, such as copper, silver, and aluminum, or may be an organic material, such as conductive rubber.

The wiring lines 103 of the wiring part include portions that connect with ground wiring lines of the wiring boards 1001, 1002. The ground wiring lines pass a larger current than wiring lines, such as signal lines, so wiring lines with lower resistance are desired. In order for the wiring lines 103 of the wiring parts at portions connected to the ground wiring lines of the wiring boards 1001, 1002 to deal with larger current, lower-resistance conductive material with a different material or thick wires may be disposed. The thickness of each wiring line 103 is preferably greater than or equal to 0.01 mm and less than or equal to 2 mm in consideration of use of ground wiring lines, signal lines, or the like. In consideration of high-density wiring, the thickness of each wiring line 103 is more preferably less than or equal to 0.5 mm.

The circumference of the wiring component is less than the circumference of each of the wiring boards 1001, 1002. The width is preferably reduced as much as possible because the area of the wiring board for mountable components increases.

The height of the wiring part 110 is higher than the tallest component of the electronic components 106 and the like. For example, in a case where a component having a height of 1.6 mm is mounted, the height H of the wiring component is preferably greater than or equal to 1.6 mm. The number and pitch P of wiring lines of the wiring component depend on the number and pitch of electrodes (not shown) of the wiring board 1001 and the wiring board 1002. Connection of the wiring component 100 to the wiring boards 1001, 1002 is such that wiring lines on the upper surface side of the wiring component 100 and the electrodes 220 of the wiring board 1001 are connected by solder 210. Similarly, the wiring lines on the lower surface side of the wiring component 100 and the electrodes 222 of the wiring board 1002 are connected by solder 210.

### Embodiment 3VI

FIGS. 37A-1 to 37E-2 are schematic diagrams showing an embodiment of a manufacturing method for the wiring component. FIGS. 37A-1 to 37E-1 are top views of the wiring component. FIGS. 37A-2 to 37E-2 are side views of the wiring component.

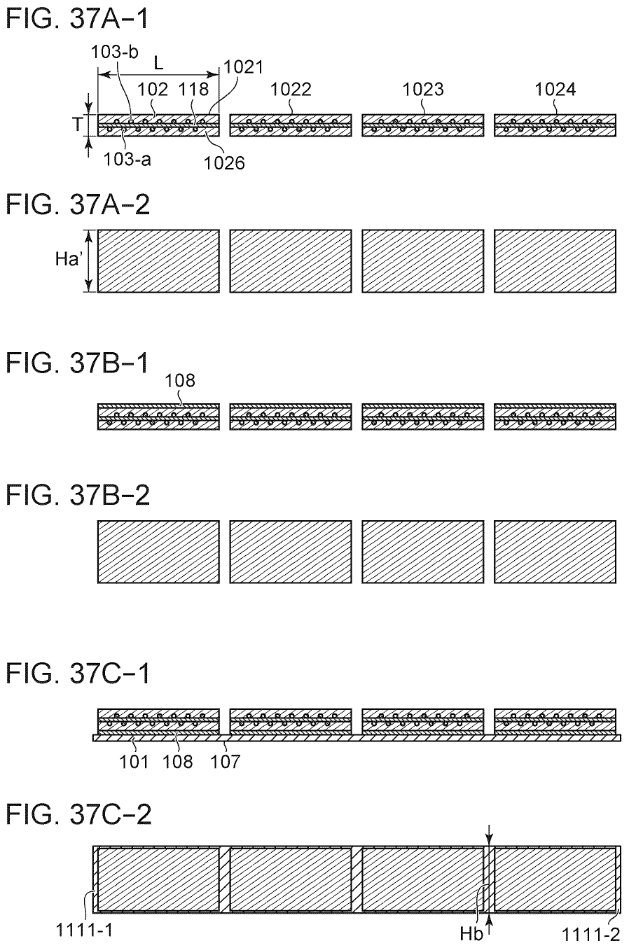

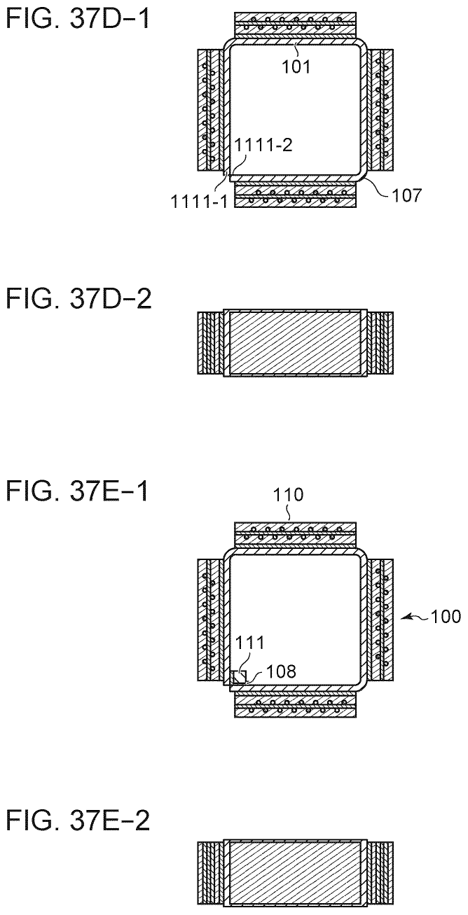

FIGS. 37A-1 and 37A-2 are diagrams of four insulating members 102 (1021, 1022, 1023, 1024). FIG. 37A-1 is a top view. FIG. 37A-2 is a side view. Each of the insulating members 102 is a rigid board made of an insulating material, such as epoxy resin. The insulating member 102 has a structure in which an insulating substrate that supports a plurality of wiring lines 103-a and an insulating substrate that supports a plurality of wiring lines 103-b are bonded to each other by an insulating binding material 118. In this example, the height Ha′ of the insulating member 102 is equal to the height Ha of each wiring line 103 (Ha=Ha′). FIGS. 37B-1 and 37B-2 are diagrams showing a step in which the insulating binding material 108 is applied to the surface of the insulating member 102 by printing or the like or with a dispenser or the like. The insulating binding material 108 should be an insulating binding material, such as epoxy and silicone. The insulating binding material 108 may be a sheet binding material.

FIGS. 37C-1 and 37C-2 are diagrams showing a step in which the wiring parts 110 are aligned by an alignment apparatus (not shown) or the like and bonded to the substrate 101 having the bendable coupling parts 107. Alignment may be performed by using an alignment mark (not shown) formed in advance. at the time of bonding, bonding may be performed while controlling the thickness of a binding material to a uniform thickness by disposing a height regulating material (not shown) in the binding material 108 such that the thickness of the binding material 108 is uniform.

FIGS. 37D-1 and 37D-2 are diagrams showing a step in which the substrate 101 is formed into a frame shape by bending the bendable coupling parts 107. Locations to be bent may be set in advance by using markers (not shown). For the bendable coupling parts 107, in a case where the material of the substrate 101 is relatively hard and is difficult to be bent, the bendable coupling parts 107 may be subjected to working for forming grooves, slits, or the like in advance. The substrate may be worked into a deformable state at selected locations by forming grooves or slits on the entire surface of at least one side of the substrate at constant intervals in a longitudinal direction. In this example, the height Hb of the substrate 101 (coupling parts 107) is greater than the height Ha of each wiring line 103 and is greater than the height Ha′ of each insulating member 102 (Hb>Ha, Hb>Ha′).

FIGS. 37E-1 and 37E-2 are diagrams showing a step in which a substrate distal end part 1111-1 and a substrate terminal end part 1111-2 are fixed by a corner connecting member 111 to which the insulating binding material 108 is applied in advance. The substrate distal end part 1111-1 and the substrate terminal end part 1111-2 may be worked in advance so that the substrate distal end part 1111-1 and the substrate terminal end part 1111-2 can be fixedly fitted to each other. The corner connecting member 111 just needs to fix the substrate distal end part 1111-1 and the substrate terminal end part 1111-2 to each other. The corner connecting member 111 may be made of the same material as the substrate 101 and may be made of a conductive material, such as a metal, or an insulating material, such as epoxy resin, Teflon, and polyimide. Threaded holes may be formed in the corner connecting member 111 in order to be fixedly screwed to the wiring board 1001 or the wiring board 1002. A larger size is preferable because a larger mounting area is intended to be ensured as much as possible. To fix the substrate distal end part 1111-1 and the substrate terminal end part 1111-2, about several millimeters per side is needed, and the size is preferably less than or equal to 2 mm per side.

With the above-described steps, it is possible to provide a tall wiring component with high-density, narrow-pitch wiring lines, easy to manufacture with less environmental load, and a manufacturing method therefor.

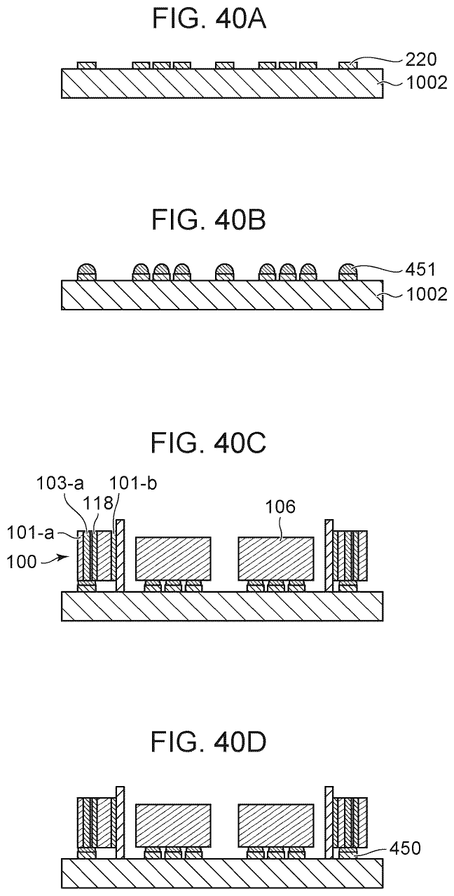

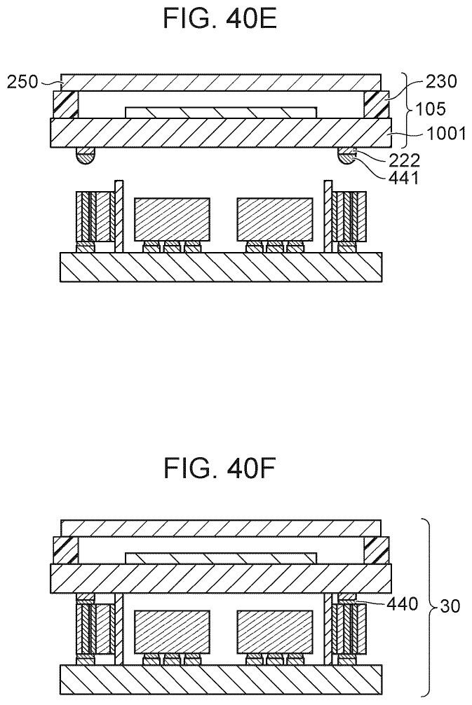

FIGS. 40A to 40F are schematic diagrams showing an embodiment of a manufacturing method for an image pickup module.

FIG. 40A is a diagram showing a wiring board 1002 before solder pastes are supplied. The wiring board 1002 has a plurality of electrodes 220. The electrodes 220 are electrodes made of a metal having electrical conductivity, such as copper, and each may be, for example, a signal electrode, a power supply electrode, a ground electrode, or a dummy electrode. The wiring board 1002 is a rigid board made of an insulating material, such as epoxy resin. A solder resist film (not shown) may be provided on the wiring board 1002. At this time, the solder resist film preferably has openings at locations corresponding to the electrodes 220. The shape of each electrode 220 may be square or round, and the relationship with a solder resist may be a so-called SMD or NSMD.

FIG. 40B is a diagram showing a step in which a solder paste 451 containing solder powder and flux is mounted on each of the electrodes 220. The solder pastes 451 can be supplied, for example, by screen printing or with a dispenser. The solder paste 451 may be supplied so as to completely cover each of the electrodes 220 as shown in FIG. 40B or may be supplied so as to partially cover each of the electrodes 220 as in the case of so-called offset printing.

FIG. 40C is a diagram showing a step in which the electronic components 106, the wiring component 100, and chip components (not shown) are mounted on the wiring board 1002. The electronic components 106, the wiring parts 110 of the wiring component 100, the chip components (not shown), and the like are mounted on predetermined electrodes 220 with a mounter or the like.

FIG. 40D is a diagram showing a step of heating the solder pastes 451 to a temperature higher than or equal to the melting point of solder powder to melt and aggregate the solder powder and then cooling the solder pastes 451 to a temperature lower than the melting point of the solder powder to solidify. As the solder solidifies, the electronic components 106, the wiring component 100, and the chip components (not shown) are electrically and mechanically connected to the wiring board 1002. Heating and cooling steps of the solder pastes can be performed in, for example, a reflow furnace.

The wiring component 100 is formed such that the individual wiring parts 110 are formed in an integrated frame shape by the substrate 101, so the wiring parts 110 are less likely to shift or fall down due to handling after the wiring parts 110 are mounted, vibrations during reflow, or the like. Particularly, even when the width of each wiring part is less than or equal to 1 mm and is thin and the height is greater than or equal to 2 mm, the wiring part does not fall down.

If the wiring parts 110 not using the substrate 101 each are disposed, the wiring parts 110 can shift or fall down due to handling after the wiring parts 110 are mounted, vibrations during reflow, or the like. Particularly, when the width of each wiring part is less than or equal to 1 mm and is thin and the height is greater than or equal to 2 mm, the risk of falling down increases.

FIG. 40E is a diagram showing a step in which the solder paste 441 containing solder powder and flux is mounted on each of the electrodes 222 of the wiring board 1001 on which the unit 105 is mounted and the wiring board 1001 is mounted on the wiring component 100 on the wiring board 1002. The solder pastes 441 can be supplied, for example, by screen printing or with a dispenser. The solder paste 441 may be supplied so as to completely cover each of the electrodes 222 as shown in FIG. 40E or may be supplied so as to partially cover each of the electrodes 222 as in the case of so-called offset printing. The wiring board 1001 on which the unit 105 is mounted is mounted with a mounter or the like such that each of the wiring lines 103 of the wiring component is located on a corresponding one of the electrodes 222 of the wiring board 1001.

The electrodes 222 are electrodes made of a metal having electrical conductivity, such as copper, and each may be, for example, a signal electrode, a power supply electrode, a ground electrode, or a dummy electrode. The wiring board 1001 is a rigid board made of an insulating material, such as ceramics and epoxy resin. A solder resist film (not shown) may be provided on the wiring board 1001. At this time, the solder resist film preferably has openings at locations corresponding to the electrodes 222. The shape of each electrode 222 may be square or round, and the relationship with a solder resist may be a so-called SMD or NSMD.

FIG. 40F is a diagram showing a step of heating the solder pastes 441 to a temperature higher than or equal to the melting point of solder powder to melt and aggregate the solder powder and then cooling the solder pastes 441 to a temperature lower than the melting point of the solder powder to solidify. As the solder solidifies, the wiring board 1001, the wiring component 100, and the chip components (not shown) are electrically and mechanically connected to the wiring board 1001. Heating and cooling steps of the solder pastes can be performed in, for example, a reflow furnace.

The module 30 can be manufactured in the above-described steps. Here, an example in which the solder pastes 441, 442 are applied to the wiring boards 1001, 1002 has been described. Alternatively, solder pastes may be applied to the wiring component 100.

### Example 3A

The wiring component shown in FIGS. 36A to 36C was manufactured by using the manufacturing method described with reference to FIGS. 37A-1 to 37E-2. In FIGS. 37A-1 and 37A-2, the wiring part 110 had a strip shape such that the length L was 41.0 mm, the thickness of the binding material 118 was 0.085 mm, the thickness T was 1.085 mm, and the height Ha was 1.8 mm. The wiring lines 103 were arranged with high density such that the diameter of a copper wiring line was 0.2 mm, the number of copper wiring lines was 140 and the closest pitch P was 0.4 mm. The insulating members 102 were made of FR-4, and the size of the outer shape was about 41.0 mm by 1.8 mm, and the thickness was 0.5 [mm].

Subsequently, as shown in FIGS. 37B-1 and 37B-2, an insulating epoxy binding material 108 was applied to the one-side surface of the insulating member 102 with a thickness of about 0.2 mm by squeegee printing.

Subsequently, as shown in FIGS. 37C-1 and 37C-2, four wiring parts were bonded to the substrate 101 such that the four wiring parts including the wiring part 1101 formed one unit by aligning the centers in an up and down direction and markers (not shown) in a right and left direction with respect to the copper plate substrate 101 with a thickness of 0.1 mm.

The length of the substrate 101 was 172 mm, and the height Hb was 2.0 mm.

Subsequently, as shown in FIGS. 37D-1 and 37D-2, the substrate 101 was formed such that the substrate distal end part 1111-1 and the substrate terminal end part 1111-2 contacted with each other in a top view by bending at right angles the center of each bendable coupling part 107. A marking line was formed in advance at the center of each bendable coupling part 107.

Subsequently, as shown in FIGS. 37E-1 and 37E-2, the substrate distal end part 1111-1 and the substrate terminal end part 1111-2 were fixed to each other by the corner connecting member 111 and the insulating binding material 108. The corner connecting member 111 was 1 mm per side and had a height of 1.8 mm. The material was an insulating material, such as glass fiber epoxy resin that was the same as the wiring board material.

Thus, the strip-shaped four wiring parts 110 were formed such that the length L was 41.0 mm, the thickness of the binding material 118 was 0.085 mm, the thickness T was 1.085 mm, and the height was 2.0 mm. Then, the wiring component 100 with high-density wiring in which the number of copper wiring lines was 140 and the closest pitch P was 0.4 [mm] was manufactured. The ratio of the height of the manufactured wiring component to the closest pitch of the wiring lines was 5:1 (2:0.4). A wiring line density was 3.15/mm2 (140/(41 mm*1.085 mm)).

### Example 3B

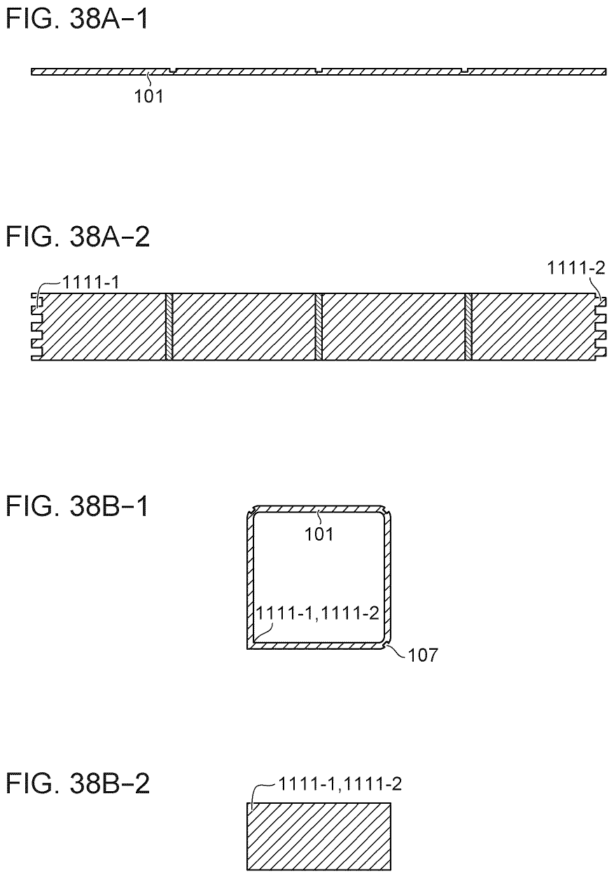

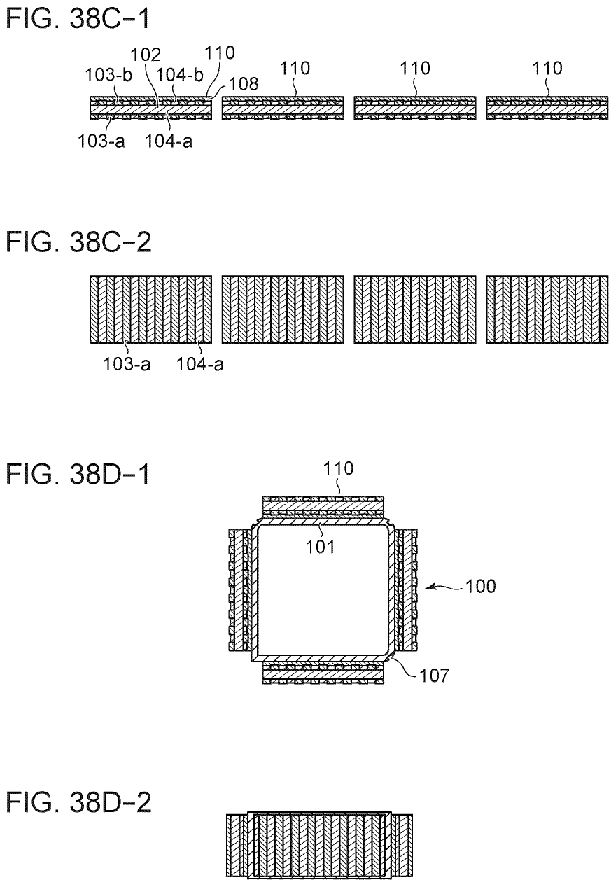

FIGS. 38A-1 to 38D-2 are schematic diagrams of a wiring component according to Example 3B and a manufacturing method therefor. FIGS. 38A-1 to 38D-1 are top views of the wiring component. FIGS. 38A-2 to 38D-2 are side views of the wiring component.

In FIGS. 38A-1 and 38A-2, the Teflon-coated copper plate substrate 101 with a thickness of 0.1 mm, having the bendable coupling parts 107 provided with slits having a depth of 0.05 mm and a width of 0.1 mm was used. A fitting part with a length of 0.5 mm, a width of 0.4 mm, and a pitch of 0.8 mm was formed at each of the substrate distal end part 1111-1 and the substrate terminal end part 1111-2.

The length of the substrate 101 was 172 mm, and the height Hb was 2.0 mm.

Subsequently, as shown in FIGS. 38B-1 and 38B-2, the substrate 101 was fixed such that the substrate distal end part 1111-1 and the substrate terminal end part 1111-2 were fitted to each other in a top view by bending at right angles each bendable coupling part 107.

Subsequently, as shown in FIGS. 38C-1 and 38C-2, an insulating epoxy binding material 108 was applied to the one-side surface of the wiring part 110 with a thickness of about 0.2 mm by squeegee printing.

For the wiring part 110, the insulating member 102 was made of FR-4, and the copper wiring lines 103 were formed on each side of the insulating member 102 such that the thickness of copper foil was 0.015 mm, the width of each opening of a solder resist 104 was 0.2 mm, and the pitch of the openings was 0.4 mm. The thickness of the solder resist 104 was 0.02 mm. Each wiring part 110 was formed in a strip shape with a length L of 41.0 mm, a width W of 0.8 mm, and a height Ha of 1.8 mm, and was subjected to high-density wiring in which the number of copper wiring lines was 140 and the closest pitch P was 0.4 mm.

Subsequently, as shown in FIGS. 38D-1 and 38D-2, four wiring parts were bonded to the substrate 101 such that the four wiring parts including the wiring part 1101 formed one unit by aligning the centers in an up and down direction and markers (not shown) in a right and left direction with respect to the substrate 101. Thus, the strip-shaped four wiring parts 110 were formed such that the length L was 41.0 mm, the thickness of the binding material 118 was 0.085 mm, the thickness T was 0.8 mm, and the height was 2.0 mm. Then, the wiring component 100 with high-density wiring in which the number of copper wiring lines was 140 and the closest pitch P was 0.4 mm was manufactured. The ratio of the height of the manufactured wiring component to the closest pitch of the wiring lines was 5:1 (2:0.4). A wiring line density was 3.15/mm2 (140/(41 mm*1.085 mm)).

### Example 3C

Example 3C shows top views of the other Examples in FIGS. 39A, 39B, 39C-1, and 39C-2.

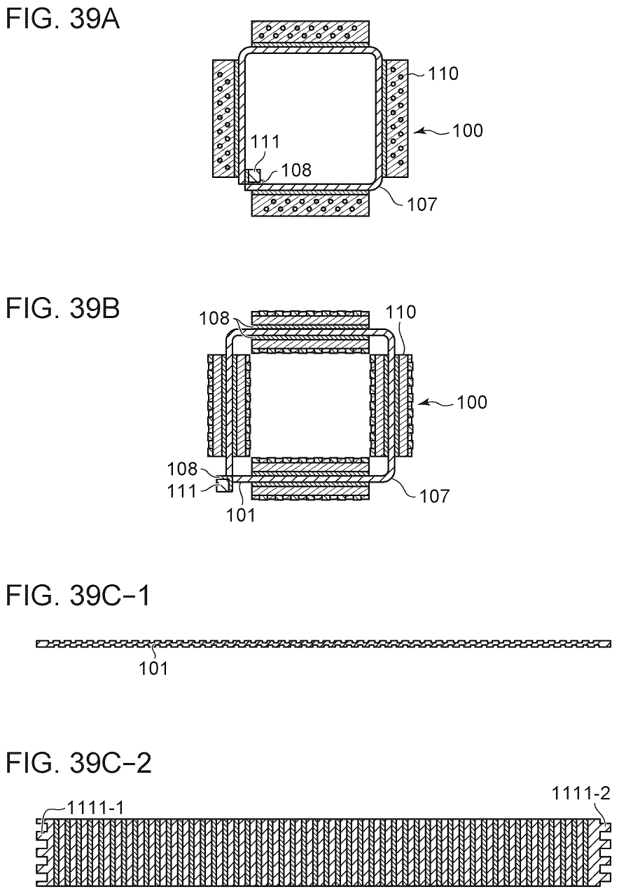

In FIG. 39A, as a wiring part, the insulating member 102 with a thickness of 2 mm was drilled to form through holes with Φ0.5 mm with the closest pitch P of 0.6 mm and the wiring lines 103 were formed by Au—Ni electroless plating in the through holes. Other than the above, the wiring component 100 was manufactured as in the case of Example 3A.

In FIG. 39B, as the wiring part 110, the insulating member 102 was made of FR-4, and the copper wiring lines 103 were formed on one side of the insulating member 102 such that the thickness of copper foil was 0.015 mm, the width of each opening of a solder resist 104 was 0.2 mm, and the pitch of the openings was 0.4 mm. Each wiring part 110 was formed in a strip shape with a length L of 41.0 mm, a thickness T of 0.4 mm, and a height Ha of 1.8 mm, and was subjected to high-density wiring in which the number of copper wiring lines was 140 and the closest pitch P was 0.4 mm. The wiring part 110 was bonded to each side of the substrate 101, and the substrate distal end part 1111-1 and the substrate terminal end part 1111-2 were fixed by the corner connecting member 111 on the outer side of the frame, thus the wiring component 100 was manufactured.

FIGS. 39C-1 and 39C-2 are diagrams showing the substrate 101 in which a large number of bendable coupling parts 107 are formed. FIG. 39C-1 is a top view of the substrate. FIG. 39C-2 is a side view of the substrate. The substrate 101 was manufactured such that grooves with a depth of 0.2 mm and a width of 0.2 mm were formed with a pitch of 0.4 mm on each side of a copper plate with a length of 172 mm, a height of 2.0 mm, and a thickness of 0.45 mm. Portions of the substrate 101 where no wiring part was bonded function as the bendable coupling parts 107, and the substrate 101 could be bent at a selected location and formed into a frame shape. Except that this substrate 101 was used, the wiring component 100 was manufactured as in the case of Example 3A (not shown).

Thus, the strip-shaped wiring component 100 was formed such that the length L was 41.0 mm, the thickness of the binding material 118 was 0.085 mm, the thickness T was 1.655 mm, and the height was 2.0 mm. The number of copper wiring lines was 280, and the closest pitch P was 0.4 mm. The ratio of the height of the manufactured wiring component to the closest pitch of the wiring lines was 5:1 (2:0.4). A wiring line density was 4.12/mm2 (280/(41 mm*1.655 mm)).

### Example 3D

The module 30 shown in FIGS. 35A and 35B was manufactured by using the wiring component manufactured in Example 3A with the manufacturing method described with reference to FIGS. 40A to 40F.

In FIG. 40A, electrodes 220 to which the electronic components 106 and the wiring component 100 were connected were formed on the wiring board 1002. A solder resist (not shown) was formed on the upper surface of the wiring board 1002 so as to partially cover each of the electrodes 220. The solder resist had connection openings, to which the electronic components 106 and the wiring component 100 to be mounted were connected, each located on a corresponding one of the electrodes 220, and the electrode 220 was exposed to the connection opening.

In the wiring board 1002, FR-4 was used for the insulating member 102, and the size of the outer shape was about 50.0 mm by 50.0 mm. The material of the electrodes 220 was copper. The diameter of each electrode 220 connected to the wiring component 100 was 0.2 mm. The electrodes 220 were arranged in a staggered manner with the closest pitch of 0.4 mm. The thickness of the solder resist was about 0.02 mm. Solder balls were mounted in advance on the back side of the electronic components 106, and the electrodes 220 to be connected to the electronic components 106 were disposed at locations corresponding to the solder balls. Electronic components, such as capacitors and resistors (not shown), were mounted in advance on the back side of the wiring board 1002. The electronic component 106 had an outer shape size of about 16.0 mm by 16.0 mm and a height of 1.6 mm.

Subsequently, as shown in FIG. 40B, solder pastes 451 were formed by screen printing so as to cover each of the electrodes 220 of the wiring board 1002. A printing plate with a thickness of 0.02 mm was used for screen printing.

The solder paste 451 contained Sn—Ag—Cu solder powder and flux. An alloy composition of the solder powder was a composition of tin-remainder, silver-3, and copper-3 with a melting point of 220° C., and the mean particle diameter of the powder was 40 μm

Subsequently, as shown in FIG. 40C, the electronic components 106, the wiring component 100, and the chip components (not shown) were mounted with a mounter on the wiring board 1002 to which the solder pastes 451 were supplied. The wiring lines 103 on the lower surface side of the wiring parts 110 of the wiring component 100 were mounted so as to be aligned with locations corresponding to the electrodes 220 of the wiring board 1002. The electronic components 106 were mounted such that the solder balls (not shown) of the electronic components 106 were aligned with locations corresponding to the electrodes 220 of the wiring board 1002. After the wiring component 100 was mounted on the wiring board 1002 with a thickness T of 1.085 mm, the wiring component 100 was self-supported without a holding mechanism or the like. The five wiring components 100 were disposed so as to surround the two electronic components 106.

Subsequently, as shown in FIG. 40D, the assembly was put into a reflow furnace, the solder pastes 451 were heated to a temperature higher than or equal to the melting point of the solder powder to melt and aggregate the solder powder into solder 210.

The electronic components 106, the wiring component 100, and the chip components (not shown) were electrically and mechanically joined to the wiring board 1002 by the solder 210.

Subsequently, as shown in FIG. 40E, the electrodes 222 of the wiring board 1001, on which the solder pastes 451 were formed by screen printing, were mounted so as to be aligned with the locations corresponding to the wiring lines 103 on the upper surface of the wiring component 100 on the wiring board 1002. The unit 105 was formed such that the image sensor (image pickup element) 240, the frame 230, and the glass lid 250 were mounted on the wiring board 1001. A solder resist (not shown) was formed on the back surface of the wiring board 1001 so as to partially cover each of the electrodes 222. The solder resist has connection openings, to which the wiring component 100 was connected, each located on a corresponding one of the electrodes 222, and the electrode 222 was exposed to the connection opening.

In the wiring board 1001, a low thermal expansion coefficient wiring board was used for the insulating member 102, and the size of the outer shape was about 52.0 mm by 52.0 mm. The material of the electrodes 222 was copper. The diameter of each of the electrodes 222 connected to the wiring lines 103 of the wiring parts 110 of the wiring component 100 was 0.2 mm. The electrodes 222 were arranged in a staggered manner with the closest pitch of 0.4 mm.

Subsequently, as shown in FIG. 40F, the assembly was put into a reflow furnace, the solder pastes 451 were heated to a temperature higher than or equal to the melting point of the solder powder to melt and aggregate the solder powder into solder 210.

The wiring board 1001 was electrically and mechanically joined to the wiring component 100 by the solder 210. Thus, the electrodes 222 of the wiring board 1001, the electrodes 220 of the wiring board 1002, and the wiring lines 103 of the wiring parts 110 of the wiring component 100 were electrically and mechanically connected via the solder 210.

With the above-described steps, the module 30 using the wiring component according to this Example can be manufactured. The image pickup module could sufficiently guarantee the optical performance of a built-in CMOS image sensor without peeling at the bonding surface of the wiring component or solder joint defects.

Similarly, the wiring components manufactured in Examples 3B and 3C were used, and the image pickup module was formed by laminating the wiring board 1001 on which the image pickup element was mounted and the wiring board 1002 on which electronic components, a power supply, and the like were mounted. The image pickup module could sufficiently guarantee the optical performance of a built-in CMOS image sensor without peeling at the bonding surface of the wiring part or solder joint defects.

### Comparative Example

In Comparative Example, the wiring parts 110 of Examples 3A to 3C are self contained and used without being bonded to a substrate, and Comparative Example is the same as Example 3D in the other points and steps. A full-size image sensor was used for the unit 105, and an image pickup module was formed by laminating the wiring board 1001 and the wiring board 1002 on which electronic components, a power supply, and the like were mounted. After the wiring components were mounted, the wiring components fell down before reflow process or during reflow.

With the image pickup module, short circuit, open circuit failure, or a solder joint defect, such as solder balls, often occurred, so the optical performance of the built-in CMOS image sensor could not be sufficiently guaranteed. Even with an image pickup module with no solder defect, a solder joint defect, such as open circuit failure, occurred in a drop test, so the optical performance of the built-in CMOS image sensor could not be sufficiently guaranteed.

### Embodiment 4I

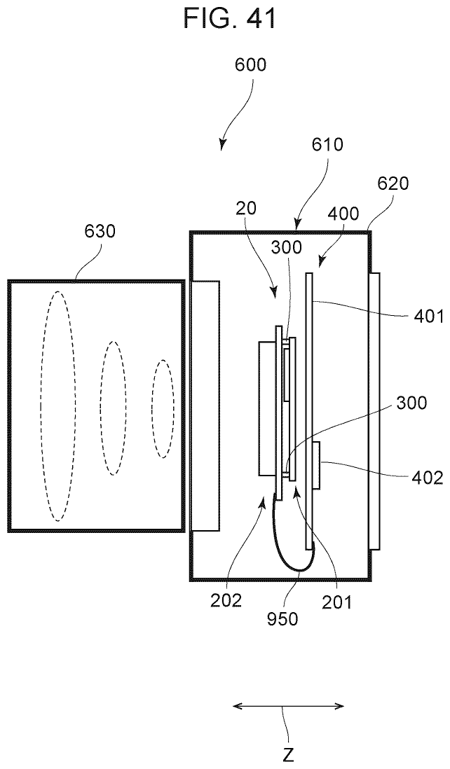

FIG. 41 is a diagram of an electronic apparatus 600 that is an image pickup apparatus serving as an example of an electronic apparatus according to Embodiment 4I. The electronic apparatus 600 is a lens interchangeable digital camera and includes a camera body 610. A lens unit 630 including lenses is detachably mounted to the camera body 610. The lens unit 630 is an interchangeable lens, that is, a lens barrel.

The camera body 610 includes a casing 620, and an image pickup module 20 and a processing module 400 disposed inside the casing 620. The image pickup module 20 and the processing module 400 are electrically connected to each other by a flexible wiring component 950 (wiring board), such as a flexible printed wiring board (FPC) so as to be communicable with each other. Image data generated by the image pickup module 20 is transmitted to the processing module 400 via the wiring component 950.

The image pickup module 20 is an example of an electronic module and has a three-dimensional mounting structure. The image pickup module 20 includes circuit units 201, 202 and a plurality of intermediate connecting units 300 that are an example of at least one intermediate connecting unit. The circuit unit 201 is an example of a first circuit unit, and the circuit unit 202 is an example of a second circuit unit.

The processing module 400 includes a printed wiring board 401 and an image processing apparatus 402 that is a semiconductor element mounted on the printed wiring board 401. The image processing apparatus 402 is, for example, a digital signal processor. The image processing apparatus 402 is configured to apply image processing to image data acquired from the image pickup module 20.

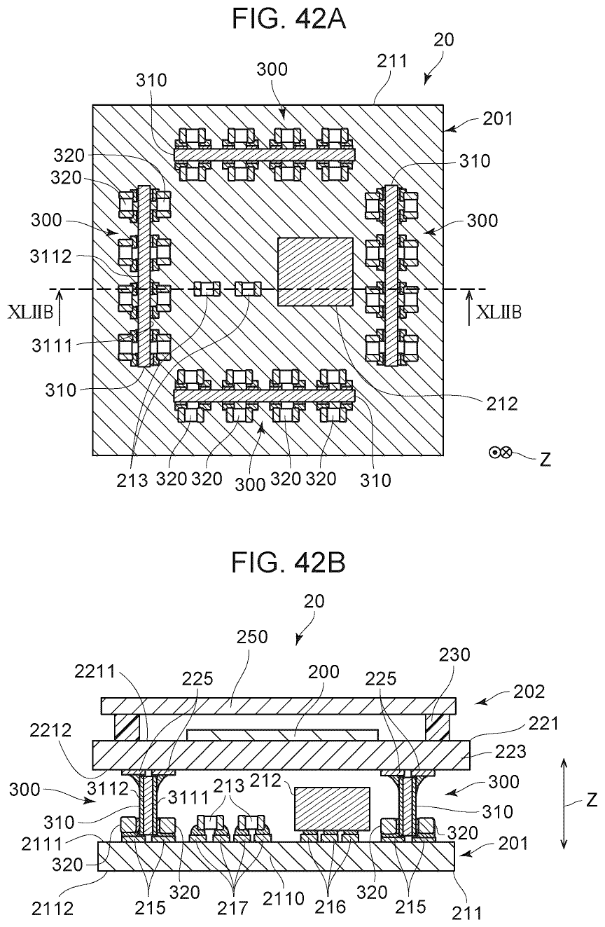

FIG. 42A is a plan view of the image pickup module 20. FIG. 42B is a sectional view of the image pickup module 20. In FIG. 42A, for the sake of illustration, the circuit unit 201 is not shown. FIG. 42B is a sectional view of the image pickup module 20, taken along the line XLIIB-XLIIB in FIG. 42A.

The circuit unit 201 is a printed wiring board, a printed circuit board, or a semiconductor package and is, for example, a printed circuit board in Embodiment 4I. The circuit unit 202 is a printed wiring board, a printed circuit board, or a semiconductor package and is, for example, a semiconductor package in Embodiment 4I.

The circuit unit 201 and the circuit unit 202 are disposed so as to face each other with a space in the Z direction that is a lamination direction. The Z direction is an example of a first direction. The plurality of intermediate connecting units 300, serving as an example of at least one intermediate connecting unit is disposed between the circuit unit 201 and the circuit unit 202.

Each intermediate connecting unit 300 has an intermediate connecting member 310. The intermediate connecting member 310 is disposed between the circuit unit 201 and the circuit unit 202 and is used to electrically and mechanically connect the circuit unit 201 to the circuit unit 202.

The circuit unit 202 includes a wiring board 221 having two principal surfaces 2211, 2212 and an electrooptical component 200 disposed on the principal surface 2211 of the wiring board 221. The principal surface 2212 is a principal surface on the back side of the principal surface 2211. The wiring board 221 is an example of a second wiring board and is a package board. The wiring board 221 is a rigid printed wiring board. The electrooptical component 200 is a semiconductor element, for example, a semiconductor chip. The circuit unit 202 includes a frame 230 and a lid 250. The frame 230 is disposed on the principal surface 2211 of the wiring board 221 so as to surround the electrooptical component 200. The lid 250 is disposed on the frame 230 so as to be opposed to the electrooptical component 200 with a space. For example, a substrate made of glass is used as the lid 250.

The wiring board 221 has a plate-shaped insulating substrate 223. The material of the insulating substrate 223 is preferably a resin having a low thermal expansion coefficient. The principal surfaces 2211, 2212 of the wiring board 221 are the principal surfaces of the insulating substrate 223.

The electrooptical component 200 is, for example, a complementary metal oxide semiconductor (CMOS) image sensor or a charge coupled device (CCD) image sensor. The electrooptical component 200 has a function to convert incoming light via the lens unit 630 to an electrical signal and generate image data in accordance with the electrical signal. The electrooptical component 200 preferably has a size compatible with an increase in size, such as APSC size and full size, in association with high resolution of an image.

The circuit unit 201 includes a wiring board 211 having two principal surfaces 2111, 2112, a memory element 212 disposed on the principal surface 2111 of the wiring board 211, and electronic components 213 disposed on the principal surface 2111 of the wiring board 211. The memory element 212 is an example of at least one semiconductor element. The principal surface 2112 is a principal surface on the back side of the principal surface 2111. The wiring board 211 is an example of a first wiring board and is a rigid printed wiring board. The memory element 212 is, for example, a semiconductor chip and is capable of storing image data in Embodiment 4I. Each of the electronic components 213 is a chip component smaller in size than the memory element 212 and is, for example, a passive element, such as a resistor, a capacitor, and an inductor, or an active element, such as a semiconductor component. In other words, the memory element 212 is taller in height in the Z direction than the electronic components 213. In this way, the memory element 212 and the electronic components 213 are mounted on the principal surface 2111 of the wiring board 211 as at least one mounting component.

The wiring board 211 has a plate-shaped insulating substrate 2110. The material of the insulating substrate 2110 is preferably a resin, such as epoxy resin containing glass fiber. The principal surfaces 2111, 2112 of the wiring board 211 are the principal surfaces of the insulating substrate 2110.

In Embodiment 4I, the principal surface 2111 of the wiring board 211 is disposed so as to be opposed to the principal surface 2212 of the wiring board 221 in the Z direction. Thus, the memory element 212 and the electronic components 213 are disposed between the wiring board 211 and the wiring board 221 in the Z direction. The plurality of intermediate connecting members 310 is disposed between the wiring board 211 and the wiring board 221 such that the memory element 212 and the electronic components 213 do not interfere with the wiring board 221 and a space is held between the wiring board 211 and the wiring board 221. In other words, the plurality of intermediate connecting members 310 also serves as a spacer.

The plurality of intermediate connecting units 300 is disposed so as to surround the memory element 212 and the electronic components 213. In Embodiment 4I, the number of the intermediate connecting units 300 is four.

The wiring board 221 has a plurality of pads 225 disposed at locations corresponding to the intermediate connecting members 310. The plurality of pads 225 is provided on the principal surface 2212. Each of the pads 225 is made of a member having electrical conductivity, for example, a metal, such as copper. Each of the pads 225 is, for example, a signal pad, a power supply pad, a ground pad, or a dummy pad. Each of the intermediate connecting members 310 is joined to the corresponding pads 225 of the plurality of pads 225 by conductive joint members, such as solder.

A solder resist film (not shown) may be provided on the principal surface 2212. At this time, the solder resist film preferably has openings at locations corresponding to the pads 225. The shape of each of the pads 225 is not limited and may be, for example, a circular shape or a polygonal shape in a plan view. The relationship between the solder resist film and the pads may be any one of solder mask defined (SMD) and non solder mask defined (NSMD).

The wiring board 211 has a plurality of pads 215 disposed at locations corresponding to the intermediate connecting members 310, a plurality of pads 216 disposed at locations corresponding to the memory element 212, and a plurality of pads disposed at locations corresponding to the electronic components 213. These pads 215, 216, 217 are provided on the principal surface 2111. Each of the pads 215, 216, 217 is made of a member having electrical conductivity, for example, a metal, such as copper. Each of the pads 215, 216, 217 is, for example, a signal pad, a power supply pad, a ground pad, or a dummy pad. Each of the intermediate connecting members 310 is joined to the corresponding pads 215 of the plurality of pads 215 by conductive joint members, such as solder. The memory element 212 is joined to the plurality of pads 216 by conductive joint members, such as solder. Each of the electronic components 213 is joined to the corresponding pads 217 of the plurality of pads 217 by conductive joint members, such as solder.

A solder resist film (not shown) may be provided on the principal surface 2111. At this time, the solder resist film preferably has openings at locations corresponding to the pads 215, 216, 217. The shape of each of the pads 215, 216, 217 is not limited and may be, for example, a circular shape or a polygonal shape in a plan view. The relationship between the solder resist film and the pads may be any one of SMD and NSMD.

Each of the intermediate connecting units 300 includes the above-described intermediate connecting member 310 and a plurality of, for example, eight electronic components 320 as at least one electronic component. Each of the electronic components 320 is mounted on the intermediate connecting member 310. Each of the electronic components 320 is a chip component smaller in size than the memory element 212 and is, for example, a passive element, such as a resistor, a capacitor, and an inductor, or an active element, such as a semiconductor component. In other words, each of the electronic components 320 is lower in height in the Z direction than the memory element 212. The size of the intermediate connecting member 310 and the size of each of the electronic components 320 mounted on the intermediate connecting member 310 are designed as needed according to the size of each of the wiring boards 211, 221 and the sizes and arrangement locations of the pads and the like of each of the wiring boards 211, 221.

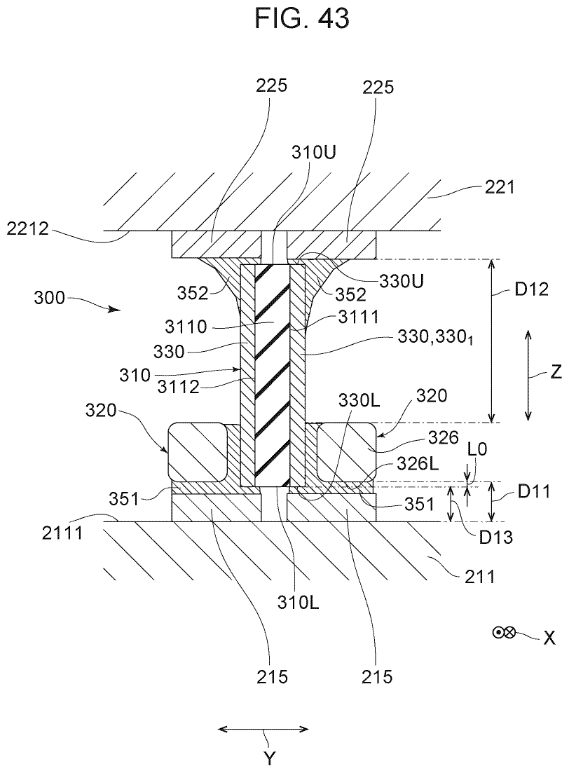

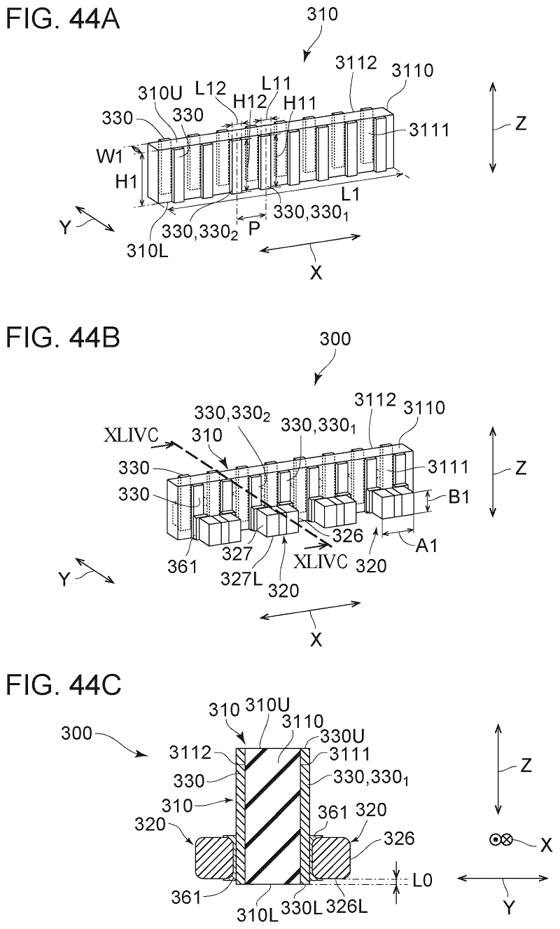

Hereinafter, one intermediate connecting unit 300 will be described focusing on the intermediate connecting unit 300. FIG. 43 is an enlarged sectional view of a relevant part of the image pickup module 20 shown in FIG. 42B. FIG. 44A is a perspective view of the intermediate connecting member 310 according to Embodiment 4I. FIG. 44B is a perspective view of the intermediate connecting unit 300 according to Embodiment 4I. FIG. 44C is a sectional view of the intermediate connecting unit 300, taken along the line XLIVC-XLIVC in FIG. 44B.

The intermediate connecting member 310 is a rectangular parallelepiped rigid wiring board. Here, the longitudinal direction of the intermediate connecting member 310 is defined as X direction, and the width direction, that is, the thickness direction, of the intermediate connecting member 310 is defined as Y direction. The height direction of the intermediate connecting member 310, that is, the shorter side direction of the intermediate connecting member 310, is a Z direction. The Z direction is a first direction, the X direction is a second direction, and the Y direction is a third direction. The X direction, the Y direction, and the Z direction intersect with one another. In the present embodiment, the X direction, the Y direction, and the Z direction are orthogonal to one another. The intermediate connecting member 310 electrically and mechanically connects the two circuit units 201, 202, that is, the two wiring boards 211, 212, while holding a space in the Z direction between the mutually opposed two principal surfaces 2111, 2212, so the intermediate connecting member 310 preferably has a rectangular parallelepiped shape long in the X direction.

The intermediate connecting member 310 has an end face 310L and an end face 310U in the Z direction. The end face 310L of the intermediate connecting member 310 is an example of a first end face, and is a lower end face in some steps in a manufacturing process for the image pickup module 20. The end face 310U of the intermediate connecting member 310 is an example of a second end face, and is an upper end face in some steps in the manufacturing process for the image pickup module 20. The end face 310L is opposed to the principal surface 2111 of the wiring board 211 in the Z direction. The end face 310U is opposed to the principal surface 2212 of the wiring board 221 in the Z direction.

The intermediate connecting member 310 includes a plate-shaped insulating substrate 3110 and a plurality of, for example, 16 wiring lines 330 disposed on the insulating substrate 3110 and extending in the Z direction.

The material of the insulating substrate 3110 is preferably a resin, such as glass fiber-containing epoxy resin. In consideration of high-density mounting components, ensuring the mounting area, and the like, in the image pickup module 20, the thickness in the Y direction of the intermediate connecting member 310 is preferably less than or equal to 5 mm, so the thickness in the Y direction of the insulating substrate 3110 is preferably less than or equal to 2.5 mm.

Each of the wiring lines 330 extends from one end of the insulating substrate 3110 to the other end of the insulating substrate 3110 in the Z direction.

Of two end faces 330L, 330U of each of the wiring lines 330 in the Z direction, the end face 330L is included in the end face 310L of the intermediate connecting member 310. The end face 330L is joined to a corresponding one of the plurality of pads 215 by a joint member 351. Of two end faces 330L, 330U of each of the wiring lines 330 in the Z direction, the end face 330U is included in the end face 310U of the intermediate connecting member 310. The end face 330U is joined to a corresponding one of the plurality of pads 225 by a joint member 352.

Each of the joint members 351, 352 is configured to include a member having electrical conductivity, for example, solder. The material of the joint member 352 is the same as the material of the joint member 351. Each of the joint members 351, 352 suitably includes solder; however, the configuration is not limited thereto. Each of the joint members 351, 352 may be a cured organic conductive adhesive.

The insulating substrate 3110 has two principal surfaces 3111, 3112. The principal surface 3111 is an example of a first principal surface of the intermediate connecting member 310, and the principal surface 3112 is an example of a second principal surface of the intermediate connecting member 310. The principal surface 3112 is a principal surface on the back side of the principal surface 3111. The principal surfaces 3111, 3112 are surfaces parallel to each other. Each of the principal surfaces 3111, 3112 is a surface that intersects with the principal surfaces 2111, 2212 and is preferably a surface orthogonal to the principal surfaces 2111, 2212. Of the plurality of wiring lines 330, at least one wiring line, that is, the eight wiring lines 330 in the present embodiment, are disposed on the principal surface 3111 of the insulating substrate 3110. Of the plurality of wiring lines 330, at least one wiring line different from the at least one wiring line, that is, other eight wiring lines 330 in the present embodiment, are disposed on the principal surface 3112 of the insulating substrate 3110. The eight wiring lines 330 disposed on the principal surface 3111 are disposed with a space from each other in the X direction. The eight wiring lines 330 disposed on the principal surface 3112 are disposed with a space from each other in the X direction.

Each of the wiring lines 330 is configured to include a member having electrical conductivity, for example, an inorganic material, such as copper, silver, and aluminum, or an organic material, such as conductive rubber. Each of the wiring lines 330 may be formed by crimping a metal foil or may be formed by applying a conductive paste with a dispenser or the like and firing the conductive paste.

Each of the electronic components 320 has two electrodes 326, 327 spaced apart from each other. The electrode 326 is an example of a first electrode, and the electrode 327 disposed on an opposite side to the electrode 326 is an example of a second electrode. Each of the electronic components 320 is preferably a chip component, such as a resistor, a capacitor, and an inductor. In a state of being mounted on the intermediate connecting member 310, the length of each electronic component 320 in the X direction is defined as A1, and the length in the Z direction is defined as B1. The size of each electronic component 320, that is, A1 by B1, is preferably any one of 3.2 mm by 1.6 mm, 1.6 mm by 0.8 mm, 1.0 mm by 0.5 mm, 0.8 mm by 0.4 mm, 0.4 mm by 0.2 mm, and 0.2 mm by 0.1 mm.

Of the eight electronic components 320, at least one electronic component, that is, four electronic components 320 in the present embodiment, are disposed on the principal surface 3111. The electronic components 320 disposed on the principal surface 3111 are examples of a first electronic component. Of the eight electronic components 320, another at least one electronic component different from the at least one electronic component, that is, the other four electronic components 320 in the present embodiment, are disposed on the principal surface 3112. The electronic components 320 disposed on the principal surface 3112 are examples of a second electronic component. The principal surface 3111 is located between the principal surface 3112 and the memory element 212.

A connection structure of each of the electronic components 320 to the intermediate connecting member 310 is the same, so the description will be made focusing on the connection structure of one electronic component 320.

The two electrodes 326, 327 of the electronic component 320 are respectively joined to two wiring lines 330 adjacent to each other. The two wiring lines 330 adjacent to each other are referred to as a wiring line 330₁ and a wiring line 330₂. The wiring line 330₁ is an example of a first wiring line, and the wiring line 330₂ is an example of a second wiring line. The wiring line 330₂ is disposed with a space from the wiring line 330₁ in the X direction.

The wiring line 330₁ is electrically connected to the wiring board 211, and the wiring line 330₂ is electrically connected to the wiring board 221. In the present embodiment, the wiring line 330₁ is electrically connected to the wiring boards 211, 221, and the wiring line 330₂ is electrically connected to the wiring boards 211, 221. Specifically, the wiring line 330₁ is electrically connected to the corresponding pad 215 in the wiring board 211 and the corresponding pad 225 in the wiring board 221. The wiring line 330₂ is electrically connected to the corresponding pad 215 in the wiring board 211 and the corresponding pad 225 in the wiring board 221. As described above, the pads 215, 225 to which the wiring line 330₁ is electrically connected and the pads to which the wiring line 330₂ is electrically connected each are, for example, a signal pad, a power supply pad, a ground pad, or a dummy pad.

In a case where one of the pads 215, 225 to which the wiring line 330₁ is electrically connected is a dummy pad, the other one of the pads 215, 225 is a pad other than a dummy pad. Similarly, in a case where one of the pads 215, 225 to which the wiring line 330₂ is electrically connected is a dummy pad, the other one of the pads 215, 225 is a pad other than a dummy pad.

In a case where the end face 330L of the wiring line 330₁ is joined to a pad, other than a dummy pad, of the wiring board 211, the end face 330U of the wiring line 330₁ does not need to be joined to any pad of the wiring board 221. Then, in a case where the end face 330U of the wiring line 330₂ is joined to a pad, other than a dummy pad, of the wiring board 221, the end face 330L of the wiring line 330₂ does not need to be joined to any pad of the wiring board 211.

The electrode 326 is joined to the wiring line 330₁, and the electrode 327 is joined to the wiring line 330₂. As shown in FIG. 43, the electrode 326 and the wiring line 330₁ are joined by the corresponding joint member 351. The electrode 327 and the wiring line 330₂ are joined by the corresponding joint member 351.

Of the end face 310L and the end face 310U of the intermediate connecting member 310 in the Z direction, the electronic component 320 is disposed closer to the end face 310L than the end face 310U. In Embodiment 4I, of the end face 330L and the end face 330U of the wiring line 330₁ in the Z direction, the electronic component 320 is disposed closer to the end face 330L than the end face 330U. In other words, a distance D11 between the electronic component 320 and the wiring board 211 in the Z direction is less than a distance D12 between the electronic component 320 and the wiring board 221 in the Z direction. The distance D11 is an example of a first distance, and the distance D12 is an example of a second distance.

The end face 326L of the electrode 326 in the Z direction is disposed so as to be opposed to the corresponding pad 215 and is joined to the corresponding pad 215 by the corresponding joint member 351. In some steps of the manufacturing process for the image pickup module 20, the end face 326L of the electrode 326 is a lower end face. The electrode 326, the wiring line 330₁, and the corresponding pad 215 are integrally joined by the corresponding joint member 351. The electrode 327, the wiring line 330₂, and the corresponding pad 215 are also similarly integrally joined by the corresponding joint member 351.

FIGS. 44B and 44C show the intermediate connecting unit 300 before being joined to the wiring board 211 of the circuit unit 201. Thus, the electrode 326 and the wiring line 330₁ are joined by the corresponding joint member 361. Similarly, the electrode 326 and the wiring line 330₂ are joined by the corresponding joint member 361. The material of the joint member 361 is the same as the material of the joint member 351.

A dimension H11 in the Z direction of the wiring line 330₁ is greater than a dimension L11 in the X direction of the wiring line 330₁. Similarly, a dimension H12 in the Z direction of the wiring line 330₂ is greater than a dimension L12 in the X direction of the wiring line 330₂.

A pitch P between the wiring line 330₁ and the wiring line 330₂ in the X direction is set to a pitch by which the electrodes 326, 327 of the electronic component 320 can be joined. Here, the pitch P is a distance between the center of the wiring line 330₁ in the X direction and the center of the wiring line 330₂ in the X direction in the two wiring lines 330₁, 330₂ adjacent in the X direction. A distance L0 between the end face 310L of the intermediate connecting member 310 and the end face 326L of the electrode 326 in the Z direction is preferably narrower than the pitch P between the wiring line 330₁ and the wiring line 330₂ in the X direction. In Embodiment 4I, a distance between the end face 330L of the wiring line 330₂ and the end face 327L of the electrode 327 in the Z direction is the same as the distance L0.

In other words, a difference |D11−D13| between a distance D13 between the intermediate connecting member 310 and the wiring board 211 in the Z direction and the distance D11 is preferably narrower than the pitch P. The distance D13 is an example of a third distance. A difference |D11−D13| is the same as the distance L0. The distance D11 may be zero. The distance D13 may be zero. The difference |D11−D13| may be zero.

The intermediate connecting member 310 may include a ground wiring line connected to grounds included in the wiring boards 211, 221. In other words, any one of the plurality of wiring lines 330 may be a ground wiring line. Because a larger current is passed through a ground wiring line than through a signal wiring line, so a lower resistance is desired. Thus, the ground wiring line may be made of a conductive material having a lower resistance or a wire having a thicker diameter.

The width in the X direction and the thickness in the Y direction of each of the wiring lines 330 should be considered according to the use of the wiring line and the use of the electronic component 320 to be connected, and are preferably greater than or equal to 0.01 mm and less than or equal to 2 mm. In consideration of high-density mounting of the plurality of wiring lines 330, the width in the X direction and the thickness in the Y direction of each of the wiring lines 330 are more preferably less than or equal to 0.5 mm.

The length in the X direction of the intermediate connecting member 310, that is, the length L1 in the X direction of the insulating substrate 3110, is preferably shorter than the length of one side of each of the wiring boards 211, 221. Here, the length in the X direction of the intermediate connecting member 310 is the same as the length L1 in the X direction of the insulating substrate 3110.

The width in the Y direction of the intermediate connecting member 310, that is, the width W1 in the Y direction of the insulating substrate 3110, is preferably thinner as much as possible since a mounting area in which components can be mounted on the wiring board 211 increases. Here, the width in the Y direction of the intermediate connecting member 310 is the sum of the width W1 in the Y direction of the insulating substrate 3110, the width in the Y direction of one wiring line 330 disposed on the principal surface 3111, and the width in the Y direction of one wiring line 330 disposed on the principal surface 3112.

The height in the Z direction of the intermediate connecting member 310, that is, the height Hi in the Z direction of the insulating substrate 3110, is preferably higher than the highest mounting component, that is, the memory element 212 or the like. Here, the height in the Z direction of the intermediate connecting member 310 is the same as the height Hi in the Z direction of the insulating substrate 3110. For example, in a case where a mounting component having a height of 1.6 mm is mounted on the wiring board 211, the height Hi in the Z direction of the intermediate connecting member 310, that is, the insulating substrate 3110, is preferably greater than or equal to 1.6 mm.

The number and pitch P of the wiring lines 330 of the intermediate connecting member 310 depend on the number of pads and the pitch between the pads of an intended one of the wiring boards 211, 221 to be connected.

In this way, since the electronic components 320 are mounted on the intermediate connecting member 310, high-density mounting is possible in the image pickup module 20, so a further reduction in the size of the image pickup module 20 is achieved.

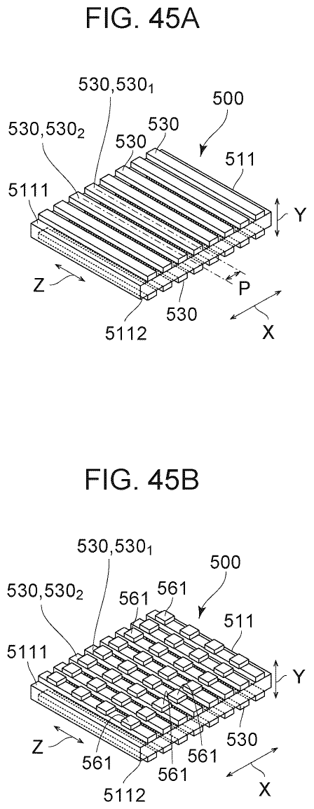

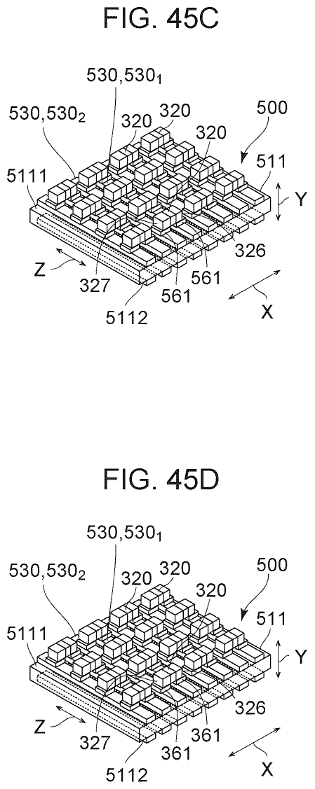

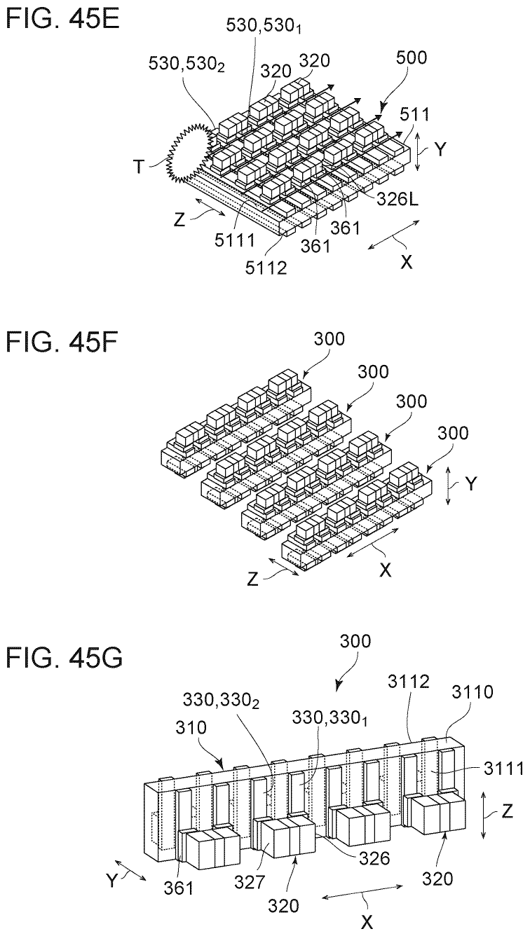

A manufacturing method for the intermediate connecting unit 300 will be described. FIGS. 45A to 45G are diagrams of steps of the manufacturing method for the intermediate connecting unit 300.

In the step shown in FIG. 45A, an intermediate 500 is prepared. The intermediate 500 may also be referred to as an intermediate structure or a structure. The intermediate 500 includes a plate-shaped insulating base material 511 and a plurality of conductive members 530 disposed on the insulating base material 511 and extending in the Z direction. Of the plurality of conductive members 530, at least one conductive member, that is, eight conductive members 530 in the example of FIG. 45A, are disposed with a space from each other in the X direction on a principal surface 5111 of the insulating base material 511. Of the plurality of conductive members 530, at least one conductive member different from the at least one conductive member, that is, eight conductive members 530 in the example of FIG. 45A, are disposed with a space from each other in the X direction on a principal surface 5112 of the insulating base material 511. The principal surface 5112 is a surface on the back side of the principal surface 5111. Here, two conductive members 530 adjacent to each other are defined as a conductive member 530₁ and a conductive member 530₂. The conductive member 530₁ is an example of a first conductive member, and the conductive member 530₂ is an example of a second conductive member. The conductive member 530₂ is disposed with a space from the conductive member 530₁ in the X direction.

Subsequently, in the step shown in FIG. 45B, a plurality of conductive pastes 561 is disposed with a space from each other in the Z direction on each conductive member 530. The conductive pastes 561 are precursors of the joint members 361. In the example shown in FIG. 45B, four conductive pastes 561 are disposed with a space from each other in the Z direction on one conductive member 530. The conductive pastes 561 are supplied onto the conductive member 530, for example, by screen printing, with a dispenser, or the like. The conductive paste 561 is preferably, for example, a conductive adhesive, such as a solder paste and a silver paste. The conductive paste 561 may be a sheet-shaped conductive adhesive. In this way, the plurality of conductive pastes 561 is disposed on each of the conductive members 530 on each of the principal surfaces 5111, 5112 of the intermediate 500. Thus, the plurality of conductive pastes 561 is arranged in an array in the X direction and in the Y direction on each of the principal surfaces 5111, 5112.

Subsequently, in the step shown in FIG. 45C, the plurality of electronic components 320 is disposed on each of the principal surfaces 5111, 5112 with a mounter (not shown). At this time, the electrodes 326, 327 of each electronic component 320 are respectively brought into contact with two conductive pastes 561 adjacent in the X direction.

Subsequently, the joint members 361 shown in FIG. 45D are formed through the step in which the conductive pastes 561 are heated to a temperature higher than or equal to a temperature at which metal powder contained in the conductive pastes 561 melts and then molten metal resulting from melting of the conductive pastes 561 is cooled. The metal powder is, for example, solder powder. Once the solder powder melts as a result of heating, molten solder aggregates.

The step of heating the conductive pastes 561 and the step of cooling the conductive pastes 561 can be performed in, for example, a reflow furnace. Through the step of heating the conductive pastes 561 and the step of cooling the conductive pastes 561, the joint members 361 are formed. The electrode 326 of each electronic component 320 is joined to the conductive member 530₁ by a corresponding one of the joint members 361, and the electrode 327 of each electronic component 320 is joined to the conductive member 530₂ by a corresponding one of the joint members 361. Thus, the electrode 326 is electrically and mechanically connected to the conductive member 530₁, and the electrode 327 is electrically and mechanically connected to the conductive member 530₂.

Subsequently, in the step shown in FIG. 45E, the intermediate 500 is cut in a straight line along the X direction. Thus, as shown in FIG. 45F, a plurality of singulated intermediate connecting units 300 is formed. FIG. 45G is one of the plurality of intermediate connecting units 300 to be manufactured.

In the cutting step, the intermediate 500 is cut such that the distance L0 (see FIG. 44C) between the cut end face of the conductive member 530 in the Z direction and the end face 326L of the electrode 326 in the Z direction is narrower than the pitch P in the X direction between the conductive member 530₁ and the conductive member 530₂. The cut end face of the conductive member 530 is an end face that will be the end face 330L of the wiring line 330. The end face 326L of the electrode 326 in the Z direction is oriented in the same direction as the cut end face and is opposed to a cutting tool T during cutting of the intermediate 500. To cut the intermediate 500, a dicer apparatus, a wire saw apparatus, or the like can be used. An interval in the Z direction with which the intermediate 500 is cut is the height Hi in the Z direction of the intermediate connecting member 310, that is, the insulating substrate 3110.

The end faces 330L, 330U of each wiring line 330 are preferably surfaces parallel to an X-Y plane and may be surfaces inclined with respect to the X-Y plane. The height in the Z direction is preferably uniform among the wiring lines 330, and the height in the Z direction may be different among the wiring lines 330.

Through the above manufacturing process, the intermediate connecting unit 300 can be easily manufactured.

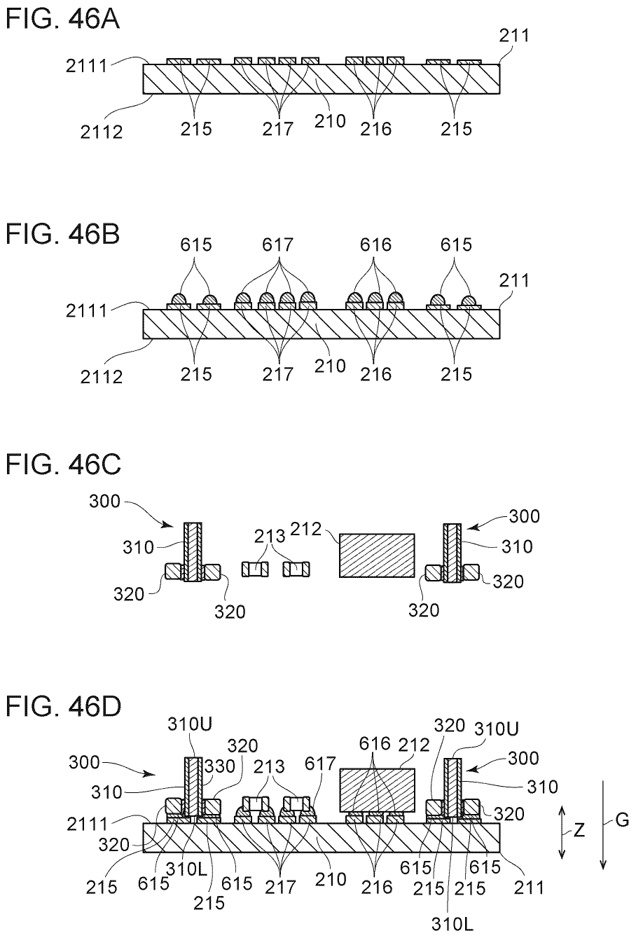

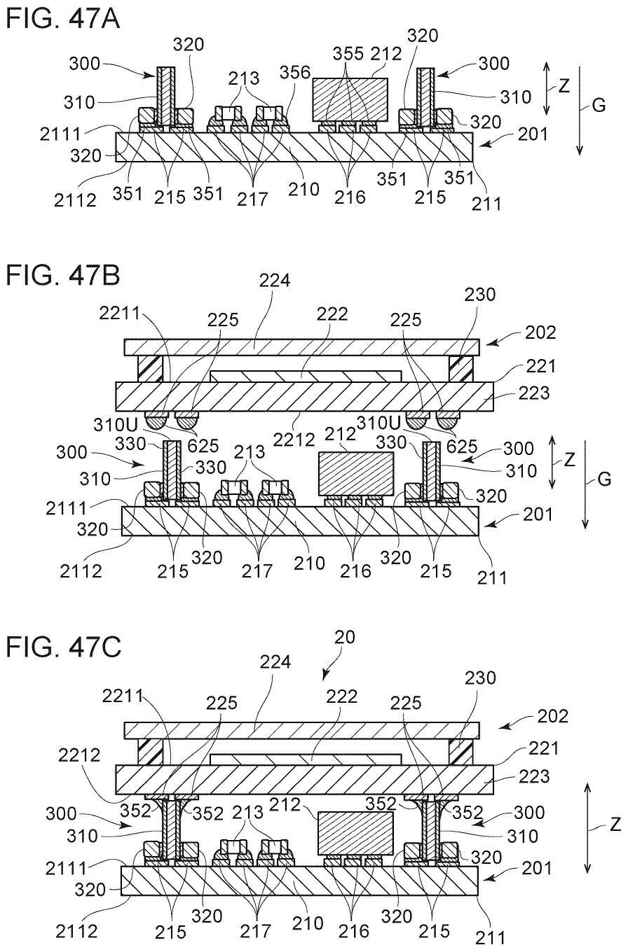

Next, a manufacturing method for the image pickup module 20 will be described. FIGS. 46A to 47C are diagrams of the steps of the manufacturing method for the image pickup module 20.

In the step shown in FIG. 46A, a wiring board 211 is prepared. The wiring board 211 has a plurality of pads 215, a plurality of pads 216, and a plurality of pads 217.

Subsequently, in the step shown in FIG. 46B, a conductive paste 615 is disposed on each of the pads 215, a conductive paste 616 is disposed on each of the pads 216, and a conductive paste 617 is disposed on each of the pads 217. Each of the conductive pastes 615 to 617 is preferably, for example, a conductive adhesive, such as a solder paste and a silver paste. Each of the conductive pastes 615 to 617 may be a sheet-shaped conductive adhesive. Each of the conductive pastes 615 to 617 is preferably a solder paste containing solder powder and flux and is preferably made of the same material as that of the above-described conductive paste 561. Each of the conductive pastes 615 to 617 can be supplied, for example, by screen printing or with a dispenser. Each of the conductive pastes 615 to 617 may be supplied so as to cover the entire exposed part of each of the pads 215 to 217 or may be supplied so as to partially cover the exposed part of each of the pads 215 to 217 like offset printing.

In the step shown in FIG. 46C, a memory element 212, electronic components 213, and intermediate connecting units 300, to be mounted on the wiring board 211, are prepared. Subsequently, as shown in FIG. 46D, the wiring board 211 is disposed at a predetermined location in a posture in which the pads 215 to 217 on the wiring board 211 face upward in a vertical direction G. The vertical direction G is a gravitational direction. Then, the memory element 212, the electronic components 213, and the intermediate connecting units 300 are mounted on the principal surface 2111 of the wiring board 211. In other words, the memory element 212 is mounted on the pads 216 in a state of being in contact with the conductive pastes 616, and each of the electronic components 213 is mounted on the pads 217 in a state of being in contact with the conductive pastes 617. Each of the intermediate connecting units 300 is mounted on the pads 215 by bringing each of the wiring lines 330 into contact with a corresponding one of the conductive pastes 615. These memory element 212, electronic components 213, and intermediate connecting units 300 are mounted on the wiring board 211 with a mounter (not shown).

Subsequently, the conductive pastes 615 to 617 are heated to a temperature higher than or equal to the temperature at which metal powder, for example, solder powder, contained in each of the conductive pastes 615 to 617 melts. Thus, the solder powder melts, and molten solder aggregates. After that, through the step of cooling the molten solder, the molten solder solidifies. Thus, as shown in FIG. 47A, joint members 351 that join the intermediate connecting units 300 to the wiring board 211, joint members 355 that join the memory element 212 to the wiring board 211, and joint members 356 that join the electronic components 213 to the wiring board 211 are formed. The heating step of heating the conductive pastes 615 to 617 to melt and the cooling step of cooling molten metal to solidify, shown in FIG. 46D, can be performed in, for example, a reflow furnace. Through the heating step and the cooling step, the joint members 351, 355, 356 are formed. In this way, through the heating step and the cooling step in FIG. 46D, the intermediate connecting units 300 are joined to the wiring board 211 of the circuit unit 201 as shown in FIG. 47A.

The electrode 326 of the electronic component 320, the wiring line 330₁, and the corresponding pad 215 are joined to one another by the corresponding joint member 351. The electrode 327 of the electronic component 320, the wiring line 330₂, and the corresponding pad 215 are joined to one another by the corresponding joint member 351. The joint member 351 is integrally formed in a manner such that a metal that is a component of the joint member 361 shown in FIG. 45G and a metal that is a component of the conductive paste 615 shown in FIG. 46B are heated to melt and aggregate and cooled to solidify. Thus, the electrode 326, the wiring line 330₁, and the corresponding pad 215 are electrically and mechanically connected to one another by the corresponding joint member 351. The electrode 327, the wiring line 330₂, and the corresponding pad 215 are electrically and mechanically connected to one another by the corresponding joint member 351.

Here, if the intermediate connecting unit 300 has no electronic component 320 and includes only the intermediate connecting member 310, there are concerns that the intermediate connecting unit 300 shifts or falls down with respect to the wiring board 211 due to handling after being mounted on the wiring board 211, vibrations during reflow, or the like. Particularly, the width W1 in the Y direction of the insulating substrate 3110 of the intermediate connecting member 310 is less than or equal to 1 mm and the height Hi in the Z direction of the insulating substrate 3110 is greater than or equal to 2 mm, it is difficult for only the intermediate connecting member 310 to be self-supported on the wiring board 211.

In Embodiment 4I, the electronic component 320 is disposed closer to the end face 310L than the end face 310U of the intermediate connecting member 310 in the Z direction as shown in FIGS. 44B and 44C. Then, as shown in FIG. 46D, the intermediate connecting unit 300 is mounted on the wiring board 211 in a posture in which the end face 310L of the intermediate connecting member 310 is located below the end face 310U in the vertical direction G. In other words, the intermediate connecting unit 300 is mounted on the wiring board 211 such that the end face 310L of the intermediate connecting member 310 is opposed to the principal surface 2111 of the wiring board 211. In this state, through the heating step and the cooling step, the intermediate connecting unit 300 is joined to the wiring board 211.

Here, the posture in which the end face 310L is located below the end face 310U in the vertical direction G is a posture in which the end face 310L is a lower end face. Thus, it is easy for the intermediate connecting unit 300 to be self-supported on the wiring board 211, so shifting or falling down of the intermediate connecting unit 300 with respect to the wiring board 211 before the intermediate connecting unit 300 is joined to the wiring board 211 can be prevented.

The distance L0 shown in FIG. 44C is narrower than the pitch P shown in FIG. 44A. For this reason, at the time when the intermediate connecting unit 300 is disposed on the wiring board 211, the end face 326L of the electrode 326 of the electronic component 320 is opposed to the corresponding pad 215 of the wiring board 211 via the conductive paste 615. At this time, the end face 326L of the electrode 326 is a lower end face. Thus, at the time when the intermediate connecting unit 300 is mounted on the wiring board 211, the intermediate connecting unit 300 can be further stably self-supported on the wiring board 211. At this time, the Z direction that is the height direction of the intermediate connecting member 310 is parallel to the vertical direction G. Then, through the heating step and the cooling step, as shown in FIG. 47A, the intermediate connecting unit 300 is joined to the wiring board 211 in a self-supported state. Therefore, the intermediate connecting unit 300 can be accurately joined to the wiring board 211. The distance L0 shown in FIG. 44C can be controlled by the arrangement locations of the conductive pastes 561 in FIG. 45B, the arrangement locations of the electronic components 320 in FIG. 45C, and the cutting locations shown in FIG. 45E.

Because the intermediate connecting unit 300 is difficult to fall down when the center-of-gravity position of the intermediate connecting unit 300 is at the center position in the Y direction of the intermediate connecting unit 300, the electronic components 320 are preferably disposed on both sides in the Y direction of the intermediate connecting member 310. At this time, the electronic component 320 disposed on the principal surface 3111 and the electronic component 320 disposed on the principal surface 3112 are preferably disposed at the same level in the Z direction.

Subsequently, in the step shown in FIG. 47B, a conductive paste 625 is disposed on each of the pads 225 of the wiring board 221 of a circuit unit 202. The conductive paste 625 is preferably, for example, a conductive adhesive, such as a solder paste and a silver paste. The conductive paste 625 may be a sheet-shaped conductive adhesive. Each of the conductive pastes 625 is preferably a solder paste containing solder powder and flux and is preferably made of the same material as that of the above-described conductive paste 561. Each of the conductive pastes 625 can be supplied, for example, by screen printing or with a dispenser. Each of the conductive pastes 625 may be supplied so as to cover the entire exposed part of each of the pads 225 or may be supplied so as to partially cover the exposed part of each of the pads 225 like offset printing.

Then, the circuit unit 202 is mounted on the end face 310U of the intermediate connecting member 310 in a posture in which each of the pads 225 on the wiring board 221 faces downward in the vertical direction G. In other words, the conductive paste 625 on each of the pads 225 is brought into contact with the end face 330U (FIG. 44C) of a corresponding one of the wiring lines 330. The circuit unit 202 is mounted on the intermediate connecting members 310 with a mounter (not shown).

Subsequently, the conductive pastes 625 are heated to a temperature higher than or equal to the temperature at which metal powder, for example, solder powder, contained in each of the conductive pastes 625 melts. Thus, the solder powder melts, and molten solder aggregates. After that, through the step of cooling the molten solder, the molten solder solidifies, and, as shown in FIG. 47C, joint members 352 that join the intermediate connecting unit 300 to the wiring board 221 are formed. The step of heating the conductive pastes 625 and the step of cooling the conductive pastes 625 can be performed in, for example, a reflow furnace. Through the step of heating the conductive pastes 625 and the step of cooling the conductive pastes 625, the joint members 352 are formed, and the intermediate connecting unit 300 is joined to the wiring board 221 of the circuit unit 202.

The image pickup module 20 can be manufactured in the above-described steps. Since the electronic components 320, such as resistors and capacitors as chip components, can also be mounted on the intermediate connecting member 310, high-density mounting in the image pickup module 20 is possible. It is possible to decrease the impedance at connecting portions between the laminated circuit units 201, 202 and the intermediate connecting units 300, so mismatching of impedance can be reduced. Falling down or shifting of the intermediate connecting member 310 with respect to the wiring board 211 can be prevented, with the result that the image pickup module 20 reduced in size can be manufactured with high accuracy.

### Embodiment 4II

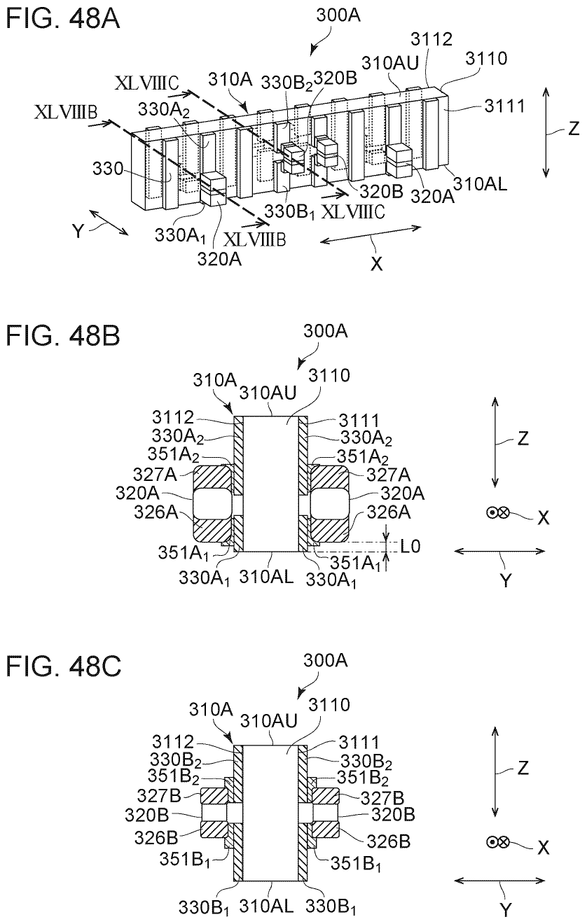

An intermediate connecting unit according to Embodiment 4II will be described. FIG. 48A is a perspective view of an intermediate connecting unit 300A according to Embodiment 4II. FIG. 48B is a sectional view of the intermediate connecting unit 300A, taken along the line XLVIIIB-XLVIIIB in FIG. 48A. FIG. 48C is a sectional view of the intermediate connecting unit 300A, taken along the line XLVIIIC-XLVIIIC in FIG. 48A. In an electronic module according to Embodiment 4II, the intermediate connecting unit 300 shown in FIG. 42A and the like are replaced with the intermediate connecting unit 300A. In Embodiment 4II, like reference signs denote components similar to those of Embodiment 4I, and the description is omitted.

The intermediate connecting unit 300A according to Embodiment 4II includes an intermediate connecting member 310A, and electronic components 320A and electronic components 320B mounted on the intermediate connecting member 310A. The electronic component 320A is larger in size than the electronic component 320B.

The intermediate connecting member 310A is a rectangular parallelepiped rigid wiring board. The intermediate connecting member 310A electrically and mechanically connects the two circuit units 201, 202, that is, the two wiring boards 211, 212, while holding a space in the Z direction between the two principal surfaces 2111, 2212 shown in FIG. 42B, so the intermediate connecting member 310A preferably has a rectangular parallelepiped shape long in the X direction.

The intermediate connecting member 310A has an end face 310AL and an end face 310AU in the Z direction. The end face 310AL of the intermediate connecting member 310A is an example of a first end face, and is a lower end face in some steps in a manufacturing process for the image pickup module. The end face 310AU of the intermediate connecting member 310A is an example of a second end face, and is an upper end face in some steps in a manufacturing process for the image pickup module.

The intermediate connecting member 310A includes an insulating substrate 3110 and a plurality of wiring lines 330, 330A₁, 330A₂, 330B₁, 330B₂ on each of the principal surface 3111 and the principal surface 3112 of the insulating substrate 3110. Each of the wiring lines 330, 330A₁, 330A₂, 330B₁, 330B₂ is a wiring line extending in the Z direction. Here, the wiring line 330A₁ is an example of a first wiring line. The wiring line 330A₂ is an example of a second wiring line. The wiring line 330B₁ is an example of a first wiring line. The wiring line 330B₂ is an example of a second wiring line. In some steps of the manufacturing process for the image pickup module, when the Z direction is made parallel to the vertical direction, the wiring line 330A₁ is located below the wiring line 330A₂ in the vertical direction, and the wiring line 330B₁ is located below the wiring line 330B₂ in the vertical direction.

The wiring line 330A₁ and the wiring line 330A₂ are disposed at the same location in the X direction and are disposed with a space from each other in the Z direction. The wiring line 330B₁ and the wiring line 330B₂ are disposed at the same location in the X direction and are disposed with a space from each other in the Z direction.

The wiring line 330A₁ is electrically connected to the wiring board 211 (FIG. 42B), and the wiring line 330A₂ is electrically connected to the wiring board 221 (FIG. 42B). Similarly, the wiring line 330B₁ is electrically connected to the wiring board 211, and the wiring line 330B₂ is electrically connected to the wiring board 221.

Each of the wiring lines 330, 330A₁, 330A₂, 330B₁, 330B₂ is configured to include a member having electrical conductivity, for example, an inorganic material, such as copper, silver, and aluminum, or an organic material, such as conductive rubber. Each of the wiring lines 330, 330A₁, 330A₂, 330B₁, 330B₂ may be formed by crimping a metal foil or may be formed by applying a conductive paste with a dispenser or the like and firing the conductive paste.

The electronic component 320A has two electrodes 326A, 327A spaced apart from each other. The electronic component 320B has two electrodes 326B, 327B spaced apart from each other. The electrode 326A is an example of a first electrode, and the electrode 327A disposed on an opposite side to the electrode 326A is an example of a second electrode. The electrode 326B is an example of a first electrode, and the electrode 327B disposed on an opposite side to the electrode 326B is an example of a second electrode. Each of the electronic components 320A, 320B is preferably a chip component, such as a resistor, a capacitor, and an inductor, and is, for example, a chip resistor that is a resistor.

The two electrodes 326A, 327A of the electronic component 320A are respectively joined to two wiring lines 330A₁, 330A₂ adjacent to each other. The wiring line 330A₂ is disposed with a space from the wiring line 330A₁ in the Z direction. The two electrodes 326B, 327B of the electronic component 320B are respectively joined to two wiring lines 330B₁, 330B₂ adjacent to each other. The wiring line 330B₂ is disposed with a space from the wiring line 330B₁ in the Z direction.

The electrode 326A is joined to the wiring line 330A₁, and the electrode 327A is joined to the wiring line 330A₂. As shown in FIG. 48B, the electrode 326A and the wiring line 330A₁ are joined by the corresponding joint member 351A₁. The electrode 327A and the wiring line 330A₂ are joined by the corresponding joint member 351A₂.

The electrode 326B is joined to the wiring line 330B₁, and the electrode 327B is joined to the wiring line 330B₂. As shown in FIG. 48C, the electrode 326B and the wiring line 330B₁ are joined by the corresponding joint member 351B₁. The electrode 327B and the wiring line 330B₂ are joined by the corresponding joint member 351B₂.

In this way, since the electronic components 320A, 320B are mounted on the intermediate connecting member 310A, high-density mounting is possible in the image pickup module, so a further reduction in the size of the image pickup module is achieved.

The electronic component 320A is larger in size than the electronic component 320B, so the electronic component 320A is heavier. The size of the electronic component 320A is, for example, 0.6 mm by 0.3 mm. The size of the electronic component 320B is, for example, 0.4 mm by 0.2 mm. Of the end face 310AL and the end face 310AU of the intermediate connecting member 310A in the Z direction, the electronic component 320A is disposed closer to the end face 310AL than the end face 310AU. In other words, a distance between the electronic component 320A and the wiring board 211 (FIG. 43) in the Z direction is less than a distance between the electronic component 320A and the wiring board 221 (FIG. 42B) in the Z direction. Thus, at the time of manufacturing an image pickup module, falling down or shifting of the intermediate connecting member 310A with respect to the wiring board 211 can be prevented, with the result that the image pickup module reduced in size can be manufactured with high accuracy. At this time, a distance L0 between the end face 310AL of the intermediate connecting member 310A and the end face 326AL of the electrode 326A in the Z direction is preferably narrower than the pitch between the wiring line 330A₁ and the wiring line 330 in the X direction.

A manufacturing method for the intermediate connecting unit 300A according to Embodiment 4II and a manufacturing method for an image pickup module having the intermediate connecting unit 300A are similar to those of Embodiment 4I, so the description is omitted.

Because the intermediate connecting unit 300A is difficult to fall down when the center-of-gravity position of the intermediate connecting unit 300A is at the center position in the Y direction of the intermediate connecting unit 300A, the electronic components 320A are preferably disposed on both sides in the Y direction of the intermediate connecting member 310A. At this time, the electronic component 320A disposed on the principal surface 3111 and the electronic component 320A disposed on the principal surface 3112 are preferably disposed at the same level in the Z direction. Similarly, the electronic components 320B are preferably disposed on both sides in the Y direction of the intermediate connecting member 310A. At this time, the electronic component 320B disposed on the principal surface 3111 and the electronic component 320B disposed on the principal surface 3112 are preferably disposed at the same level in the Z direction.

### Example 4A

A specific example of the manufacturing method for the intermediate connecting unit 300 described in Embodiment 4I will be described. A chip component, that is a capacitor, having a size of 0.4 mm by 0.2 mm was used as the electronic component 320. An insulating flat plate having a low thermal expansion coefficient was used for the insulating base material 511 shown in FIG. 45A. The insulating base material 511 had a size such that the length in the X direction was 41.0 mm, the length in the Z direction was 50.0 mm, and the thickness in the Y direction was 1.0 mm. Seventy conductive members 530 made of the material of copper with a pitch P of 0.4 mm were disposed on each of the principal surfaces 5111, 5112 of the insulating base material 511. The thickness of each conductive member 530 was set to 0.015 mm, and the width was set to 0.2 mm.

Subsequently, as shown in FIG. 45B, a conductive paste 561 was applied onto each conductive member 530 by printing. The conductive paste 561 was a solder paste containing Sn—Ag—Cu solder powder and flux. An alloy composition of solder powder contained in the solder paste was tin-remainder, silver-3, and copper-3, and the melting point of the solder powder was 220° C. The mean particle diameter of the solder powder was 40 μm.

Subsequently, as shown in FIG. 45C, a plurality of electronic components 320 was mounted on the conductive members 530 of each of the principal surfaces 5111, 5112 with a mounter.

Subsequently, as shown in FIG. 45D, the intermediate 500 on which the electronic components 320 were mounted was put in a reflow furnace, and the conductive paste 561 was heated to a temperature higher than or equal to the melting point of the solder powder. After the solder powder melted and the molten solder aggregated, the molten solder was cooled to a temperature lower than the melting point of solder to solidify, with the result that the joint members 361 were formed. With such a joint structure, the electrodes 326 of the electronic components 320 were electrically and mechanically connected to the conductive member 530₁, and the electrodes 327 of the electronic components 320 were electrically and mechanically connected to the conductive member 530₂.

Subsequently, as shown in FIG. 45E, the intermediate 500 was cut into a strip shape by using a dicer apparatus to obtain a plurality of intermediate connecting units 300 as shown in FIG. 45F. In the intermediate connecting member 310 of each intermediate connecting unit 300, the length L1 in the X direction of the insulating substrate 3110 was 41.0 mm, the width W1 in the Y direction of the insulating substrate 3110 was 1.0 mm, and the height Hi in the Z direction of the insulating substrate 3110 was 1.8 mm. Thirty-five electronic components 320 were mounted on each of the principal surfaces 3111, 3112 of the intermediate connecting member 310, and the intermediate connecting unit 300 having 70 electronic components 320 in total could be manufactured.

Next, a specific example of a manufacturing method for an image pickup module 20 using the intermediate connecting member 310 will be described.

A wiring board 211 shown in FIG. 46A was prepared. A solder resist (not shown) was formed on the principal surface 2111 of the wiring board 211 so as to partially cover each of the pads 215 to 217. The solder resist had openings at locations corresponding to the pads 215 to 217, and each of the pads 215 to 217 was partially exposed.

FR-4 was used for the insulating substrate 2110 of the wiring board 211. The size of the outer shape of the wiring board 211 in a plan view was 50.0 mm by 50.0 mm. Electronic components, such as capacitors and resistors (not shown), were mounted in advance on the principal surface 2112 of the wiring board 211. The material of each of the pads 215 to 217 of the wiring board 211 was copper. The pads 215 to which an intermediate connecting unit 300 was connected each had a width of 0.2 mm and a length of 0.3 mm and were arranged with a pitch of 0.4 mm.

As shown in FIG. 46B, conductive pastes 615 to 617 were respectively formed on the pads 215 to 217 of the wiring board 211 by screen printing. A printing plate with a thickness of 0.02 mm was used for screen printing. Each of the conductive pastes 615 to 617 was a solder paste containing Sn—Ag—Cu solder powder and flux. An alloy composition of solder powder contained in the solder paste was tin-remainder, silver-3, and copper-3, and the melting point of the solder powder was 220° C. The mean particle diameter of the solder powder was 40 μm.

A memory element 212 to a back surface of which solder balls were connected in advance was prepared. The pads 216 of the wiring board 211 were disposed at locations corresponding to the solder balls of the memory element 212. The size of the outer shape of the memory element 212 was a length of 16.0 mm, a width of 16.0 mm, and a height of 1.6 mm. Four intermediate connecting units 300 were prepared.

Subsequently, as shown in FIG. 46D, the memory element 212, the electronic components 213, and the intermediate connecting units 300 were mounted with a mounter on the wiring board 211 to which the conductive pastes 615 to 617 were supplied. the four intermediate connecting units 300 were mounted on the wiring board 211 so as to surround the memory element 212 and the electronic components 213.

In each of the four intermediate connecting units 300, the end face 330L of each of the wiring lines 330 was aligned with a corresponding one of the pads 215 of the wiring board 211, and the intermediate connecting units 300 were mounted on the wiring board 211. The solder balls (not shown) of the memory element 212 were aligned with the pads 216 of the wiring board 211, and the memory element 212 was mounted on the wiring board 211. The width W1 of the insulating substrate 3110 of the intermediate connecting unit 300 was 1.0 mm, and the intermediate connecting unit 300 was supported by the electronic components 320 on the side surfaces of the intermediate connecting member 310 and self-supported on the wiring board 211.

Subsequently, the wiring board 211 on which these components were mounted was put into a reflow furnace, and the conductive pastes 615 to 617 were heated to a temperature higher than or equal to the melting point of the solder powder. After the solder powder melted and the molten solder aggregated, the molten solder was cooled to a temperature lower than the melting point of solder to solidify. Thus, as shown in FIG. 47A, the memory element 212, the electronic components 213, and the intermediate connecting units 300 were joined to the wiring board 211.

Subsequently, as shown in FIG. 47B, conductive pastes 625 were respectively formed on the pads 225 of the wiring board 221 by screen printing. Each of the conductive pastes 615 to 617 was a solder paste containing Sn—Ag—Cu solder powder and flux. An alloy composition of solder powder contained in the solder paste was tin-remainder, silver-3, and copper-3, and the melting point of the solder powder was 220° C. The mean particle diameter of the solder powder was 40 μm.

Subsequently, the pads 225 of the circuit unit 202 to which the conductive pastes 625 were supplied were aligned with the end faces 330U of the wiring lines 330 of the intermediate connecting units 300, and the circuit unit 202 was mounted on the four intermediate connecting units 300. A solder resist (not shown) was formed on the principal surface 2212 of the wiring board 221 so as to partially cover each of the pads 225. The solder resist had openings at locations corresponding to the pads 225, and each of the pads 225 was partially exposed.

An insulating substrate having a low thermal expansion coefficient was used for the insulating substrate 223 of the wiring board 221. The size of the outer shape of the wiring board 221 in a plan view was 52.0 mm by 52.0 mm. The material of each of the pads 225 of the wiring board 221 was copper. The pads 225 to which an intermediate connecting unit 300 was connected each had a width of 0.2 mm and a length of 0.3 mm and were arranged with a pitch of 0.4 mm.

Subsequently, as shown in FIG. 47C, a mounted product in which the circuit unit 202 was mounted on the intermediate connecting units 300 was put into a reflow furnace, and the conductive pastes 625 were heated to a temperature higher than or equal to the melting point of the solder powder. After the solder powder melted and the molten solder aggregated, the molten solder was cooled to a temperature lower than the melting point of solder to solidify. Thus, the circuit unit 202 was joined to the intermediate connecting units 300.

The image pickup module 20 could be manufactured in the above-described steps. In the image pickup module 20, the electronic components 320 mounted on each intermediate connecting member 310 did not peel off or did not have a solder joint defect. Then, the image pickup module 20 could sufficiently guarantee the optical performance of the electrooptical component 200 that was an image sensor.

### Example 4B

The intermediate connecting unit 300A shown in FIGS. 48A to 48C, described in Embodiment 4II, was also manufactured with a similar method to that of Example 4A, and an image pickup module using the intermediate connecting unit 300A was also manufactured with a method similar to that of Example 4A. A 0.6 mm-by-0.3 mm chip resistor was used for the electronic component 320A. A 0.4 mm-by-0.2 mm chip resistor was used for the electronic component 320B. In the image pickup module, the electronic components 320A, 320B mounted on each intermediate connecting member 310A did not peel off or did not have a solder joint defect. Then, the image pickup module could sufficiently guarantee the optical performance of an image sensor.

The present invention is not limited to the above-described embodiments, and many modifications are applicable within the technical concept of the present invention. Advantageous effects described in the embodiments are only the most favorable advantageous effects obtained from the present invention, and advantageous effects of the present invention are not limited to those described in the embodiments.

In the above-described embodiments, a case where the electronic apparatus is a digital camera has been described as an example; however, the configuration is not limited thereto. For example, the electronic apparatus may be a mobile communication device. For example, the electronic apparatus may be an information device, such as a smartphone and a personal computer, or a communication device, such as a modem and a router. Alternatively, the electronic apparatus may be a business machine, such as a printer and a copying machine, a medical apparatus, such as a radiographic apparatus, a magnetic imaging apparatus, an ultrasonic imaging apparatus, and an endoscope, an industrial apparatus, such as a robot and a semiconductor manufacturing apparatus, or a transportation apparatus, such as a vehicle, a plane, and a ship.

In a case where wiring lines are provided in a limited space in the casing of an electronic apparatus, a reduction in the size and high density of the electronic apparatus are possible when the intermediate connecting unit 300 is used. The electronic module according to the present invention is applicable to any electronic apparatus.

An electronic component different from the electronic components in the above-described embodiments may be mounted on an intermediate connecting member. In this case, of two electrodes included in the different electronic component, one electrode may be joined to any one of wiring lines of the intermediate connecting member, and the other electrode may be joined to a member other than the intermediate connecting member, for example, a pad of a wiring board.

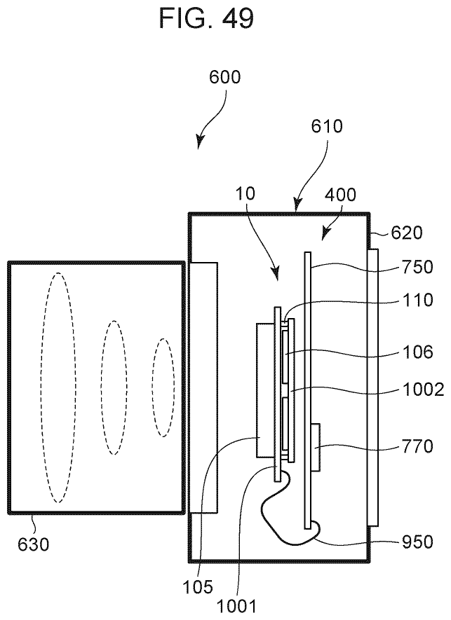

FIG. 49 is a diagram of a digital camera that is an electronic apparatus 600 serving as an example of an apparatus according to the present embodiment.

The electronic apparatus 600 is, for example, a lens interchangeable digital camera and includes a camera body 610. A lens unit (lens barrel) 630 including lenses is detachably mounted. The camera body 610 includes a casing 620, an image pickup module 10 disposed in the casing 620, and a processing module 400. The image pickup module 10 and the processing module 400 are electrically connected to each other by a wiring component 950 (wiring board), such as a flexible wiring board. The features of the above-described modules 20, 30 may be applied to the image pickup module 10.

The image pickup module 10 includes a wiring board 1001 on which a unit 105 is mounted, a wiring board 1002 on which a tall component, that is, an electronic component 106 or the like, is mounted, and a wiring component 100. The unit 105 includes an electronic component 240 that is an image sensor (image pickup element), and a lid 250. The wiring board 1001 and the wiring board 1002 are electrically connected via the wiring component 100. A circuit unit includes an integrated circuit component 770 that is an example of the electronic component and a wiring board 750 on which the integrated circuit component 770 is mounted. A unit including a wiring board and an electronic component mounted on the wiring board may be referred to as circuit board.

The image sensor (image pickup element) is, for example, a complementary metal oxide semiconductor (CMOS) image sensor or a charge coupled device (CCD) image sensor. The image sensor has a function to convert light incoming via the lens unit 630 to an electrical signal.

The integrated circuit component 770 is, for example, a digital signal processor. The integrated circuit component 770 can be an image processing apparatus that has a function to acquire an electrical signal from the image sensor, execute a process of correcting the acquired electrical signal, and generate image data.

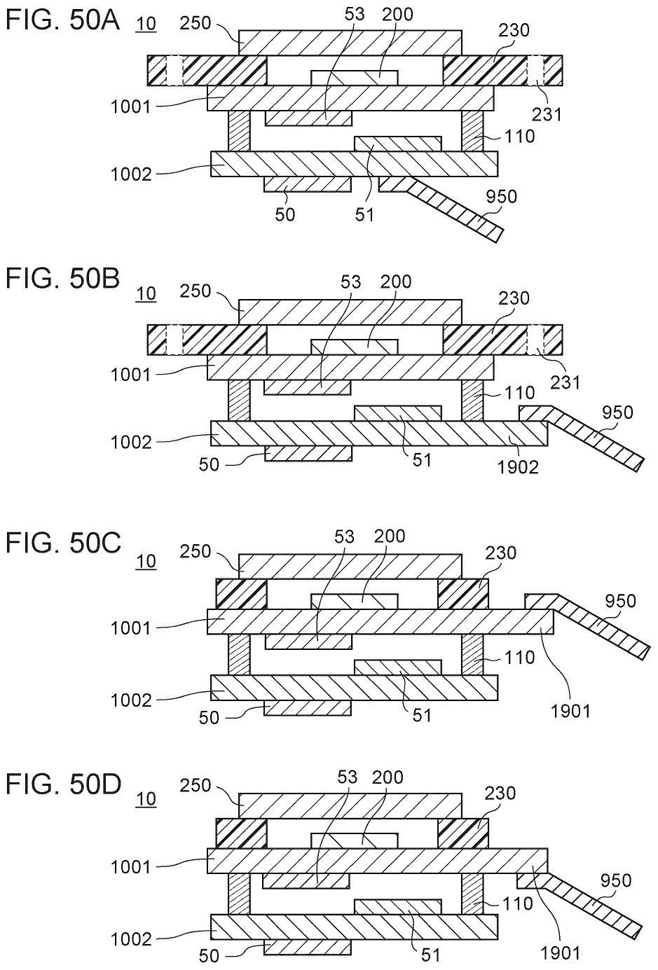

FIGS. 50A to 50D show other modes of the module 10 to which the features of the modules 20, 30 are applicable. The connecting member 110 that electrically connects the wiring board 1001 to the wiring board 1002 is disposed between the wiring board 1001 and the wiring board 1002 and is soldered to the wiring board 1001 and the wiring board 1002. Of the principal surfaces of the wiring board 1001, the electrooptical component 200 is mounted on the principal surface on an opposite side to the side of the wiring board 1002. The wiring board 1001 is provided between the electrooptical component 200 and the wiring board 1002. Of the principal surfaces of the wiring board 1002, the integrated circuit component 50 is mounted on the principal surface on an opposite side to the side of the wiring board 1001. The wiring board 1002 is provided between the integrated circuit component 50 and the wiring board 1001. Of the principal surfaces of the wiring board 1002, the integrated circuit component 51 is mounted on the principal surface on the wiring board 1001 side. The integrated circuit component 51 is provided between the wiring board 1001 and the wiring board 1002. Of the principal surfaces of the wiring board 1001, an electronic component 53 is mounted on the principal surface on an opposite side (the wiring board 1002 side) to the electrooptical component 200 side. The electronic component 53 is provided between the wiring board 1001 and the wiring board 1002. At least one or some of the integrated circuit component 50, the integrated circuit component 51, and the electronic component 53 may overlap the electrooptical component 200 in a direction perpendicular to the principal surface of the wiring board 1001, the principal surface of the wiring board 1002, and the principal surface of the electrooptical component 200. Thus, a mounting surface can be effectively used. At least one or some of the integrated circuit component 51, the integrated circuit component 52, and the electronic component 53 may overlap the electrooptical component 200 in a direction perpendicular to the principal surface of the wiring board 1001, the principal surface of the wiring board 1002, and the principal surface of the electrooptical component 200. Thus, the influence of heat between the electrooptical component 200 and other components can be reduced. The electronic component 53 may be an integrated circuit component, such as a memory and a power IC, or a passive component, such as a capacitor, a resistor, and an inductor. By mounting the electronic component 53 and the electrooptical component 200 on the same wiring board 1001, a wiring line path between the electronic component 53 and the electrooptical component 200 can be shortened. Therefore, a component that can easily provide an advantageous effect due to a short wiring line path to the electrooptical component 200 is preferably selected for the electronic component 53. For example, a memory is suitable for the electronic component 53 in terms of signal processing and a capacitor is suitable for the electronic component 53 in terms of noise reduction. A memory included in the module 10 as any one of the integrated circuit component 50, the integrated circuit component 51, and the electronic component 53 is used to store data output from the electrooptical component 200 and data to be input to the electrooptical component 200. When the integrated circuit component 50 or the integrated circuit component 51 is a memory, communication between the memory and the electrooptical component 200 is performed via the connecting member 110. Any one of the integrated circuit component 50, the integrated circuit component 51, and the electronic component 53 may supply electric power to the electrooptical component 200. Any one of the integrated circuit component 50, the integrated circuit component 51, and the electronic component 53 may supply electric power to at least another one of the integrated circuit component 50, the integrated circuit component 51, and the electronic component 53. The electronic component 53 may serve as a memory, the integrated circuit component 50 or the integrated circuit component 51 may serve as a power IC, and electric power may be supplied from the power IC to the memory.

The module 10 can include a wiring component 950 for connection with another module in the electronic apparatus 600. The wiring component 950 is a cable and the like and is a wiring board having flexibility (flexible wiring board), typically, a flexible printed wiring board. The wiring component 950 is connected to the wiring board 1001 or the wiring board 1002. In the modes of FIGS. 50A and 50B, the wiring component 950 is connected to the wiring board 1002. In the modes of FIGS. 50C and 50D, the wiring component 950 is connected to the wiring board 1001. A method of connecting the wiring component 950 to the wiring board 1001 or the wiring board 1002 is typically a method inserting the wiring component 950 to a connector mounted on the wiring board 1001 or the wiring board 1002 to fix the wiring component 950. With this method, the wiring component 950 can be attached to and detached from the wiring board 1001 or the wiring board 1002. As another connection method, there is a method of soldering the wiring component 950 to the wiring board 1001 or the wiring board 1002. With this method, it is possible to reduce the possibility that the wiring component 950 comes off from the wiring board 1001 or the wiring board 1002, and the weight of the module is reduced by the weight of the connector. Therefore, it is advantageous in mechanically actuating the module 10 with a drive unit in a casing of the apparatus. Instead of soldering the wiring component 950 to the wiring board 1001 or the wiring board 1002, the wiring component 950 can be joined to the wiring board 1001 or the wiring board 1002 by a conductive member, such as an anisotropic conductive film (ACF). The disclosure of Japanese Patent Laid-Open No. 2020-120106 and Japanese Patent Laid-Open No. 2021-168378 can be incorporated herein for soldering of a flexible wiring board. When a resin substrate, such as a glass epoxy resin and a thermosetting resin, is used as an insulating substrate (an insulating substrate or an insulating substrate part) of each of the wiring boards 1001, 1002, the weight of the module can be reduced as compared to using a ceramic substrate.

In the mode of FIG. 50A, of the principal surfaces of the wiring board 1002, the wiring component 950 is connected to the principal surface on an opposite side to the wiring board 1001 side. In the mode of FIG. 50A, in order words, the wiring component 950 and the integrated circuit component 50 are fixed to the same surface of the wiring board 1002. Connecting portions between the wiring component 950 and the wiring board 1002 can overlap the electrooptical component 200.

In the mode of FIG. 50B, of the principal surfaces of the wiring board 1002, the wiring component 950 is connected to the principal surface on the wiring board 1001 side. In order words, the wiring component 950 and the integrated circuit component 51 are fixed to the same surface of the wiring board 1002. In the mode of FIG. 50B, the wiring board 1002 has an expanded part 1902 extending outward beyond the intermediate connecting member 110 (an opposite side to the integrated circuit component 51 with respect to the intermediate connecting member 110). The wiring component 950 is connected to this expanded part 1902. To suppress interference between the wiring component 950 and the wiring board 1001, the expanded part 1902 preferably does not overlap the wiring board 1001.

In the mode of FIG. 50C, of the principal surfaces of the wiring board 1001, the wiring component 950 is connected to the principal surface on an opposite side to the wiring board 1002 side. In order words, the wiring component 950 and the electrooptical component 200 are fixed to the same surface of the wiring board 1001. In the mode of FIG. 50C, the wiring board 1001 has an expanded part 1901 extending outward beyond the frame 230 (an opposite side to the electrooptical component 200 with respect to the frame 230). The wiring component 950 is connected to this expanded part 1901. Connecting portions between the wiring component 950 and the wiring board 1001 do not overlap the electrooptical component 200.

In the mode of FIG. 50D, of the principal surfaces of the wiring board 1001, the wiring component 950 is connected to the principal surface on the wiring board 1001 side (the principal surface on an opposite side to the electrooptical component 200 side). In order words, the wiring component 950 and the electronic component 53 are fixed to the same surface of the wiring board 1001. In the mode of FIG. 50D, the wiring board 1001 has an expanded part 1901 extending outward beyond the intermediate connecting member 110 (an opposite side to the integrated circuit component 51 with respect to the intermediate connecting member 110). The wiring component 950 is connected to this expanded part 1901. To suppress interference between the wiring component 950 and the wiring board 1002, the expanded part 1901 preferably does not overlap the wiring board 1002.

In the modes of FIGS. 50A and 50B, the frame 230 has an expanded part extending to an opposite side (the outer side of an outer edge) to the electrooptical component 200 with respect to the outer edge of the wiring board 1001. The expanded part of the frame 230 can be used to dissipate heat of the module 10. The expanded part of the frame 230 has through holes 231. The through holes 231 are used to fix the module 10 to another component as screw holes in the casing 620 of the electronic apparatus 600. The disclosure of Japanese Patent Laid-Open No. 2013-243341 and Japanese Patent Laid-Open No. 2015-084377 can be incorporated herein for the expanded part of the frame 230. In the modes of FIGS. 50C and SOD as well, the frame 230 may have an expanded part. For example, the expanded part of the frame 230 should be provided at two upper and lower sides of the quadrilateral electrooptical component 200 in a plan view, and the expanded part 1901 of the wiring board 1001 should be provided at two right and left sides. Through holes may be provided at the expanded parts 1901, 1102 of the wiring boards 1001, 1002, and the through holes may be used to fix the module 10 to another component in the casing 620 of the electronic apparatus 600.

Here, the wiring boards 1001, 1002 on which the electronic components are mounted have been described. Alternatively, another wiring board on which an electronic component is mounted may be connected to the wiring board 1001 or the wiring board 1002 via an intermediate connecting member. Another wiring board on which an electronic component is mounted may be directly soldered to the wiring board 1001 or the wiring board 1002. Another wiring board may be disposed between the wiring board 1001 and the wiring board 1002, or the wiring board 1002 may be disposed between another wiring board and the wiring board 1001.

The above-described embodiments may be modified as needed without departing from the technical idea. For example, a plurality of embodiments may be combined. The matter of part of at least one embodiment may be deleted or replaced. A new matter may be added to at least one embodiment. Advantageous effects described in the embodiments are only the favorable advantageous effects obtained from the present invention, and advantageous effects of the present invention are not limited to those described in the embodiments.

The disclosed content of the specification includes not only the ones explicitly described in the specification but also all the matter that can be understood from the specification and the drawings attached to the specification. The disclosed content of the specification includes complements of individual concepts described in the specification. In other words, when, for example, “A is B” is described in the specification, even if the description that “A is not B” is omitted, the specification may be regarded describing that “A is not B”. This is because, when “A is B” is described, it is assumed that the case “A is not B” has been considered.

Embodiments of the present invention are not limited to the above-described embodiments. Various changes or modifications are applicable without departing from the spirit and scope of the present invention. Therefore, the following claims are attached to show the scope of the present invention.

According to the present invention, it is possible to provide a technology beneficial to high integration of a module.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A module comprising:
a first wiring board;
a first component that is an electrooptical component mounted on the first wiring board;
a second wiring board overlapping the first wiring board;
a second component that is an integrated circuit component mounted on the second wiring board; and
a connecting member disposed between the first wiring board and the second wiring board, the connecting member being soldered to the first wiring board and the second wiring board, the connecting member electrically connecting the first wiring board to the second wiring board.

2. The module according to claim 1, wherein the second component is provided between the first wiring board and the second wiring board.

3. The module according to claim 1, wherein the second component overlaps the first component in a direction perpendicular to a principal surface of the first component.

4. The module according to claim 1, further comprising a third component mounted on the first wiring board, wherein the third component is provided between the first wiring board and the second wiring board.

5. The module according to claim 4, wherein the third component overlaps the first component in a direction perpendicular to a principal surface of the first component.

6. The module according to claim 1, further comprising a fourth component mounted on the second wiring board, wherein the second wiring board is provided between the first wiring board and the fourth component.

7. The module according to claim 6, wherein the fourth component overlaps the first component in a direction perpendicular to a principal surface of the first component.

8. The module according to claim 1, further comprising a third wiring board soldered to the first wiring board or the second wiring board.

9. The module according to claim 8, wherein the third wiring board is a flexible wiring board.

10. The module according to claim 8, wherein the second wiring board is provided between the third wiring board and the first wiring board.

11. The module according to claim 1, wherein the first wiring board includes a resin substrate.

12. The module according to claim 1, wherein the second component is electrically connected to the first component via the connecting member.

13. The module according to claim 4, wherein the third component is a memory.

14. The module according to claim 1, wherein the connecting member has at least one of a part made of glass epoxy resin and a part made of thermosetting resin.

15. The module according to claim 1, wherein the connecting member includes at least one of a copper wiring line and a solder resist.

16. The module according to claim 1, wherein the first component is electrically connected to the first wiring board by wire bonding.

17. The module according to claim 1, wherein the second component supplies electric power to the first component.

18. An apparatus comprising the module according to claim 1 and a casing accommodating the module.

19. The apparatus according to claim 18, further comprising a drive unit that mechanically actuates the module in the casing.

20. The apparatus according to claim 18, wherein
the first component is an image sensor, and
the apparatus further comprises a display module that displays an image picked up by the image sensor.
